(19) United States
(12) Patent Application Publication
(10) Pub. No.: US 2024/0153846 A1
(43) Pub. Date: May 9, 2024

(54) SYSTEMS FOR THERMAL MANAGEMENT AND METHODS THEREOF

(71) Applicant: Holo, Inc., Newark, CA (US)

(72) Inventors: Karthik BODLA, Houston, TX (US); Xiangyu GAO, Fremont, CA (US); Arian AGHABABAIE, San Francisco, CA (US); Jonathan POMEROY, Oakland, CA (US)

(21) Appl. No.: 18/239,514

(22) Filed: Aug. 29, 2023

Related U.S. Application Data
(63) Continuation of application No. PCT/US22/18041, filed on Feb. 25, 2022.
(60) Provisional application No. 63/155,005, filed on Mar. 1, 2021.
(60) Provisional application No. 63/176,663, filed on Apr. 19, 2021.

(51) Int. Cl. H01L 23/46; G06F 1/20; H05K 7/20

(52) U.S. Cl. CPC H01L 23/46; G06F 1/20; H05K 7/20; G06F 2200/201

(57) ABSTRACT

The present disclosure provides a thermal management device. In some cases, the thermal management device may comprise a first portion of a housing. The first portion may be configured to facilitate a transfer of a first thermal energy from a first surface of an integrated circuit module (ICM) to a surface of the first portion, or vice versa. The thermal management device may further comprise a first plurality of channels disposed within the first portion. The first plurality of channels may be configured to provide a first fluid flow path in thermal contact with the first portion. The first fluid flow path may be configured to facilitate a transfer of the first thermal energy from the first portion to a cooling fluid disposed within the first fluid flow path.

### CROSS-REFERENCE

This application is a continuation of International Patent Application No. PCT/US22/18041, filed Feb. 25, 2022, which claims the benefit of U.S. Provisional Patent Application No. 63/155,005, filed Mar. 1, 2021, and U.S. Provisional Patent Application No. 63/176,663, filed Apr. 19, 2021, each of which is incorporated herein by reference in its entirety.

### BACKGROUND

Heat transfer devices such as heat sinks and heat exchangers can play an important role in a variety of applications, including thermal control systems, energy storage systems, heat recovery systems, and energy conversion systems. As these systems become more and more complex, they may require more efficient thermal management solutions to manage increased thermal loads and to optimize system performance.

### SUMMARY

Recognized herein are various limitations with thermal management devices currently available. The cooling performance of thermal management devices such as heat sinks and heat exchangers may depend on the size and/or shape of the heat sink or heat exchanger or the materials used to construct the heat sink or heat exchanger. Given the ongoing development of increasingly complex devices and systems with high thermal loads and power densities, there is a need for more efficient thermal management devices capable of managing higher thermal loads and power densities. Additive manufacturing and three-dimensional (3D) printing technologies may provide an alternative approach to fabricating high-performance heat transfer devices with customized and complex freeform shapes that can enhance the thermal management capabilities. Provided herein are heat sink devices that may be fabricated using additive manufacturing and/or 3D printing techniques to leverage, for example, liquid cooling (e.g., water cooling).

In an aspect, the present disclosure provides a thermal management device, comprising: (a) a shell comprising: (1) a first conformal section and a second conformal section, wherein the first conformal section is parallel to the second conformal section, the first conformal section and the second conformal section are not in direct contact with one another, and wherein the first conformal section and the second conformal section are configured to receive a cooling fluid; and (2) a fluid supply section configured to provide fluidic communication with both the first conformal section and the second conformal section, wherein the fluid supply section comprises; (i) a first opening configured to allow the cooling fluid to flow into the shell; and (ii) a second opening configured to allow the cooling fluid to flow out of the shell; and (b) an array of fins disposed within the first conformal section and the second conformal section, wherein the array of fins provides a path through which the cooling fluid can flow and wherein the array of fins is in thermal communication with the shell.

In some embodiments, the array of fins comprises a first set of fins and a second set of fins, wherein the first set of fins and the second set of fins are provided in a staggered arrangement.

In some embodiments of any one of the thermal management device disclosed herein, the array of fins comprises a plurality of fins with one or more turbulating features disposed on a surface of one or more fins of the plurality of fins.

In some embodiments of any one of the thermal management device disclosed herein, the array of fins comprises one or more jagged fins that extend upwards from the surface of the plate in a zigzag pattern.

In some embodiments of any one of the thermal management device disclosed herein, the array of fins comprises a plurality of tapered fins.

In some embodiments of any one of the thermal management device disclosed herein, the thermal management device further comprises one or more turbulating fins configured to enhance turbulence within the cooling fluid when the cooling fluid flows through the array of fins.

In some embodiments of any one of the thermal management device disclosed herein, the shell is configured to operatively couple to an integrated circuit module (ICM), to facilitate a transfer of thermal energy (i) from a first surface of the ICM to the first conformal section of the shell and (ii) from a second surface of the ICM to the second conformal section of the shell.

In another aspect, the present disclosure provides a thermal management device, comprising: a first portion configured to operatively couple to at least a portion of an edge of an integrated circuit module (ICM); a second portion configured to facilitate a transfer of thermal energy from a surface of the ICM to a surface of the second portion, or vice versa, wherein the first portion and the second portion are not on a same plane; and at least one fluid flow path in thermal contact with the second portion and configured to facilitate a transfer of the thermal energy from the second portion to a cooling fluid disposed within the at least one fluid flow path.

In some embodiments, the first portion is in fluid communication with the second portion. In some embodiments of any one of the thermal management device disclosed herein, the first portion comprises an inlet and an outlet, wherein the at least one fluid flow path is in fluid communication with the inlet and the outlet.

In some embodiments of any one of the thermal management device disclosed herein, the at least one fluid flow path is disposed within the second portion.

In some embodiments of any one of the thermal management device disclosed herein, the first portion is coupled to the second portion.

In some embodiments of any one of the thermal management device disclosed herein, the first portion is disposed substantially perpendicular to the second portion.

In another aspect, the present disclosure provides a thermal management device, comprising: a first conformal portion configured to facilitate a transfer of thermal energy from a first portion of a surface of an integrated circuit module (ICM); and a second conformal portion configured to facilitate a transfer of thermal energy from a second portion of the surface of the ICM, wherein (i) the first portion and the second portion of the surface of the ICM have different heights relative to each other, and (ii) the first conformal portion and the second conformation portion of the thermal management device have different heights relative to each other, corresponding to the different heights of the first portion and the second portion of the surface of the ICM.

In some embodiments, the first conformal portion and the second conformal portion are coupled to each other.

In some embodiments of any one of the thermal management device disclosed herein, the first conformal portion and the second conformal portion are thermally coupled to each other.

In some embodiments of any one of the thermal management device disclosed herein, (i) the first conformal portion comprises a first fluid flow path configured to facilitate a transfer of the thermal energy from the first portion of the surface of the ICM to a cooling fluid disposed within the first fluid flow path; and (ii) the second conformal portion comprises a second fluid flow path configured to facilitate a transfer of the thermal energy from the second portion of the surface of the ICM to a cooling fluid disposed within the second fluid flow path. In some embodiments, the first fluid flow path is in fluid communication with the second fluid flow path. In some embodiments, a flow rate of the cooling fluid across the first fluid flow path and a flow rate of the cooling fluid across the second fluid flow path are different.

In some embodiments of any one of the thermal management device disclosed herein, a thermal resistivity of the first conformal portion and a thermal resistivity of the second conformal portion are different.

In some embodiments of any one of the thermal management device disclosed herein, an area of the first conformal portion and an area of the second conformal portion are different.

In some embodiments of any one of the thermal management device disclosed herein, the first conformal portion and the second conformal portion are on a same side of the thermal management device.

In another aspect, the present disclosure provides a thermal management device, comprising: a portion of a housing, wherein the portion is configured to facilitate a transfer of a thermal energy from a surface of an integrated circuit module (ICM) to a surface of the portion, or vice versa; and a plurality of channels disposed within the portion, wherein the plurality of channels is configured to provide a fluid flow path in thermal contact with the portion, wherein the fluid flow path is configured to facilitate a transfer of the thermal energy from the portion to a cooling fluid disposed within the fluid flow path.

In some embodiments, the thermal management device further comprises: (i) an additional portion of the housing, wherein the additional portion is configured to facilitate a transfer of an additional thermal energy from an additional surface of the ICM to a surface of the additional portion, or vice versa; and (ii) an additional plurality of channels disposed within the additional portion, wherein the additional plurality of channels is configured to provide an additional fluid flow path in thermal contact with the additional portion, wherein the additional fluid flow path is configured to facilitate a transfer of the additional thermal energy from the additional portion to a cooling fluid disposed within the additional fluid flow path. In some embodiments of any one of the thermal management device disclosed herein, the surface of the portion and the additional surface of the additional portion are not in direct contact with each other. In some embodiments of any one of the thermal management device disclosed herein, the surface of the portion and the additional surface of the additional portion are substantially parallel to each other. In some embodiments of any one of the thermal management device disclosed herein, the housing is a shell-like body, and the portion and the additional portion are two respective sidewalls of the shell-like body. In some embodiments of any one of the thermal management device disclosed herein, the fluid flow path and the additional fluid flow path are in fluid communication with a same fluid supply channel. In some embodiments of any one of the thermal management device disclosed herein, the same fluid supply channel is disposed within the housing.

In some embodiments of any one of the thermal management device disclosed herein, the plurality of channels or the additional plurality of channels comprises an array of fins.

In some embodiments of any one of the thermal management device disclosed herein, the thermal management device is configured to releasably couple to the ICM.

In some embodiments of any one of the thermal management device disclosed herein, the ICM is a computer memory module.

In some embodiments of any one of the thermal management device disclosed herein, the thermal management device is operatively coupled to the ICM.

In another aspect, the present disclosure provides a method for thermal management, comprising operatively coupling a thermal management device to an integrated circuit module (ICM), wherein the thermal management device comprises: (a) a shell comprising: (1) a first conformal section and a second conformal section, wherein the first conformal section is parallel to the second conformal section, the first conformal section and the second conformal section are not in direct contact with one another, and wherein the first conformal section and the second conformal section are configured to receive a cooling fluid; and (2) a fluid supply section configured to provide fluidic communication with both the first conformal section and the second conformal section, wherein the fluid supply section comprises; (i) a first opening configured to allow the cooling fluid to flow into the shell; and (ii) a second opening configured to allow the cooling fluid to flow out of the shell; and (b) an array of fins disposed within the first conformal section and the second conformal section, wherein the array of fins provides a path through which the cooling fluid can flow and wherein the array of fins is in thermal communication with the shell.

In some embodiments, the method further comprises providing the cooling fluid to the thermal management device.

In another aspect, the present disclosure provides a method for thermal management, comprising operatively coupling (i) a thermal management device to (ii) an integrated circuit module (ICM), wherein the thermal management device comprises: a first portion configured to operatively couple to at least a portion of an edge of the ICM; a second portion configured to facilitate a transfer of thermal energy from a surface of the ICM to a surface of the second portion, or vice versa, wherein the first portion and the second portion are not on a same plane; and at least one fluid flow path in thermal contact with the second portion and configured to facilitate a transfer of the thermal energy from the second portion to a cooling fluid disposed within the at least one fluid flow path.

In some embodiments, the method further comprises providing the cooling fluid to the thermal management device.

In another aspect, the present disclosure provides a method for thermal management, comprising operatively coupling (i) a thermal management device to (ii) an integrated circuit module (ICM), wherein the thermal management device comprises: a first conformal portion configured to facilitate a transfer of thermal energy from a first portion of a surface of the ICM; and a second conformal portion configured to facilitate a transfer of thermal energy from a second portion of the surface of the ICM, wherein (i) the first portion and the second portion of the surface of the ICM have different heights relative to each other, and (ii) the first conformal portion and the second conformation portion of the thermal management device have different heights relative to each other, corresponding to the different heights of the first portion and the second portion of the surface of the ICM.

In some embodiments, (i) the first conformal portion comprises a first fluid flow path configured to facilitate a transfer of the thermal energy from the first portion of the surface of the ICM to a cooling fluid disposed within the first fluid flow path; or (ii) the second conformal portion comprises a second fluid flow path configured to facilitate a transfer of the thermal energy from the second portion of the surface of the ICM to a cooling fluid disposed within the second fluid flow path, wherein the method further comprises providing the cooling fluid to the thermal management device.

In another aspect, the present disclosure provides a method for thermal management, comprising operatively coupling (i) a thermal management device to (ii) an integrated circuit module (ICM), wherein the thermal management device comprises: a portion of a housing, wherein the portion is configured to facilitate a transfer of a thermal energy from a surface of an integrated circuit module (ICM) to a surface of the portion, or vice versa; and a plurality of channels disposed within the portion, wherein the plurality of channels is configured to provide a fluid flow path in thermal contact with the portion, wherein the fluid flow path is configured to facilitate a transfer of the thermal energy from the portion to a cooling fluid disposed within the fluid flow path.

In some embodiments, the method further comprises providing the cooling fluid to the thermal management device.

In another aspect, the present disclosure provides a thermal management device, comprising: (i) a base plate configured to be in thermal communication with a heat source or a heat sink; and (ii) a plurality of fins disposed on a surface of the base plate, wherein a surface of at least one fin of the plurality of fins comprises a first depression and a second depression located above the first depression, wherein the first depression and the second depression are configured to generate one or more vortices in a flow of a working fluid, wherein the plurality of fins form a fluid flow path such that the first depression and the second depression disrupt a boundary layer of the flow of the working fluid along the fluid flow path.

In some embodiments, the surface of the at least one fin comprises a plurality of depressions comprising a first set of depressions disposed at a first height and a second set of depressions disposed at a second height.

In some embodiments of any one of the thermal management devices disclosed herein, the plurality of depressions comprise a semi-circular shape, a circular shape, a triangular shape, a rectangular shape, or a scoop shape.

In some embodiments of any one of the thermal management devices disclosed herein, the plurality of depressions are symmetric or asymmetric.

In some embodiments of any one of the thermal management devices disclosed herein, a density of the plurality of depressions is variable or constant across the surface of the at least one fin.

In some embodiments of any one of the thermal management devices disclosed herein, the plurality of depressions are continuous or discontinuous along a reference axis.

In some embodiments of any one of the thermal management devices disclosed herein, the plurality of depressions are periodic or aperiodic. In some embodiments, the reference axis corresponds to a direction of flow of the working fluid or a direction that is different than a direction of flow of the working fluid.

In some embodiments of any one of the thermal management devices disclosed herein, the plurality of depressions are offset or staggered.

In some embodiments of any one of the thermal management devices disclosed herein, the plurality of fins comprise a first fin with a depression and a second fin with a depression, wherein the depression of the first fin is aligned or not aligned with the depression of the second fin.

In some embodiments of any one of the thermal management devices disclosed herein, the plurality of fins are straight or tapered.

In some embodiments of any one of the thermal management devices disclosed herein, a fin thickness or fin gap of the plurality of fins is variable.

In some embodiments of any one of the thermal management devices disclosed herein, the plurality of fins are straight, wavy, discontinuous straight, or wavy with breaks.

In another aspect, the present disclosure provides a method for thermal management, comprising: (a) providing a thermal management device comprising: (i) a base plate configured to be in thermal communication with a heat source or a heat sink; and (ii) a plurality of fins disposed on a surface of the base plate, wherein a surface of at least one fin of the plurality of fins comprises a first depression and a second depression located above the first depression, wherein the first depression and the second depression are configured to generate one or more vortices in a flow of a working fluid, wherein the plurality of fins form a fluid flow path such that the first depression and the second depression disrupt a boundary layer of the flow of the working fluid along the fluid flow path; and (b) directing the working fluid along the fluid flow path to facilitate a transfer of thermal energy from at least a subset of the plurality of fins to the working fluid, or from the working fluid to at least the subset of the plurality of fins.

In some embodiments, the surface of the at least one fin comprises a plurality of depressions comprising a first set of depressions disposed at a first height and a second set of depressions disposed at a second height.

In some embodiments of any one of the methods disclosed herein, the plurality of depressions comprise a semi-circular shape, a circular shape, a triangular shape, a rectangular shape, or a scoop shape.

In some embodiments of any one of the methods disclosed herein, the plurality of depressions are symmetric or asymmetric.

In some embodiments of any one of the methods disclosed herein, a density of the plurality of depressions is variable or constant across the surface of the at least one fin.

In some embodiments of any one of the methods disclosed herein, the plurality of depressions are continuous or discontinuous along a reference axis.

In some embodiments of any one of the methods disclosed herein, the plurality of depressions are periodic or aperiodic. In some embodiments, the reference axis corresponds to a direction of flow of the working fluid or a direction that is different than a direction of flow of the working fluid.

In some embodiments of any one of the methods disclosed herein, the plurality of depressions are offset or staggered.

In some embodiments of any one of the methods disclosed herein, the plurality of fins comprise a first fin with a depression and a second fin with a depression, wherein the depression of the first fin is aligned or not aligned with the depression of the second fin.

In some embodiments of any one of the methods disclosed herein, the plurality of fins are straight or tapered.

In some embodiments of any one of the methods disclosed herein, a fin thickness or fin gap of the plurality of fins is variable.

In some embodiments of any one of the methods disclosed herein, the plurality of fins are straight, wavy, discontinuous straight, or wavy with breaks.

In another aspect, the present disclosure provides a thermal management device, comprising: (i) a base plate configured to be in thermal communication with a heat source or a heat sink; and (ii) a plurality of fins in thermal communication with the base plate, wherein a surface of at least one fin of the plurality of fins comprises a plurality of protrusions configured to disrupt a flow of a working fluid, wherein the at least one fin comprises a non-linear shape or profile, wherein the plurality of fins form a fluid flow path such that the plurality of protrusions disrupt the flow of the working fluid along the fluid flow path.

In some embodiments, the plurality of fins comprise a plurality of wavy fins.

In some embodiments of any one of the thermal management devices disclosed herein, the plurality of wavy fins comprise a wave shape extending along a direction of flow of the working fluid. In some embodiments of any one of the thermal management devices disclosed herein, the plurality of wavy fins comprise a wave shape extending along a transverse direction that is perpendicular or normal to a direction of flow of the working fluid. In some embodiments of any one of the thermal management devices disclosed herein, the plurality of wavy fins have a same or variable amplitude or frequency. In some embodiments of any one of the thermal management devices disclosed herein, the plurality of wavy fins comprise a uniform or non-uniform amplitude or frequency.

In some embodiments of any one of the thermal management devices disclosed herein, the plurality of protrusions are non-uniformly distributed in a direction of flow of the working fluid or a transverse direction that is perpendicular or normal to the direction of flow of the working fluid.

In some embodiments of any one of the thermal management devices disclosed herein, the plurality of fins comprise a set of planar fins and a set of wavy fins.

In some embodiments of any one of the thermal management devices disclosed herein, the plurality of fins comprise a first region comprising a set of planar fins and a second region comprising a set of wavy fins.

In some embodiments of any one of the thermal management devices disclosed herein, the plurality of fins comprise at least one fin comprising a wavy portion and a linear portion.

In some embodiments of any one of the thermal management devices disclosed herein, the plurality of protrusions comprise a triangular profile, straight profile, a square profile, or a diamond profile.

In some embodiments of any one of the thermal management devices disclosed herein, (i) one or more protrusions of the plurality of protrusions of the at least one fin is not in direct contact with (ii) one or more protrusions of an additional fin of the plurality of fins.

In another aspect, the present disclosure provides a method for thermal management, comprising: (a) providing a thermal management device comprising: (i) a base plate configured to be in thermal communication with a heat source or a heat sink; and (ii) a plurality of fins in thermal communication with the base plate, wherein a surface of at least one fin of the plurality of fins comprises a plurality of protrusions configured to disrupt a flow of a working fluid, wherein the at least one fin comprises a non-linear shape or profile; wherein the plurality of fins form a fluid flow path such that the plurality of protrusions disrupt the flow of the working fluid along the fluid flow path; and (b) directing the working fluid along the fluid flow path to facilitate a transfer of thermal energy from at least a subset of the plurality of fins to the working fluid, or from the working fluid to at least the subset of the plurality of fins.

In some embodiments, the plurality of fins comprise a plurality of wavy fins.

In some embodiments of any one of the methods disclosed herein, the plurality of wavy fins comprise a wave shape extending along a direction of flow of the working fluid. In some embodiments of any one of the methods disclosed herein, the plurality of wavy fins comprise a wave shape extending along a transverse direction that is perpendicular or normal to a direction of flow of the working fluid. In some embodiments of any one of the methods disclosed herein, the plurality of wavy fins have a same or variable amplitude or frequency. In some embodiments of any one of the methods disclosed herein, the plurality of wavy fins comprise a uniform or non-uniform amplitude or frequency.

In some embodiments of any one of the methods disclosed herein, the plurality of protrusions are non-uniformly distributed in a direction of flow of the working fluid or a transverse direction that is perpendicular or normal to the direction of flow of the working fluid.

In some embodiments of any one of the methods disclosed herein, the plurality of fins comprise a set of planar fins and a set of wavy fins.

In some embodiments of any one of the methods disclosed herein, the plurality of fins comprise a first region comprising a set of planar fins and a second region comprising a set of wavy fins.

In some embodiments of any one of the methods disclosed herein, the plurality of fins comprise at least one fin comprising a wavy portion and a linear portion.

In some embodiments of any one of the methods disclosed herein, the plurality of protrusions comprise a triangular profile, straight profile, a square profile, or a diamond profile.

In some embodiments of any one of the methods disclosed herein, (i) one or more protrusions of the plurality of protrusions of the at least one fin is not in direct contact with (ii) one or more protrusions of an additional fin of the plurality of fins.

In another aspect, the present disclosure provides a thermal management device, comprising: (i) a base plate configured to be in thermal communication with a heat source or a heat sink; and (ii) a plurality of pins in thermal communication with the base plate, wherein the plurality of pins is configured to provide a fluid flow path that directs a working fluid (i) along a length of the plurality of pins and (ii) across a surface of the base plate, wherein a property or a characteristic of the plurality of pins varies along the fluid flow path provided by the plurality of pins.

In some embodiments, the property or characteristic comprises a pin size, a pin shape, a pin density, or a pin spacing.

In some embodiments of any one of the thermal management devices disclosed herein, the thermal management device further comprises an inlet configured to receive the working fluid, wherein a height of the plurality of pins varies based on a proximity of the pins to the inlet.

In some embodiments of any one of the thermal management devices disclosed herein, the plurality of pins comprise a round shape, a rectangular shape, an elliptical shape, or a triangular shape.

In some embodiments of any one of the thermal management devices disclosed herein, a pin size and a pin gap of the plurality of pins varies along a length or a width of the base plate. In some embodiments, the plurality of pins comprise (i) a first set of pins adjacent to an upstream region of a fluid flow path of the working fluid and (ii) a second set of pins adjacent to a downstream region of the fluid flow path of the working fluid, wherein the first set of pins are smaller and more densely packed than the second set of pins.

In some embodiments of any one of the thermal management devices disclosed herein, the plurality of pins comprise a plurality of regions comprising different types of pins.

In some embodiments of any one of the thermal management devices disclosed herein, the plurality of pins are oriented at an angle relative to the surface of the base plate to aid in fluid routing and pickup, wherein the angle is less than or equal to 90 degrees.

In some embodiments of any one of the thermal management devices disclosed herein, the plurality of pins are oriented at an angle relative to the surface of the base plate to aid in fluid routing and pickup, wherein the angle is greater than or equal to 90 degrees.

In some embodiments of any one of the thermal management devices disclosed herein, the plurality of pins are spatially distributed to provide one or more cutout regions for flow impingement.

In some embodiments of any one of the thermal management devices disclosed herein, the fluid flow path along the plurality of pins is configured to disrupt the flow of the working fluid to enhance or facilitate a transfer of thermal energy from (i) the plurality of pins to the working fluid or (ii) the working fluid to the plurality of pins.

In another aspect, the present disclosure provides a method for thermal management, comprising: (a) providing a thermal management device comprising: (i) a base plate configured to be in thermal communication with a heat source or a heat sink; and (ii) a plurality of pins in thermal communication with the base plate, wherein the plurality of pins is configured to provide a fluid flow path that directs a working fluid (i) along a length of the plurality of pins and (ii) across a surface of the base plate, wherein a property or a characteristic of the plurality of pins varies along the fluid flow path provided by the plurality of pins; and (b) directing the working fluid along the fluid flow path to facilitate a transfer of thermal energy from at least a subset of the plurality of pins to the working fluid, or from the working fluid to at least the subset of the plurality of pins.

In some embodiments, the property or characteristic comprises a pin size, a pin shape, a pin density, or a pin spacing.

In some embodiments of any one of the methods disclosed herein, the thermal management device further comprises an inlet configured to receive the working fluid, wherein a height of the plurality of pins varies based on a proximity of the pins to the inlet.

In some embodiments of any one of the methods disclosed herein, the plurality of pins comprise a round shape, a rectangular shape, an elliptical shape, or a triangular shape.

In some embodiments of any one of the methods disclosed herein, a pin size and a pin gap of the plurality of pins varies along a length or a width of the base plate. In some embodiments, the plurality of pins comprise (i) a first set of pins adjacent to an upstream region of a fluid flow path of the working fluid and (ii) a second set of pins adjacent to a downstream region of the fluid flow path of the working fluid, wherein the first set of pins are smaller and more densely packed than the second set of pins.

In some embodiments of any one of the methods disclosed herein, the plurality of pins comprise a plurality of regions comprising different types of pins.

In some embodiments of any one of the methods disclosed herein, the plurality of pins are oriented at an angle relative to the surface of the base plate to aid in fluid routing and pickup, wherein the angle is less than or equal to 90 degrees.

In some embodiments of any one of the methods disclosed herein, the plurality of pins are oriented at an angle relative to the surface of the base plate to aid in fluid routing and pickup, wherein the angle is greater than or equal to 90 degrees.

In some embodiments of any one of the methods disclosed herein, the plurality of pins are spatially distributed to provide one or more cutout regions for flow impingement.

In some embodiments of any one of the methods disclosed herein, the fluid flow path along the plurality of pins is configured to disrupt the flow of the working fluid to enhance or facilitate a transfer of thermal energy from (i) the plurality of pins to the working fluid or (ii) the working fluid to the plurality of pins.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1 schematically illustrates a perspective view of a jacketed cooling sleeve thermal management device in relation to an object to be cooled;

FIG. 2 schematically illustrates a lateral-section view of one conformal section of a jacketed cooling sleeve thermal management device;

FIG. 3 schematically illustrates a lateral-section view of one conformal section of a jacketed cooling sleeve thermal management device;

FIG. 4A schematically illustrates a schematic drawing that shows a jacketed cooling sleeve thermal management device that is configured to make thermal contact with devices that have different thicknesses;

FIG. 4B schematically illustrates a schematic drawing that shows a jacketed cooling sleeve thermal management device that is configured to make thermal contact with devices that have different thicknesses;

FIG. 5A schematically illustrates a schematic drawing that shows a jacketed cooling sleeve thermal management device that is configured to make thermal contact with devices that have different thicknesses;

FIG. 5B schematically illustrates a schematic drawing that shows a jacketed cooling sleeve thermal management device that is configured to make thermal contact with devices that have different thicknesses;

FIG. 6 schematically illustrates a schematic drawing that shows a series of jacketed cooling sleeve thermal management devices disposed onto a series of objects to be cooled;

FIG. 7 schematically illustrates a three-dimensional (3D) printing system usable to print at least a portion of a thermal management device;

FIGS. 8A and 8B schematically illustrate an example thermal management device comprising a fin having a plurality of depressions;

FIGS. 9A and 9B schematically illustrate another example thermal management device comprising a fin having a plurality of depressions;

FIG. 10A schematically illustrates an example thermal management device comprising a plurality of straight fins;

FIG. 10B schematically illustrates an example thermal management device comprising a plurality of fins with varied cross-sectional dimensions;

FIG. 11 schematically illustrates an example thermal management device comprising a plurality of wavy fins;

FIG. 12 schematically illustrates an example thermal management device comprising a plurality of fins comprising a plurality of protrusions on a surface of a wavy portion of the plurality of fins; and

FIGS. 13A-13C schematically illustrate an example thermal management device having variable pins under impingement.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The term “conformal section,” “conformal side,” “conformal unit,” “conformal portion,” or “conformal sleeve,” as disclosed herein, generally refers to a portion of a thermal management device (e.g., heat sink) that exhibit one or more complimentary features (e.g., a morphological feature, thermal resistivity, thermal conductivity, etc.) to facilitate a transfer of thermal energy from a surface of a source of heat, or vice versa. In some cases, a thermal management device can comprise two conformal sections configured to be operatively coupled to two morphological profiles (e.g., shapes, heights, areas, depths, etc.) of a heat-generating device. In some cases, a thermal management device can comprise two conformal sections exhibiting different heat transfer capacities (e.g., different heat resistivities) to be operatively coupled to two portions of a heat-generating device that, e.g., emit different amounts of heat. In some cases, two conformal sections may exhibit different heat transfer capacities (e.g., different heat resistivities) by having, for example, (i) different materials with different heat transfer capacities, (ii) different morphological profiles, and/or (iii) different internal structures (e.g., absence or presence of sub-channels or array of fins, design of the sub-channels or array of fins, etc.).

In some cases, a complimentary feature (e.g., shape, heat transfer capacity, etc.) of a conformal section of a thermal management device as disclosed herein may be adjustable during operation of the thermal management device. For example, a height of at least a portion of the conformal section may be adjustable. In another example, heat transfer capacity (e.g., thermal resistivity) of at least a portion of the conformal section may be adjustable, e.g., by modifying a flow rate of cooling fluid within the at least the portion of the conformal section, by modifying flow path of cooling fluid within the at least the portion of the conformal section, etc. Alternatively or in addition to, the complimentary feature of the conformal section of the thermal management device may not and need not be adjustable during operation of the thermal management device.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

The present disclosure provides thermal management devices formed by three-dimensional printing. Such devices, as printed, may be single-piece devices with unitary structures. For example, such devices may be substantially uniform, and may not include any seams on a surface of such devices and/or any material discontinuities within an internal structure of such devices. Such devices may have uniform grain structures. Such devices may have substantially ordered grains or grain boundaries.

Thermal Management Devices and Systems

The present disclosure provides various embodiments of a thermal management device. A thermal management device may be a heat sink. The heat sink can be configured to, for example, cool heat-generating devices (e.g., an integrated circuit module (ICM), such as a memory module). In some embodiments, the heat sink may fit conformally onto a heat-generating device, to remove heat (e.g., simultaneously) from two or more surfaces (e.g., two or more sides) of the heat-generating device.

Non-limiting examples of a heat-generating device can include electronic systems or mechanical systems (e.g., thermal control systems, energy storage systems, heat recovery systems, energy conversion systems, etc.) that may generate heat during their operation. In some cases, as such systems become more complex (e.g., in design, components, operations, etc.), the systems may generate even more heat, or generate more heat on a per unit area basis. As such, thermal management devices as disclosed herein may be used to regulate or manage temperatures of such systems (e.g., dissipate heat from the systems) prior to, during, or subsequent to their operations. In some examples, the thermal management devices as disclosed herein may dissipate heat from one or more surfaces (e.g., more than one sides) of a heat-generating device.

A heat-generating device can be a high-performance electrical equipment. A heat-generating device can comprise a computer motherboard. A computer motherboard may be a printed circuit board (PCB) comprising one or more major components of a computer, such as a central processing unit (CPU), random-access memory (RAM), artificial intelligence (AI) accelerators, power semiconductors, etc. A computer motherboard may allocate power and allow communication among the one or more major components and additional hardware component(s). In some cases, such components may generate heat during operation and require cooling. As such, the thermal management devices disclosed herein, for example, may be arranged parallel to at least a portion of the computer motherboard. Alternatively or in addition to, the thermal management devices disclosed herein may be arranged perpendicular to at least a portion of the computer motherboard. Three-dimensional (3D) printing (e.g., additive manufacturing) may be utilized to fabricate thermal management device comprising one or more fluid channels that are, e.g., small enough to make contact (e.g., thermal contact) with two or more sides of a component of the motherboard, even for a motherboard comprising a plurality of such components parallel to one another. In some cases, continuing trends of electronics miniaturization and performance improvement can lead to continually-increasing packaging density of semiconductors in electronics systems. Increased packaging density can lead to increased heat fluxes. Thus, there is an unmet need for thermal management systems to regulate thermal energy from such electronic systems.

In some aspects, the present disclosure provides thermal management devices with microstructures designed for enhancing the thermal performance of liquid cooled devices. In some aspects, the present disclosure provides utilizing additive manufacturing methods or three-dimensional (3D) printing methods for generating enhanced thermal management with improved thermal performance at reduced pressure drop penalties. In some cases, the thermal management devices of the present disclosure may be usable in, for example, data centers, high performance computing devices, power semiconductors, and other high performance electronic systems.

In an aspect, the present disclosure provides thermal management device. The thermal management device may comprise a first portion configured to operatively couple to at least a portion of an edge of a heat generating device. The thermal management device may further comprise a second portion configured to facilitate a transfer of thermal energy from a surface of the heat generating device to a surface of the second portion, or vice versa, wherein the first portion and the second portion are not on a same plane. The thermal management device may further comprise at least one fluid flow path in thermal contact with the second portion. The at least one fluid flow path may be configured to facilitate a transfer of the thermal energy from the second portion to a cooling fluid disposed within the at least one fluid flow path.

In some cases, a thermal management device of the present disclosure may comprise a first portion of a housing configured to operatively couple to at least a portion of an edge of an integrated circuit module (ICM). The thermal management device may further comprise a second portion of the housing configured to facilitate a transfer of thermal energy from a surface of the ICM to a surface of the second portion, or vice versa, wherein the first portion and the second portion are not on a same plane. The thermal management device may further comprise at least one fluid flow path in thermal contact with the second portion. The at least one fluid flow path may be configured to facilitate a transfer of the thermal energy from the second portion to a cooling fluid disposed within the at least one fluid flow path.

The housing of the thermal management device as disclosed herein may comprise at least 1, 2, 3, 4, 5, 6, 7, 8, 9. 10, or more sides (or walls). The housing of the thermal management device may comprise at most 10, 9, 8, 7, 6, 5, 4, 3, 2, or 1 side. The housing of the thermal management device may comprise two or more sides that are coupled to each other (e.g., directly coupled to each other, non-directly coupled to each other, thermally coupled to each other, etc.). In some cases, a side of the housing may couple two additional sides of the housing (e.g., a shell-like body, a box-like body, etc.).

In some cases, the walls of the housing of the thermal management device as disclosed herein may enclose the housing, Alternatively, the walls of the housing may not enclose the housing, such that the housing comprises an opening. Yet in another alternative, the housing may comprise a sealable opening, e.g., via one or more movable wall.

In some cases, the housing of the thermal management device as disclosed herein may comprise a shell-like body (i.e., a sleeve or a jacketed cooling sleeve, as used interchangeably herein). The first portion of the housing may be a base (e.g., a bottom portion between and coupled to two sidewalls) of the shell-like body. The second portion of the housing may be a sidewall of the shell-like body. In some cases, the first portion of the housing (e.g., the base) may be coupled to (or connected to) the second portion of the housing (e.g., the sidewall).

In some cases, the first portion of the housing may be disposed non-parallel to the second portion of the housing. An angle between the first portion and the second portion may be less than 180 degrees. The angle between the first portion and the second portion may be less than 180 degrees, less than about 170 degrees, less than about 160 degrees, less than about 150 degrees, less than about 140 degrees, less than about 130 degrees, less than about 120 degrees, less than about 110 degrees, less than about 100 degrees, less than about 90 degrees, less than about 80 degrees, less than about 70 degrees, or less than about 60 degrees. For example, the first portion and the second portion may be disposed substantially perpendicular (or about 90 degrees) to one another.

In some cases, the first portion of the housing of the thermal management device may be in fluid communication with the second portion, e.g., via one or more channels disposed within the first portion and the second portion configured to permit flow of a cooling fluid (e.g., liquid, gas) there between. In some cases, the first portion may comprise an inlet and an outlet, and the at least one fluid flow path may be in fluid communication with the inlet and the outlet. The first portion may comprise one or more fluid channels (e.g., at least 1, 2, 3, 4, 5, or more fluid channels) in fluid communication with the inlet and the outlet. The first portion may comprise at least 1, 2, 3, 4, 5, or more inlets. The first portion may comprise at most 5, 4, 3, 2, or 1 inlet. The first portion may comprise at least 1, 2, 3, 4, 5, or more outlets. The first portion may comprise at most 5, 4, 3, 2, or 1 outlet. In the first portion, a fluid channel between an inlet and an outlet may be straight. Alternatively, such fluid channel may not and need not be straight, e.g., curved, jagged, etc. In some examples, the at least one fluid flow path may be within the second portion of the housing of the thermal management device. The at least one fluid flow path may be in direct fluid communication with the inlet and/or the outlet. Alternatively, the at least one fluid flow path may be in indirect fluid communication with the inlet and/or the outlet, e.g., via being in direct fluid communication with a fluid channel of the first portion that is connected to the inlet and/or the outlet. In some examples, the inlet and the outlet of the first portion of the housing may be in fluid communication with each other via the at least one fluid flow channel of the second portion of the housing.

In another aspect, the present disclosure provides a thermal management device. The thermal management device may comprise a first conformal portion configured to facilitate a transfer of thermal energy from a first portion of a surface of a heat generating device. The thermal management device may further comprise a second conformal portion configured to facilitate a transfer of thermal energy from a second portion of the surface of the heat generating device. In some cases, the first portion and the second portion of the surface of the heat generating device may have different features (e.g., different shapes, such as different heights) relative to each other. In some cases, the first conformal portion and the second conformation portion of the thermal management device may have different features (e.g., different shapes, such as different heights) relative to each other, corresponding to the different features of the first portion and the second portion of the surface of the heat generating device.

In some cases, a thermal management device of the present disclosure may comprise a first conformal portion of a housing configured to facilitate a transfer of thermal energy from a first portion of a surface of an ICM. The thermal management device may further comprise a second conformal portion of the housing configured to facilitate a transfer of thermal energy from a second portion of the surface of the ICM. In some cases, the first portion and the second portion of the surface of the ICM may have different features (e.g., different shapes, such as different heights) relative to each other. In some cases, the first conformal portion and the second conformation portion of the housing of the thermal management device may have different features (e.g., different shapes, such as different heights) relative to each other, corresponding to the different features of the first portion and the second portion of the surface of the ICM.

In some cases, the housing of the thermal management device as disclosed herein may comprise a shell-like body. The shell-like body may comprise a base and two sidewalls coupled to each other via the base. In some cases, the first conformal portion and the second conformation portion of the housing of the thermal management device may be parts of a same sidewall of the shell-like body. In some cases, the first conformal portion and the second conformation portion of the housing of the thermal management device may be parts of a same surface of the same sidewall of the shell-like body.

In some cases, the first conformal portion and the second conformal portion may be coupled to each other. Alternatively, the first conformal portion and a second conformal portion may be indirectly coupled to each other via an additional portion of the housing of the thermal management device.

In some cases, the first conformal portion and the second conformal portion may be thermally coupled to each other. Alternatively, the first conformal portion and a second conformal portion may be indirectly thermally coupled to each other via an additional portion of the housing of the thermal management device. The first conformal portion may facilitate a transfer of thermal energy from the second conformal portion, or vice versa, via one or more fluid flow paths.

In some cases, the first conformal portion may comprise a first fluid flow path configured to facilitate a transfer of the thermal energy from the first portion of the surface of the ICM to a cooling fluid disposed within the first fluid flow path. The second conformal portion may comprise a second fluid flow path configured to facilitate a transfer of the thermal energy from the second portion of the surface of the ICM to a cooling fluid disposed within the second fluid flow path. The first fluid flow path may be in fluid communication with the second fluid flow path. The thermal management device may comprise at least 1, 2, 3, 4, 5, or more channels connecting the first fluid flow path and the second fluid flow path. The thermal management device may comprise at most 5, 4, 3, 2, or 1 channel connecting the first fluid flow path and the second fluid flow path.

In some cases, a flow rate (or a flow resistivity) of the cooling fluid across the first fluid flow path and a flow rate of the cooling fluid across the second fluid flow path may be different. In some examples, such difference may be due to different designs or architectures (e.g., length, shape, curvature, cross-sectional diameter, thickness, a number of sub-channels, etc.) of the first fluid flow path and the second fluid flow path. Alternatively or in addition to, the such difference in the flow rate may be regulated by one or more flow regulators (e.g., at least 1, 2, 3, 4, 5, or more flow valves) in fluid communication with the first fluid flow path or the second fluid flow path. The one or more flow regulators may be coupled to an entry orifice of the first fluid flow path or the second fluid flow path. Alternatively or in addition to, the one or more flow regulators may be disposed within the first fluid flow path or the second fluid flow path. A flow rate (or flow resistivity) of the cooling fluid across the first fluid flow path may be greater than a flow rate (or flow resistivity) of the cooling fluid across the second fluid flow path by at least about 1 percent (%), 2%, 3%, 4%, 5%, 10%, 15%, 20%, 30%, 40%, 50%, 60%, 70%, 80%, 90%, 100%, 150%, 200%, 300%, 400%, 500%, or more. A flow rate (or flow resistivity) of the cooling fluid across the first fluid flow path may be greater than a flow rate (or flow resistivity) of the cooling fluid across the second fluid flow path by at most about 500%, 400%, 300%, 00%, 150%, 100%, 90%, 80%, 70%, 60%, 50%, 40%, 30%, 20%, 15%, 10%, 5%, 4%, 3%, 2%, 1% or less.

Alternatively, a flow rate (or a flow resistivity) of the cooling fluid across the first fluid flow path and a flow rate of the cooling fluid across the second fluid flow path may not be different.

In some cases, a thermal resistivity of the first conformal portion and a thermal resistivity of the second conformal portion may be different. In some examples, such difference may be due to different designs or architectures (e.g., length, shape, curvature, cross-sectional diameter, thickness, a number of sub-channels, etc.) of the first fluid flow path and the second fluid flow path.

Alternatively or in addition to, the difference in the thermal resistivity may be due at least in part to the first conformal portion and the second conformal portion having different materials having different thermal resistivities. A thermal resistivity of the first conformal portion may be greater than a thermal resistivity of the second conformal portion by at least about 1%, 2%, 3%, 4%, 5%, 10%, 15%, 20%, 30%, 40%, 50%, 60%, 70%, 80%, 90%, 100%, 150%, 200%, 300%, 400%, 500%, or more. A thermal resistivity of the first conformal portion may be greater than a thermal resistivity of the second conformal portion by at most about 500%, 400%, 300%, 00%, 150%, 100%, 90%, 80%, 70%, 60%, 50%, 40%, 30%, 20%, 15%, 10%, 5%, 4%, 3%, 2%, 1% or less.

Alternatively, a thermal resistivity of the first conformal portion and a thermal resistivity of the second conformal portion may not be different.

In some cases, a height of the first conformal portion and a height of the second conformal portion may be different. A height of the first conformal portion relative to the housing (e.g., relative to a reference point, line, or plane of the housing) may be greater than a height of the second conformal portion relative to the housing by at least about 1%, 2%, 3%, 4%, 5%, 10%, 15%, 20%, 30%, 40%, 50%, 60%, 70%, 80%, 90%, 100%, 150%, 200%, 300%, 400%, 500%, or more. A height of the first conformal portion relative to the housing (e.g., relative to a reference point, line, or plane of the housing) may be greater than a height of the second conformal portion relative to the housing by at most about 500%, 400%, 300%, 00%, 150%, 100%, 90%, 80%, 70%, 60%, 50%, 40%, 30%, 20%, 15%, 10%, 5%, 4%, 3%, 2%, 1% or less.

Alternatively, a height of the first conformal portion and a height of the second conformal portion may not be different.

In some cases, a surface area of the first conformal portion and a surface area of the second conformal portion may be different. A surface area of the first conformal portion may be greater than a surface area of the second conformal portion relative to the housing by at least about 1%, 2%, 3%, 4%, 5%, 10%, 15%, 20%, 30%, 40%, 50%, 60%, 70%, 80%, 90%, 100%, 150%, 200%, 300%, 400%, 500%, or more. A surface area of the first conformal portion may be greater than a surface area of the second conformal portion relative to the housing by at most about 500%, 400%, 300%, 00%, 150%, 100%, 90%, 80%, 70%, 60%, 50%, 40%, 30%, 20%, 15%, 10%, 5%, 4%, 3%, 2%, 1% or less.

Alternatively, a surface area of the first conformal portion and a surface area of the second conformal portion may not be different.

In another aspect, the present disclosure provides a thermal management device. The thermal management device may comprise a first portion configured to facilitate a transfer of a first thermal energy from a first surface of a heat generating device to a surface of the first portion, or vice versa. The thermal management device may further comprise a first plurality of channels disposed within the first portion. The first plurality of channels may be configured to provide a first fluid flow path in thermal contact with the first portion. The first fluid flow path may be configured to facilitate a transfer of the first thermal energy from the first portion to a cooling fluid disposed within the first fluid flow path.

In some cases, a thermal management device of the present disclosure may comprise a first portion of a housing configured to facilitate a transfer of a first thermal energy from a first surface of an ICM to a surface of the first portion, or vice versa. The thermal management device may further comprise a first plurality of channels disposed within the first portion. The first plurality of channels may be configured to provide a first fluid flow path in thermal contact with the first portion. The first fluid flow path may be configured to facilitate a transfer of the first thermal energy from the first portion to a cooling fluid disposed within the first fluid flow path.

In some cases, the thermal management device may further comprise a second portion of the housing. The second portion may be configured to facilitate a transfer of a second thermal energy from a second surface of the ICM to a surface of the second portion, or vice versa. The thermal management device may further comprise a second plurality of channels disposed within the second portion. The second plurality of channels may be configured to provide a second fluid flow path in thermal contact with the second portion. The second fluid flow path may be configured to facilitate a transfer of the second thermal energy from the second portion to a cooling fluid disposed within the second fluid flow path.

In some cases, the housing of the thermal management device as disclosed herein may comprise a shell-like body. The shell-like body may comprise a base and two sidewalls coupled to each other via the base. In some cases, the first portion and the second portion of the housing of the thermal management device may be two different sidewalls of the shell-like body. In some cases, the first surface of the first portion and the second surface of the second portion may be substantially parallel to each other.

In some cases, the surface of the first portion and the surface of the second portion may face each other. Alternatively, the surface of the first portion and the surface of the second portion may not face each other. In some cases, the surface of the first portion and the surface of the second portion may be in direct contact with each other. Alternatively, the surface of the first portion and the surface of the second portion may not be in direct contact with each other (e.g., may be connected via an additional portion of the thermal management device, e.g., via a “base” portion of the shell-like shape). In some cases, the surface of the first portion and the surface of the second portion may be in direct thermal contact with each other. Alternatively, the surface of the first portion and the surface of the second portion may not be in direct thermal contact with each other (e.g., may be connected via an additional medium for thermal transfer between each other). Yet in another alternative, the surface of the first portion and the surface of the second portion may not be in thermal contact with each other.

In some cases, the first surface of the first portion and the second surface of the second portion may not touch each other. In some cases, a distance between the first surface of the first portion and the second surface of the second portion may be at least about 0.1 millimeter (mm), 0.2 mm, 0.3 mm, 0.4 mm, 0.5 mm, 0.6 mm, 0.7 mm, 0.8 mm, 0.9 mm, 1 mm, 2 mm, 3 mm, 4 mm, 5 mm, 6 mm, 7 mm, 8 mm, 9 mm, 1 centimeter (cm), 2 cm, 3 cm, 4 cm, 5 cm, or more. A distance between the first surface of the first portion and the second surface of the second portion may be at most about 5 cm, 4 cm, 3 cm, 2 cm, 1 cm, 9 mm, 8 mm, 7 mm, 6 mm, 5 mm, 4 mm, 3 mm, 2 mm, 1 mm, 0.9 mm, 0.8 mm, 0.7 mm, 0.6 mm, 0.5 mm, 0.4 mm, 0.3 mm, 0.2 mm, 0.1 mm, or less.

In some cases, wherein the first fluid flow path and the second fluid flow path may be in fluid communication with a same fluid supply channel. The same fluid supply channel may disposed within the housing. In some cases, the housing may comprise a central fluid channel, and at least a portion of the central fluid channel may provide fluid to the first fluid flow path and the second fluid flow path. A different portion of the central fluid channel may receive any fluid that is directed away from the first fluid flow path and the second fluid flow path, and direct the received fluid out of the housing (or out of the thermal management device). Alternatively, the same fluid supply channel (i) may not be disposed within the housing and (ii) may be in fluid communication with at least a portion of the housing.

In another aspect, the present disclosure provides a thermal management device. The thermal management device may comprise a base plate configured to be in thermal communication with a heat source or a heat sink. The thermal management device may further comprise a plurality of fins (e.g., at least 2, 3, 4, 5, 6, 7, 8, 9, 10, or more fins) disposed on a surface of the base plate. A surface of at least one fin of the plurality of fins may comprise a first depression and a second depression located above the first depression (e.g., along a Z-axis). In some cases, the first depression and the second depression may be configured to generate one or more vortices in a flow of a working fluid. In some cases, the plurality of fins may form a fluid flow path such that the first depression and the second depression may disrupt a boundary layer of the flow of the working fluid along the fluid flow path. The boundary layer may be a layer of the working fluid substantially adjacent to (or substantially surrounding) at least a portion of the surface of the at least one fin (e.g., the first depression and the second depression).

In some cases, the surface of the at least one fin of the plurality of fins may comprise a plurality of rows disposed along different heights of the surface. Each row of the plurality of rows can comprise a plurality of depressions. The surface may comprise at least about 2, 3, 4, 5, 6, 7, 8, 9, 10, or more rows. The surface may comprise at most about 10, 9, 8, 7, 6, 5, 4, 3, or 2 rows. Each row can comprise at least about 2, 3, 4, 5, 6, 7, 8, 9, 10, 15, 20, 30, 40, 50, 100, or more depressions. Each row can comprise at most about 100, 60, 40, 30, 20, 15, 10, 9, 8, 7, 6, 5, 4, 3, or 2 depressions. In each row, the plurality of depressions may be spaced out evenly. Alternatively, in each row, the plurality of depressions may not be spaced out evenly, and thus, the spacings between the adjacent depressions may vary. A row of the plurality of rows may be linear. Alternatively, a row of the plurality of rows may be non-linear (e.g., curved). In the plurality of rows, spacings between two adjacent rows may be uniform. Alternatively, the spacings between two adjacent rows within the plurality of rows may not be uniform (e.g., may vary). For example, within a surface of a fin, a spacing between two bottom-most rows may be different than a spacing between two top-most rows. The plurality of rows may be disposed at different heights along an axis (e.g., Z-axis) across the surface of the at least one fin. The axis (e.g., Z-axis) may be different than a direction of flow of the working fluid adjacent to the surface. The axis and the direction of the flow of the working fluid may be offset (or may be different) by at least about 1, 2, 3, 4, 5, 10, 20, 30, 60, 90, 120, or more degrees. The axis and the direction of the flow of the working fluid may be offset (or may be different) by at most about 120, 90, 60, 30, 20, 10, 5, 4, 3, 2, or 1 degree.

In some cases, the surface of the at least one fin of the plurality of fins may comprise a plurality of columns disposed along different heights of the surface. Each column of the plurality of columns can comprise a plurality of depressions. The surface may comprise at least about 2, 3, 4, 5, 6, 7, 8, 9, 10, or more columns. The surface may comprise at most about 10, 9, 8, 7, 6, 5, 4, 3, or 2 columns. Each column can comprise at least about 2, 3, 4, 5, 6, 7, 8, 9, 10, 15, 20, 30, 40, 50, 100, or more depressions. Each column can comprise at most about 100, 60, 40, 30, 20, 15, 10, 9, 8, 7, 6, 5, 4, 3, or 2 depressions. In each column, the plurality of depressions may be spaced out evenly. Alternatively, in each column, the plurality of depressions may not be spaced out evenly, and thus, the spacings between the adjacent depressions may vary. A column of the plurality of columns may be linear. Alternatively, a column of the plurality of columns may be non-linear (e.g., curved). In the plurality of columns, spacings between two adjacent columns may be uniform. Alternatively, the spacings between two adjacent columns within the plurality of columns may not be uniform (e.g., may vary). For example, within a surface of a fin, a spacing between two left-most columns may be different than a spacing between two right-most columns.

A depth (or an average depth) of each depression on the surface of the at least one fin maybe at least about 0.1%, 0.2%, 0.5%, 1%, 2%, 5%, 10%, 20%, 50%, or more of a thickness of the at least one fin. The depth (or the average depth) of each depression on the surface of the at last one fin may be at most about 50%, 20%, 10%, 5%, 2%, 1%, 0.5%, 0.2%, 0.1%, or less of the thickness of the at least one fin. A depression on the surface of the at least one fin may exhibit a uniform depth with respect to the surface. Alternatively, the depression may not exhibit a uniform depth with respect to the surface. In some examples, a first depression of a first row (or first column) of the plurality of rows (or columns) and a second depression of a second row (or second column) of the plurality of rows (or columns) directly adjacent to the first row (or the first column) may be aligned with respect to each other (e.g., the first depression and the second depression may be substantially above and under each other). Alternatively, the first depression and the second depression may be off-set (or staggered).

A cross-section of a depression, as disclosed herein, may be a scoop shape, a circle, a semi-circle, a square, a rectangle, a triangle, a pentagon, a hexagon, a heptagon, an octagon, a nonagon, a decagon, or any polygon with at least three or more sides.

A density of the plurality of depressions disposed on a surface of the at least one fin, as disclosed herein, may be varied. For example, a first density of the plurality of depressions in a first zone of the surface may be different than a second density of the plurality of depressions in a second zone of the surface by at least about 0.1%, 0.2%, 0.5%, 1%, 2%, 5%, 10%, 20%, 30%, 40%, 50%, 80%, or more. The first density of the plurality of depressions in the first zone of the surface may be different than the second density of the plurality of depressions in the second zone of the surface by at most about 80%, 50%, 40%, 30%, 20%, 10%, 5%, 2%, 1%, 0.5%, 0.2%, 0.1%, or less. In some cases, different densities of the plurality of depressions on the surface may have different effects on the change in the boundary layer of the flow of the working fluid adjacent to the surface, thereby modifying (or enhancing) thermal exchange from the at least one fin and the working fluid. Alternatively, the density of the plurality of depressions disposed on the surface of the at least one fin, as disclosed herein, may be constant.

A fin can have one or more sides (e.g., one side, two sides, three sides, or more), each side comprising the plurality of depressions as disclosed herein. The presence of the plurality of depressions can increase a surface area of the fin by at least about 1%, 2%, 5%, 10%, 20%, 30%, 40%, 50%, 80%, 100%, 200%, or more. The presence of the plurality of depressions can increase a surface area of the fin by at most about 200%, 100%, 80%, 50%, 40%, 30%, 20%, 10%, 5%, 2%, 1%, or less.

Two fins may be disposed adjacent to each other, such that a first surface of a first fin and a second surface of a second fin may be facing each other. In some cases, a depression on the first surface and a depression on a second surface may be disposed directly across each other (or aligned with respect to each other). Alternatively, a depression on the first surface and a depression on the second surface may be staggered, such that the depressions are not directly aligned with respect to each other.

In another aspect, the present disclosure provides a thermal management device. The thermal management device may comprise a base plate configured to be in thermal communication with a heat source or a heat sink. The thermal management device may further comprise a plurality of fins (e.g., at least 2, 3, 4, 5, 6, 7, 8, 9, 10, or more fins) disposed on a surface of the base plate. A surface of at least one fin of the plurality of fins may comprise one or more protrusions (e.g., at least 1, 2, 3, 4, 5, 6, 7, 8, 9, 10, or more protrusions). The protrusion(s) may be configured to generate one or more vortices in a flow of a working fluid. In some cases, the plurality of fins may form a fluid flow path such that the protrusion(s) may disrupt a boundary layer of the flow of the working fluid along the fluid flow path. In some cases, the at least one fin may comprise a non-linear shape or profile.

In some cases, the surface of the at least one fin of the plurality of fins may comprise a plurality of rows disposed along different heights of the surface. Each row of the plurality of rows can comprise a plurality of protrusions. The surface may comprise at least about 2, 3, 4, 5, 6, 7, 8, 9, 10, or more rows. The surface may comprise at most about 10, 9, 8, 7, 6, 5, 4, 3, or 2 rows. Each row can comprise at least about 2, 3, 4, 5, 6, 7, 8, 9, 10, 15, 20, 30, 40, 50, 100, or more protrusions. Each row can comprise at most about 100, 60, 40, 30, 20, 15, 10, 9, 8, 7, 6, 5, 4, 3, or 2 protrusions. In each row, the plurality of protrusions may be spaced out evenly. Alternatively, in each row, the plurality of protrusions may not be spaced out evenly, and thus, the spacings between the adjacent protrusions may vary. A row of the plurality of rows may be linear. Alternatively, a row of the plurality of rows may be non-linear (e.g., curved, wavy, etc.). In the plurality of rows, spacings between two adjacent rows may be uniform. Alternatively, the spacings between two adjacent rows within the plurality of rows may not be uniform (e.g., may vary). For example, within a surface of a fin, a spacing between two bottom-most rows may be different than a spacing between two top-most rows. The plurality of rows may be disposed at different heights along an axis (e.g., Z-axis) across the surface of the at least one fin. The axis (e.g., Z-axis) may be different than a direction of flow of the working fluid adjacent to the surface. The axis and the direction of the flow of the working fluid may be offset (or may be different) by at least about 1, 2, 3, 4, 5, 10, 20, 30, 60, 90, 120, or more degrees. The axis and the direction of the flow of the working fluid may be offset (or may be different) by at most about 120, 90, 60, 30, 20, 10, 5, 4, 3, 2, or 1 degree.

In some cases, the surface of the at least one fin of the plurality of fins may comprise a plurality of columns disposed along different heights of the surface. Each column of the plurality of columns can comprise a plurality of protrusions. The surface may comprise at least about 2, 3, 4, 5, 6, 7, 8, 9, 10, or more columns. The surface may comprise at most about 10, 9, 8, 7, 6, 5, 4, 3, or 2 columns. Each column can comprise at least about 2, 3, 4, 5, 6, 7, 8, 9, 10, 15, 20, 30, 40, 50, 100, or more protrusions. Each column can comprise at most about 100, 60, 40, 30, 20, 15, 10, 9, 8, 7, 6, 5, 4, 3, or 2 protrusions. In each column, the plurality of protrusions may be spaced out evenly. Alternatively, in each column, the plurality of protrusions may not be spaced out evenly, and thus, the spacings between the adjacent protrusions may vary. A column of the plurality of columns may be linear. Alternatively, a column of the plurality of columns may be non-linear (e.g., curved). In the plurality of columns, spacings between two adjacent columns may be uniform. Alternatively, the spacings between two adjacent columns within the plurality of columns may not be uniform (e.g., may vary). For example, within a surface of a fin, a spacing between two left-most columns may be different than a spacing between two right-most columns.

A height (or an average height) of each protrusion on the surface of the at least one fin maybe at least about 0.1%, 0.2%, 0.5%, 1%, 2%, 5%, 10%, 20%, 50%, or more of a thickness of the at least one fin. The height (or the average height) of each protrusion on the surface of the at last one fin may be at most about 50%, 20%, 10%, 5%, 2%, 1%, 0.5%, 0.2%, 0.1%, or less of the thickness of the at least one fin. A protrusion on the surface of the at least one fin may exhibit a uniform height with respect to the surface. Alternatively, the protrusion may not exhibit a uniform height with respect to the surface. In some examples, a first protrusion of a first row (or first column) of the plurality of rows (or columns) and a second protrusion of a second row (or second column) of the plurality of rows (or columns) directly adjacent to the first row (or the first column) may be aligned with respect to each other (e.g., the first protrusion and the second protrusion may be substantially above and under each other). Alternatively, the first protrusion and the second protrusion may be off-set (or staggered).

A cross-section of a protrusion, as disclosed herein, may be a scoop shape, a circle, a semi-circle, a square, a rectangle, a triangle, a pentagon, a hexagon, a heptagon, an octagon, a nonagon, a decagon, or any polygon with at least three or more sides.

A density of the plurality of protrusions disposed on a surface of the at least one fin, as disclosed herein, may be varied. For example, a first density of the plurality of protrusions in a first zone of the surface may be different than a second density of the plurality of protrusions in a second zone of the surface by at least about 0.1%, 0.2%, 0.5%, 1%, 2%, 5%, 10%, 20%, 30%, 40%, 50%, 80%, or more. The first density of the plurality of protrusions in the first zone of the surface may be different than the second density of the plurality of protrusions in the second zone of the surface by at most about 80%, 50%, 40%, 30%, 20%, 10%, 5%, 2%, 1%, 0.5%, 0.2%, 0.1%, or less. In some cases, different densities of the plurality of protrusions on the surface may have different effects on the change in the boundary layer of the flow of the working fluid adjacent to the surface, thereby modifying (or enhancing) thermal exchange from the at least one fin and the working fluid. Alternatively, the density of the plurality of protrusions disposed on the surface of the at least one fin, as disclosed herein, may be constant.

A fin can have one or more sides (e.g., one side, two sides, three sides, or more), each side comprising the plurality of protrusions as disclosed herein. The presence of the plurality of protrusions can increase a surface area of the fin by at least about 1%, 2%, 5%, 10%, 20%, 30%, 40%, 50%, 80%, 100%, 200%, or more. The presence of the plurality of protrusions can increase a surface area of the fin by at most about 200%, 100%, 80%, 50%, 40%, 30%, 20%, 10%, 5%, 2%, 1%, or less.

Two fins may be disposed adjacent to each other, such that a first surface of a first fin and a second surface of a second fin may be facing each other. In some cases, a protrusion on the first surface and a protrusion on a second surface may be disposed directly across each other (or aligned with respect to each other). Alternatively, a protrusion on the first surface and a protrusion on the second surface may be staggered, such that the protrusions are not directly aligned with respect to each other. In some cases, a protrusion on the first surface and a protrusion on the second surface may be in direct contact with each other. Alternatively, a protrusion on the first surface and a protrusion on the second surface may not be in direct contact with each other.

In another aspect, the present disclosure provides a thermal management device. The thermal management device may comprise a base plate configured to be in thermal communication with a heat source or a heat sink. The thermal management device may further comprise a plurality of fins or pins (e.g., at least 2, 3, 4, 5, 6, 7, 8, 9, 10, or more fins or pins) in communication with the base plate (e.g., disposed on a surface of the base plate). The plurality of fins or pins may be configured to provide a fluid flow path that directs a working fluid (i) along a length of the plurality of fins or pins and (ii) across a surface of the base plate. In some cases, a property or a characteristic of the plurality of fins or pins may vary along the fluid flow path provided by the plurality of fins or pins.

A fin may be a structure, wherein the longest dimension of the structure is positioned substantially parallel to the base plate. In some cases, a pin may be a structure, wherein the longest dimension of the structure is not positioned parallel to the base plate, e.g., but rather positioned substantially perpendicular to the base plate.

The property or the characteristic of the plurality of fins or pins may comprise size, width, length, height, shape, surface area, cross-sectional area, volume, porosity, density of the material of the fins/pins, surface roughness, rigidity of the fins/pins, flexibility of the fins/pins, density of the fins/pins, spacing between two or more adjacent fins/pins, etc.

The thermal management device can further comprise an inlet configured to receive the working fluid. The thermal management device may comprise at least 1, 2, 3, 4, 5, 6, 7, 8, 19, 10, or more inlets. The thermal management device may comprise at most 10, 9, 8, 7, 6, 5, 4, 3, 2, or 1 inlet. The property/characteristic of the plurality of fins or pins may vary based on a proximity of the fins or pins to the inlet. In some cases, a first plurality of fins or pins that is proximal to the inlet may exhibit a different property/characteristic than a second plurality of fins or pins that is farther away from the inlet. For example, the first plurality of ins or pins proximal to the inlet may exhibit a shorter height and/or a higher fin/pin density than the second plurality of fins or pins, such that the void (or empty space, cutout regions, etc.) generated by the differences in height between the first plurality of fins/pins and the second plurality of fins/pins can receive flow of the working fluid from the inlet and direct the working fluid to flow towards other portions of the thermal management device (e.g., the first and second plurality of fins/pins). Such void (or empty space, cutout regions, etc.) may effect impingement of flow of the working fluid when flowing from the inlet and towards the baseplate. As such, the direction of flow of the working fluid from the inlet may not be parallel to the plane of the base plate (e.g., may be substantially perpendicular to the plane of the base plate).

A property/characteristic of the plurality of fins/pins may decrease as a distance between each fin/pin from the inlet increases. Alternatively, the property/characteristic of the plurality of fins/pins may increase as a distance between each fin/pin from the inlet increases. In some cases, the density of the plurality of fins/pins may decrease as a distance between each fin/pin from the inlet increases. Alternatively, the density of the plurality of fins/pins may increase as a distance between each fin/pin from the inlet increases. In some cases, a height of the plurality of fins/pins may decrease as a distance between each fin/pin from the inlet increases. Alternatively, the density of the plurality of fins/pins may increase as a distance between each fin/pin from the inlet increases. In some cases, a cross-sectional area of the plurality of fins/pins may decrease as a distance between each fin/pin from the inlet increases. Alternatively, the cross-sectional area of the plurality of fins/pins may increase as a distance between each fin/pin from the inlet increases. In some cases, a cross-sectional shape of the plurality of fins/pins may decrease as a distance between each fin/pin from the inlet increases. Alternatively, the cross-sectional shape of the plurality of fins/pins may increase as a distance between each fin/pin from the inlet increases. In some cases, a surface area of the plurality of fins/pins may decrease as a distance between each fin/pin from the inlet increases. Alternatively, the surface area of the plurality of fins/pins may increase as a distance between each fin/pin from the inlet increases. In some cases, a volume of the plurality of fins/pins may decrease as a distance between each fin/pin from the inlet increases. Alternatively, the volume of the plurality of fins/pins may increase as a distance between each fin/pin from the inlet increases. In some cases, an inter-fin/pin spacing of the plurality of fins/pins may decrease as a distance between each fin/pin from the inlet increases. Alternatively, the inter-fin/pin spacing of the plurality of fins/pins may increase as a distance between each fin/pin from the inlet increases.

In some cases, the plurality of fins or pins as disclosed herein can be oriented at an angle relative to the plane/surface of the base plate, to aid in fluid routing and pickup. The angle may be less than or equal to about 90 degrees, 85 degrees, 80 degrees, 75 degrees, 70 degrees, 65 degrees, 60 degrees, 55 degrees, 50 degrees, 45 degrees, 40 degrees, 35 degrees, 30 degrees, or less. Alternatively, the angle may be greater than or equal to about 90 degrees, 95 degrees, 100 degrees, 105 degrees, 110 degrees, 115 degrees, 120 degrees, 125 degrees, 130 degrees, 140 degrees, 150 degrees, or more.

In some embodiments of any one of the thermal management device disclosed herein, one or more features of the thermal management device (e.g., one or more fins having one or more depressions, one or more protrusions, and/or one or more varied property/characteristic along one or more dimensions of the thermal management device) may alter a flow pattern of a working fluid while flowing via a flow path across the thermal management device. The altered or modified flow pattern may enhance or optimize heat transfer from at least a portion of the thermal management device (e.g., which device receives thermal energy from a separate source, such as computing devices) to the working fluid, or vice versa.

In some embodiments of any one of the thermal management device disclosed herein, a performance factor of the thermal management device may be assessed in terms of (i) a ratio between a thermal resistance of a control (e.g., a control thermal management device lacking one or more enhancement features as disclosed herein) (“R_{baseline}”) and a thermal resistance of the thermal management device (TMD) (“R_{TMD}”), which is normalized to (ii) a ratio between a pressure drop of the thermal management device (“dP_{TMD}”) and a pressure drop of the control (“dP_{baseline}”), as shown below:

$$Performance factor = \frac{{R}_{b a s e l i n e} / {R}_{T M D}}{{dP}_{T M D} / {dP}_{b a s e l i n e}} \qquad Equation 1$$

The performance factor may be a way to assess the goodness of the designs of thermal management devices, which may be sensitive to pressure drop increases associated with enhanced thermal designs and/or properties. The performance factor includes a pressure drop penalty that may be incurred when thermal performance improvements are gained via new thermal management designs, as disclosed herein. In some cases, the penalty on the pressure drop may be expected to be higher than the thermal performance enhancement, and thus the performance factor may be expected to be less than 1. The closer the performance factor is to the value of 1 may indicate that the improvements or modifications to the thermal management device may exhibit enhanced thermal performance with minimal increase in the pressure drop within the thermal management device (e.g., minimal increase in the pressure drop between an inlet and an outlet of the thermal management device for working fluid flow).

Modification of a thermal management device with one or more features as disclosed herein may increase a thermal performance of the thermal management device by at least about 0.1%, 0.2%, 0.5%, 1%, 2%, 5%, 10%, 20%, 30%, 40%, 50%, 80%, 100%, 200%, or more. Modification of the thermal management device with one or more features as disclosed herein may increase a thermal performance of the thermal management device by at most about 200%, 100%, 80%, 50%, 40%, 30%, 20%, 10%, 5%, 2%, 1%, 0.5%, 0.2%, 0.1%, or less.

Modification of the thermal management device with one or more features as disclosed herein may decrease thermal resistivity (e.g., as defined by degrees Celsius per watt (° C./W)) of the thermal management device by at least about 0.1%, 0.2%, 0.5%, 1%, 2%, 5%, 10%, 20%, 30%, 40%, 50%, 60%, 70%, 80%, 90%, or more. Modification of the thermal management device with one or more features as disclosed herein may decrease thermal resistivity of the thermal management device by at most about 100%, 90%, 80%, 70%, 60%, 50%, 40%, 30%, 20%, 10%, 5%, 2%, 1%, 0.5%, 0.2%, 0.1%, or less.

Modification of the thermal management device with one or more features as disclosed herein may increase a pressure drop within the thermal management device (e.g., a pressure drop between an inlet and an outlet of the thermal management device) by no more than about 0.1%, 0.2%, 0.5%, 1%, 2%, 5%, 10%, 20%, 30%, 40%, 50%, 60%, 70%, 80%, 90%, 100%, 200%, 300%, 400%, 500%, 600%, 700%, 800%, or more. Alternatively, the modification of the thermal management device with one or more features as disclosed herein may not increase the pressure drop within the thermal management device.

Modification of the thermal management device with one or more features as disclosed herein may yield a performance factor (e.g., as defined by Equation 1) that is at least about 0.7, 0.75, 0.8, 0.85, 0.9, 0.91, 0.92, 0.93, 0.94, 0.95, 0.96, 0.97, 0.98, 0.99, or more. In some cases, even with the modifications as disclosed herein, the performance factor of the thermal management device can be 1.

In some embodiments of any one of the thermal management device disclosed herein, a dimension (e.g., circumference, thickness, area, shape, etc.) of a cross-section (e.g., across a transverse plane, a coronal plane, or a sagittal plane) of a fin may be constant. Alternatively, the dimension of the cross-section of the fin may be varied. For example, a first area of a first cross-section of a fin may be different (e.g., greater than or less than) than a second area of a second cross-section of the fin that is parallel to the first cross-section by at least about 0.1%, 0.2%, 0.5%, 1%, 2%, 5%, 10%, 20%, 30%, 40%, 50%, 80%, or more. The first area of the first cross-section of the fin may be different than the second area of the second cross-section of the fin by at most about 80%, 50%, 40%, 30%, 20%, 10%, 5%, 2%, 1%, 0.5%, 0.2%, 0.1%, or less.

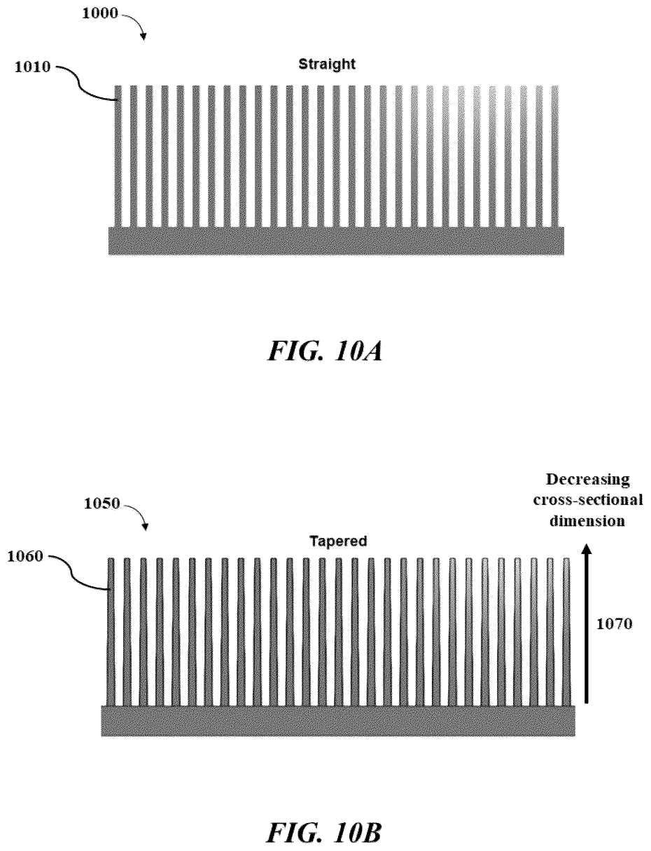

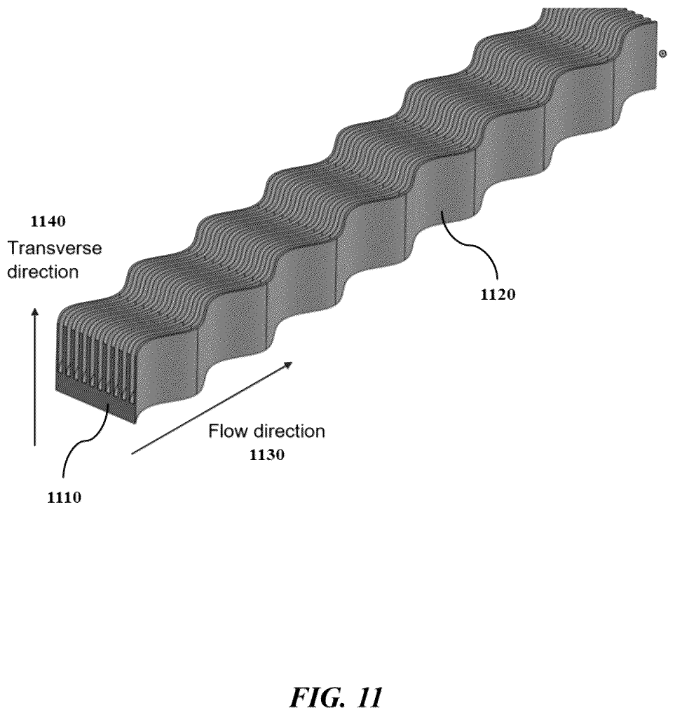

FIGS. 10A and 10B schematically illustrate different examples of the thermal management device as disclosed herein. FIG. 10A illustrates a thermal management device 1000 comprising a plurality of fins 1010 that are straight. Each fin of the plurality of fins 1010 may have uniform cross-sectional dimensions (e.g., area, shape, size, etc.) along the height of the fin. FIG. 10B illustrates a different thermal management device 1050 comprising a plurality of fins 1060 that are not straight. A cross-sectional dimension of each fin of the plurality of fins 1060 may decrease (or increase) along the height of the fin, as indicated by the arrow 1070.

In some embodiments of any one of the thermal management device disclosed herein, two neighboring fins disposed adjacent to each other (or directly next to each other) may have the same morphological features (e.g., circumference, thickness, area, shape, volume, surface roughness, density of material, etc.). Alternatively, the two neighboring fins disposed adjacent to each other may have one or more different morphological features.

In any of the embodiments described herein, the use of manifolds and manifold channels may permit the thermal management devices disclosed herein to achieve highly distributed flow arrangements, thereby improving temperature uniformity across a heated base plate, increasing a convection coefficient in the microchannels, and lowering a pressure drop of the cooling fluid via a reduction of a local flow velocity and a fluid path length.

A variability of flow rates and/or flow resistances across different zones of the array of fins may allow for a reduction in pressure drop of a fluid flowing between an inlet and an outlet of the manifold block of the thermal management device.

In some embodiments of any one of the thermal management device disclosed herein, at least a portion of the surface of the thermal management device (e.g., at least a portion of the surface of the housing of the thermal management device) may function as a heat sink, e.g., as a cold plate to direct transfer of thermal energy from a heat-generating devices (e.g., ICM) to the thermal management device (e.g., fluid flow channel within the thermal management device, a plurality of channels or sub-channels within the thermal management device, an array of fins within the thermal management device, etc.).

In some embodiments of any one of the thermal management device disclosed herein, a fluid (or a working fluid) may be a gas and/or liquid that is capable of absorbing or transmitting thermal energy. The working fluid may be oxygen, nitrogen, an inert gas (e.g., argon or helium), air, water, ammonia, methanol, ethanol, hydrogen, helium, propane, butane, isobutane, ammonia, sulfur dioxide, or any combination thereof. The working fluid may include one or more chlorofluorocarbons, one or more hydrochlorofluorocarbons, one or more hydrofluorocarbons, and/or one or more fluorocarbons. For example, the working fluid may be trichlorofluoromethane; dichlorodifluoromethane; difluoromethane; pentafluoroethane; chlorotrifluoromethane; chlorodifluoromethane; dichlorofluoromethane; chlorofluoromethane; bromochlorodifluoromethane; 1,1,2-trichloro-1,2,2-trifluoroethane; 1,1,1-trichloro-2,2,2-trifluoroethane; 1,2-dichloro-1,1,2,2-tetrafluoroethane; 1-chloro-1,1,2,2,2-pentafluoroethane; 2-chloro-1,1,1,2-tetrafluoroethane; 1,1-dichloro-1-fluoroethane; 1-chloro-1,1-difluoroethane; tetrachloro-1,2-difluoroethane; tetrachloro-1,1-difluoroethane; 1,1,2-trichlorotrifluoroethane; 1-bromo-2-chloro-1,1,2-trifluoroethane; 2-bromo-2-chloro-1,1,1-trifluoroethane; 1,1-dichloro-2,2,3,3,3-pentafluoropropane; and/or 1,3-dichloro-1,2,2,3,3-pentafluoropropane. The working fluid may be trifluoromethane (HFC-23); difluoromethane (HFC-32); fluoromethane (HFC-41); 2-chloro-1,1,1,2-tetrafluoroethane (HFC-124); 1,1,2,2,2-pentafluoroethane (HFC-125); 1,1,2,2-tetraflu-oroethane (HFC-134); 1,1,1,2-tetrafluoroethane (HFC-134a,); 1,1-difluoroethane (HFC-152a); and/or 1,1,1,2,3,3,3-heptafluoropropane (HFC-227ea). The working fluid may be carbon tetrafluoride; perfluorooctane; perfluoro-2-methylpentane; perfluoro-1,3-dimethylcyclohexane; perfluorodecalin; hexafluoroethane; and/or perfluoromethylcyclohexane.

In some embodiments of any one of the thermal management device disclosed herein, a channel (e.g., the fluid channel, the fluid flow channel, one or more of the first plurality of channels, one or more of the second plurality of channels, a fluid supply channel, etc.) may comprise a plurality of sub-channels for fluid flow path. The plurality of sub-channels may be provided (or generated) by having, for example, protrusion elements such as a plurality of fins (e.g., an array of fins). A fin of a plurality of fins may have various cross-sectional shapes. A cross-section of a fin of a plurality of fins may be an airfoil, a circle, a square, a rectangle, a triangle, a pentagon, a hexagon, a heptagon, an octagon, a nonagon, a decagon, or any polygon with at least three or more sides.

A channel, as disclosed herein, may comprise a plurality of sub-channels. The plurality of sub-channels may comprise at least 2 sub-channels, 2 sub-channels, 3 sub-channels, 4 sub-channels s, 5 sub-channels, 6 sub-channels, 7 sub-channels, 8 sub-channels, 9 sub-channels, 10 sub-channels, 11 sub-channels, 12 sub-channels, 13 sub-channels, 14 sub-channels, 15 sub-channels, 16 sub-channels, 17 sub-channels, 18 sub-channels, 19 sub-channels, 20 sub-channels, 25 sub-channels, 50 sub-channels, 100 sub-channels, 200 sub-channels, 300 sub-channels, 400 sub-channels, 500 sub-channels, 1000 sub-channels, 2000 sub-channels, or more. The plurality of sub-channels may comprise at most 2000 sub-channels, 1000 sub-channels, 500 sub-channels, 400 sub-channels, 300 sub-channels, 200 sub-channels, 100 sub-channels, 50 sub-channels, 25 sub-channels, 20 sub-channels, 19 sub-channels, 18 sub-channels, 17 sub-channels, 16 sub-channels, 15 sub-channels, 14 sub-channels, 13 sub-channels, 12 sub-channels, 11 sub-channels, 10 sub-channels, 9 sub-channels, 8 sub-channels, 7 sub-channels, 6 sub-channels, 5 sub-channels, 4 sub-channels, 3 h sub-channels, or 2 sub-channels. The plurality of sub-channels may be parallel to each other. Alternatively, the plurality of sub-channels may not be parallel to each other. The plurality of sub-channels may comprise the same dimension (e.g., length, cross-sectional diameter, curvature, etc.). Alternatively, the plurality of sub-channels may comprise different dimensions.

A channel, as disclosed herein, may comprise an array of fins (or a plurality of fins). The array of fins may comprise at least 1 fin, 2 fins, 3 fins, 4 fins, 5 fins, 6 fins, 7 fins, 8 fins, 9 fins, 10 fins, 11 fins, 12 fins, 13 fins, 14 fins, 15 fins, 16 fins, 17 fins, 18 fins, 19 fins, 20 fins, 25 fin, 50 fins, 100 fins, 200 fins, 300 fins, 400 fins, 500 fins, 1000 fins, 2000 fins, or more. The array of fins may comprise at most 2000 fins, 1000 fins, 500 fins, 400 fins, 300 fins, 200 fins, 100 fins, 50 fins, 25 fins, 20 fins, 19 fins, 18 fins, 17 fins, 16 fins, 15 fins, 14 fins, 13 fins, 12 fins, 11 fins, 10 fins, 9 fins, 8 fins, 7 fins, 6 fins, 5 fins, 4 fins, 3 fins, 2 fins, or 1 fin. A density of fins within an array of fins may be uniform across the array of fins. Alternatively, a density of fins within an array of fins may not be uniform (heterogeneous) across the array of fins. An array of fins may comprise fins of the same dimension (e.g., length, cross-sectional diameter, curvature, etc.). Alternatively, an array of fins may comprise fins having different dimensions (e.g., length, cross-sectional diameter, curvature, etc.).

In some embodiments of any one of the thermal management device disclosed herein, a plurality of fins may be provided in a staggered arrangement. The staggered arrangement of the array of fins may be configured such that a fluid flow path of a working fluid to one fin in a first column of fins is not obstructed by another fin in a second column of fins that is positioned in front of the first column of fins. The staggered arrangement may allow a working fluid (e.g., a second working fluid) to efficiently flow through the array of fins, thereby enhancing the rate of heat transfer between the array of fins and the second working fluid. For example, the staggered arrangement may allow a working fluid (e.g., a second working fluid) to flow through the array of fins with thermal exposure to one or more surfaces of each fin of the array of fins, thereby enhancing the amount of heat transfer between the array of fins and the second working fluid. Thermal exposure may involve thermal contact that facilitates a transfer of thermal energy between the array of fins and the second working fluid, through one or more heat transfer mechanisms.

In some embodiments of any one of the thermal management device disclosed herein, the fins of the array of fins may comprise one or more turbulating features disposed on a surface of the fin. The one or more turbulating features may be configured to generate turbulence when the cooling fluid flows across and/or through the array of fins, thereby enhancing heat transfer between the cooling fluid and the one or more fins of the array of fins. In some cases, the one or more turbulating features may be shaped as a diamond or a pyramid.

In some embodiments of any one of the thermal management device disclosed herein, the fins of the array of fins may comprise one or more tapered fins. The one or more tapered fins may be configured such that a width of the tapered fins gradually decreases along an axis spanning the height of the tapered fins.

In some embodiments of any one of the thermal management device disclosed herein, the fins of the array of fins may comprise one or more jagged fins. The one or more jagged fins may extend upwards from an inner surface of the thermal management device (e.g., a portion of the housing). The one or more jagged fins may have a vertical cross-section that is in a zigzag pattern. A first portion of the one or more jagged fins may extend upwards from the inner surface of the thermal management device (e.g., an inner surface of a portion of a housing of the thermal management device) at a first angle. A second portion of the one or more jagged fins may extend upwards from an upper end of the first potion of the one or more jagged fins at a second angle. The first angle may be equal to the second angle. Alternatively, the first angle may not be equal to the second angle. The one or more jagged fins may comprise a plurality of portions that extend upwards from one another at a plurality of angles. The one or more jagged fins may be configured to increase a surface area of the one or more jagged fins in thermal contact with the cooling fluid, thereby enhancing heat transfer between the cooling fluid and the one or more jagged fins.

In some embodiments of any one of the thermal management device disclosed herein, the array of fins may comprise one or more turbulating fins. The one or more turbulating fins may have a hollow internal region. The one or more turbulating fins may have an opening disposed on a surface of the one or more turbulating fins. The opening may be configured to allow a cooling fluid to flow through the opening from a front side of the turbulating fin to a back side of the turbulating fin. The opening may be in the shape of a circle, a square, an ellipse, a rectangle, or a combination thereof. The one or more turbulating fins may comprise a turbulating feature located within the hollow internal region. The turbulating feature may be configured as a helical structure that extends from a bottom of the turbulating fin to a top of the turbulating fin. The helical structure may have one or more coils extending from a bottom of the turbulating fin to a top of the turbulating fin. The one or more coils may make a predetermined number of turns along a height of the helical structure. The predetermined number of turns may range from 1 turn to 100 turns. The helical structure may have a predetermined pitch. The predetermined pitch may range from 1 millimeter (mm) to 1 meter (m). The predetermined pitch may vary along a height of the helical structure. The helical structure may have a predetermined diameter. The predetermined diameter may range from 1 millimeter to 1 meter. The predetermined diameter may vary across one or more coils of the helical structure. The one or more coils may have a predetermined coil angle. The coil angle may range from 0.001 degrees to 90 degrees. The predetermined coil angle may vary along a height of the helical structure. The helical structure may have a coil with a cross-section. The cross-section may be in the shape of a circle, a square, a rectangle, or an airfoil as described elsewhere herein. In some cases, one or more features of the helical structure (e.g., height, number of coils, number of turns for each coil, pitch, diameter, coil angle, or cross-sectional shape) may be pre-determined and/or adjusted to generate turbulence within the cooling fluid while the cooling fluid flows past and/or through the array of fins or the turbulating fins. Further, the one or more features of the helical structure may be pre-determined and/or adjusted to enhance mixing of the cooling fluid and to enhance heat transfer between the cooling fluid and one or more components of the thermal management device, while the cooling fluid flows past and/or through the array of fins or the turbulating fins.

In some embodiments of any one of the thermal management device disclosed herein, the array of fins may be oriented in different directions. A first fin from the array of fins may be disposed at an angle relative to a second fin of the array of fins. The angle may be at least about 5 degrees, 10 degrees, 15 degrees, 20 degrees, 25 degrees, 30 degrees, 35 degrees, 40 degrees, 45 degrees, 50 degrees, 55 degrees, 60 degrees, 65 degrees, 70 degrees, 75 degrees, 80 degrees, 85 degrees, 90 degrees, 95 degrees, 100 degrees, 105 degrees, 110 degrees, 115 degrees, 120 degrees, 125 degrees, 130 degrees, 135 degrees, 140 degrees, 145 degrees, 150 degrees, 155 degrees, 160 degrees, 165 degrees, 170 degrees, 175 degrees, or more. The angle may be at most about 175 degrees, 170 degrees, 165 degrees, 160 degrees, 155 degrees, 150 degrees, 145 degrees, 140 degrees, 135 degrees, 130 degrees, 125 degrees, 120 degrees, 115 degrees, 110 degrees, 105 degrees, 100 degrees, 95 degrees, 90 degrees, 85 degrees, 80 degrees, 75 degrees, 70 degrees, 65 degrees, 60 degrees, 55 degrees, 50 degrees, 45 degrees, 40 degrees, 35 degrees, 30 degrees, 25 degrees, 20 degrees, 15 degrees, 10 degrees, 5 degrees, or less. Alternatively, the array of fins may be oriented in the same direction, e.g., the fins of the array of fins may be oriented substantially parallel to one another.

In some embodiments of any one of the thermal management device disclosed herein, the housing of the thermal management device and the array of fins may comprise a same material. Alternatively, the housing of the thermal management device and the array of fins may comprise different materials.

In some embodiments of any one of the thermal management device disclosed herein, the flow rate of a fluid across a fluid flow path (e.g., across a fluid flow channel, across one or more of a plurality of channels or sub-channels, across a spacing between two fins of an array of fins, etc.) within the thermal management device may range from a flow rate of between about 0.01 liters per meter (LPM) to about 10 LPM. For example, the flow rate may be at least about 0.01 LPM, 0.02 LPM, 0.03 LPM, 0.04 LPM, 0.05 LPM, 0.06 LPM, 0.07 LPM, 0.08 LPM, 0.09 LPM, 0.1 LPM, 0.2 LPM, 0.3 LPM, 0.4 LPM, 0.5 LPM, 0.6 LPM, 0.7 LPM, 0.8 LPM, 0.9 LPM, 1 LPM, 2 LPM, 3 LPM, 4 LPM, 5 LPM, 6 LPM, 7 LPM, 8 LPM, 9 LPM, 10 LPM, or more. In some cases, the flow rate may range from about 0.5 LPM to 2 LPM. For example, the flow rate may be at least about 0.5 LPM, 0.6 LPM, 0.7 LPM, 0.8 LPM, 0.9 LPM, 1.0 LPM, 1.1 LPM, 1.2 LPM, 1.3 LPM, 1.4 LPM, 1.5 LPM, 1.6 LPM, 1.7 LPM, 1.8 LPM, 1.9 LPM, 2 LPM, or more.

In some embodiments of any one of the thermal management device disclosed herein, the thermal resistivity of at least a portion (or a conformal portion) of the thermal management device may be at least about 0.1 square millimeter degree-C per Watt (mm²·° C./W), 0.2 mm²·° C./W, 0.3 mm²·° C./W, 0.4 mm²·° C./W, 0.5 mm²·° C./W, 0.6 mm²·° C./W, 0.7 mm²·° C./W, 0.8 mm²·° C./W, 0.9 mm·° C./W, 1 mm²·° C./W, 2 mm²·° C./W, 3 mm²·° C./W, 4 mm²·° C./W, 5 mm²·° C./W, 6 mm²·° C./W, 7 mm²·° C./W, 8 mm²·° C./W, 9 mm²·° C./W, 10 mm²·° C./W, 15 mm²·° C./W, 20 mm²·° C./W, 25 mm²·° C./W, 30 mm²·° C./W, 35 mm²·° C./W, 40 mm²·° C./W, 45 mm²·° C./W, 50 mm²·° C./W, 60 mm²·° C./W, 70 mm²·° C./W, 80 mm²·° C./W, 90 mm²·° C./W, 100 mm²·° C./W, or more. The thermal resistivity of at least a portion (or a conformal portion) of the thermal management device may be at most about 100 mm²·° C./W, 90 mm²·° C./W, 80 mm²·° C./W, 70 mm²·° C./W, 60 mm²·° C./W, 50 mm²·° C./W, 45 mm²·° C./W, 40 mm²·° C./W, 35 mm²·° C./W, 30 mm²·° C./W, 25 mm²·° C./W, 20 mm·° C./W, 15 mm²·° C./W, 10 mm²·° C./W, 9 mm²·° C./W, 8 mm²·° C./W, 7 mm²·° C./W, 6 mm²·° C./W, 5 mm²·° C./W, 4 mm²·° C./W, 3 mm²·° C./W, 2 mm²·° C./W, 1 mm²·° C./W, 0.9 mm²·° C./W, 0.8 mm²·° C./W, 0.7 mm²·° C./W, 0.6 mm²·° C./W, 0.5 mm²·° C./W, 0.4 mm²·° C./W, 0.3 mm²·° C./W, 0.2 mm²·° C./W, 0.1 mm·° C./W, or less.

In some embodiments of any one of the thermal management device disclosed herein, an area of at least a portion (or a conformal portion) of the thermal management device may range from about 0.01 mm² to about 1000 mm². For example, the area of at least a portion (or a conformal portion) of the thermal management device may be at least about 0.01 mm², 0.02 mm², 0.03 mm², 0.04 mm², 0.05 mm², 0.06 mm², 0.07 mm², 0.08 mm², 0.09 mm², 0.1 mm², 0.2 mm², 0.3 mm², 0.4 mm², 0.5 mm², 0.6 mm², 0.7 mm², 0.8 mm², 0.9 mm², 1 mm², 2 mm², 3 mm², 4 mm², 5 mm², 6 mm², 7 mm², 8 mm², 9 mm², 10 mm², 20 mm², 30 mm², 40 mm², 50 mm², 60 mm², 70 mm², 80 mm², 90 mm², 100 mm², 200 mm², 300 mm², 400 mm², 500 mm², 600 mm², 700 mm², 800 mm², 900 mm², 1000 mm², or more.

In some embodiments of any one of the thermal management device disclosed herein, each fin of the array of fins may be separated by a distance. The distance may correspond to a spacing between one or more fins (i.e., a fin-to-fin spacing). The fin-to-fin spacing may range from between about 10 nanometers to about 5,000 microns. The distance between a first fin and a second fin may be at least about 40 micrometers. In some cases, a distance between a first fin and a second fin may be at least about 200 micrometers. In other cases, the distance may be at least about 250 micrometers. In any of the embodiments described herein, the distance between the first fin and the second fin may range from between about 100 micrometers to 1 centimeter. For example, the distance between the first fin and the second fin may be at least about 100 micrometers, 150 micrometers, 200 micrometers, 250 micrometers, 300 micrometers, 350 micrometers, 400 micrometers, 450 micrometers, 500 micrometers, 550 micrometers, 600 micrometers, 650 micrometers, 700 micrometers, 750 micrometers, 800 micrometers, 850 micrometers, 900 micrometers, 950 micrometers, 1 millimeter, 2 millimeters, 3 millimeters, 4 millimeters, 5 millimeters, 6 millimeters, 7 millimeters, 8 millimeters, 9 millimeters, 1 centimeter, or more.

In some embodiments of any one of the thermal management device disclosed herein, the array of fins may comprise a material exhibiting a thermal conductivity of at least about 1 Watts per meter-Kelvin (W/m·K), 2 W/m·K, 3 W/m·K, 4 W/m·K, 5 W/m·K, 10 W/m·K, 20 W/m·K, 30 W/m·K, 40 W/m·K, 50 W/m·K, 100 W/m·K, 200 W/m·K, 300 W/m·K, 400 W/m·K, 500 W/m·K, 600 W/m·K, 700 W/m·K, 800 W/m·K, 900 W/m·K, 1000 W/m·K, or more. The array of fins may comprise a material exhibiting a thermal conductivity of at most about 1000 W/m·K, 900 W/m·K, 800 W/m·K, 700 W/m·K, 600 W/m·K, 500 W/m·K, 400 W/m·K, 300 W/m·K, 200 W/m·K, 100 W/m·K, 50 W/m·K, 40 W/m·K, 30 W/m·K, 20 W/m·K, 10 W/m·K, 5 W/m·K, 4 W/m·K, 3 W/m·K, 2 W/m·K, 1 W/m·K, or less.

In some embodiments of any one of the thermal management device disclosed herein, a heat generating device (or a source of thermal energy) may include, but are not limited to, a circuit, a computer processor, a plurality of computer processors, a light source (e.g., a lamp, such as an incandescent lamp, a halogen lamp, a carbon arc lamp, or a discharge lamp), a torch, a laser, a heater, a furnace (e.g., an induction furnace, an electric arc furnace, a gas-fired furnace, a plasma arc furnace, a microwave furnace, or an electric resistance furnace), or a hot fluid (e.g., superheated steam). The source of thermal energy may be an object (e.g., a mechanical component, a mechanical structure, and/or a surface of a mechanical component or a mechanical structure) that is in thermal contact with a hot object, such as a circuit, a computer processor, a plurality of computer processors, a light source (e.g., a lamp, such as an incandescent lamp, a halogen lamp, a carbon arc lamp, or a discharge lamp), a torch, a laser, a heater, a furnace (e.g., an induction furnace, an electric arc furnace, a gas-fired furnace, a plasma arc furnace, a microwave furnace, or an electric resistance furnace), or an open flame. The source of thermal energy may include an electronic component (e.g., a circuit board, a computer processor(s), a graphics processing unit, or an application-specific integrated circuit) and/or an object (e.g., a mechanical component, a mechanical structure, and/or a surface of a mechanical component or a mechanical structure) that is in thermal communication with the electronic component such that the object is capable of absorbing and transmitting at least a portion of the thermal energy generated by the electronic component.

The source of thermal energy may generate thermal energy by combustion. In an example, a hydrocarbon (e.g., methane) may be combined with oxygen and subjected to an oxidation reaction (e.g., a combustion reaction) to generate carbon monoxide and/or carbon dioxide, water, and thermal energy.

The source of thermal energy may generate thermal energy by resistive heating. Resistive heating may include heating achieved by passing an electrical current through an electrically resistive material. The electrically resistive material may be a conducting material with a resistance property that may impede the movement of electrons through the material and/or cause electrons to collide with each other, thereby generating thermal energy. The source of thermal energy may generate thermal energy through inductive heating. Inductive heating may involve the use of electromagnetic induction to generate electrical currents inside a conducting material. The electrical currents may flow through the conducting material and generate thermal energy by resistive heating.

The source of thermal energy may generate thermal energy through dielectric heating. Dielectric heating may involve the use of radio wave or microwave electromagnetic radiation to cause the rotation of molecules within a material.

In some embodiments of any one of the thermal management device disclosed herein, a transfer of thermal energy (e.g., from a surface of an ICM to a surface of a thermal management device) may be via one or more heat transfer mechanisms. The one or more heat transfer mechanisms may include advection, conduction, convection, radiation, and/or any combination thereof. Advection may involve the transfer of heat by the flow of a fluid. Conduction may involve the transfer of heat when vibrating atoms and molecules adjacent to one another interact with nearby atoms and molecules and transfer heat and/or kinetic energy to the nearby atoms and molecules. Convection may involve the transfer of heat by a movement of a working fluid. In some cases, convection may involve the transfer of heat by buoyancy forces caused when thermal energy expands a working fluid. In other cases, convection may involve the transfer of heat by diffusion. Alternatively, convection may involve forced convection whereby a working fluid is forced to flow by a source of thermal energy using a pump and/or a fan. Radiation may involve the transfer of energy through photons in electromagnetic waves.

In some embodiments of any one of the thermal management device disclosed herein, the thermal management device (or liquid cooling device) may be manufactured as a single unitary piece or structure. As such, the thermal management device may not require a sealing unit (e.g., an O-ring) between two or more components or two or more sub-components of the thermal management device, to prevent a cooling fluid from leaking between the two or more components or the two or more sub-components of the thermal management device. The thermal management device, as printed, may be substantially uniform, and may not include any seams on a surface of the thermal management device and/or any material discontinuities within an internal structure of the thermal management device. The thermal management device may have a uniform grain structure. The liquid cooling device, as printed, may have substantially ordered grains or grain boundaries.

The single unitary piece or structure may comprise at least one metal (e.g., copper). The single unitary piece or structure may have one or more material properties substantially similar to one or more material properties of bulk copper. The one or more material properties may include, for example, brittleness, bulk modulus, coefficient of restitution, compressive strength, creep, ductility, durability, elasticity, fatigue limit, flexibility, fracture toughness, hardness, malleability, mass diffusivity, plasticity, resilience, shear modulus, shear strength, specific modulus, specific weight, stiffness, tensile strength, toughness, yield strength, Young's modulus, thermal conductivity, thermal diffusivity, thermal expansion, specific heat, melting point, capacitance, electrical resistivity, electrical conductivity, and/or density.

Alternatively, a thermal management device as disclosed herein may comprise two or more components or sub-components operatively coupled (or directly coupled) to one another.

In another aspect, the present disclosure provides methods of utilizing any one of the thermal management devices disclosed herein for thermal management of a heat-generating device (e.g., electronic systems). The method can comprise providing the thermal management device to the heat-generating device. The method can further comprise coupling the thermal management device to the heat-generating device. The thermal management device and the heat-generating device can be directly coupled or indirectly coupled (e.g., via a liquid, semi-liquid, gel, semi-solid, or solid medium capable of facilitating heat transfer). Such coupling can facilitate a transfer of thermal energy from the heat-generating device to the thermal management device, or vice versa. The method can further comprise directing a working fluid along a fluid flow path of the thermal management device, to facilitate a transfer of thermal energy from the thermal management device (e.g., from a plurality of fins or pins of the thermal management device) to the working fluid, or vice versa.

Methods for Forming Thermal Management Devices and Systems

The present disclosure provides systems and methods for forming a thermal management device or system. The thermal management device or system may be fabricated using one or more additive manufacturing techniques, such as one or more three-dimensional (3D) printing techniques.

Additive manufacturing techniques may include vat photopolymerization, powder bed fusion, material extrusion, material jetting, binder jetting, and/or direct energy deposition. Additive manufacturing techniques may include one or more three-dimensional (3D) printing techniques. A 3D printing technique may include direct light processing (DLP), continuous direct light processing (CDLP), stereolithography (SLA), fused deposition modeling (FDM), fused filament fabrication (FFF), selective laser sintering (SLS), material jetting (MJ), nano particle jetting (NPJ), drop on demand (DOD), binder jetting, direct metal laser sintering (DMLS), selective laser melting (SLM), electron beam melting (EBM), multi jet fusion (MJF), direct energy deposition (DED), laser engineered net shaping, and/or electron beam additive manufacturing.

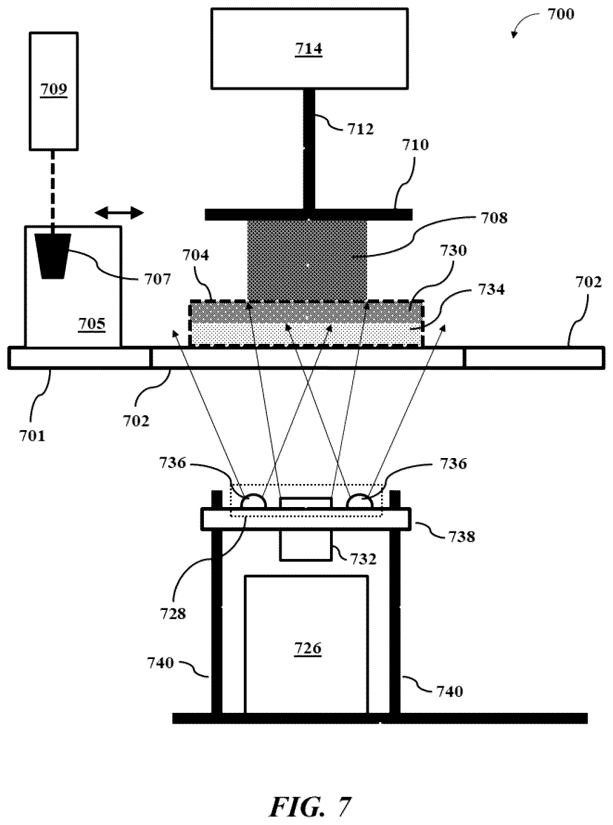

In an example, stereolithography (SLA) may be used to print the thermal management devices illustrated in FIG. 7. Printing of the thermal management devices may be performed using a three-dimensional (3D) printing system, such as the 3D printing system of FIG. 7.

FIG. 7 illustrates an example of a three-dimensional (3D) printing system 700 which may be used to print the thermal management devices of the present disclosure. The three-dimensional (3D) printing system 700 may include an open platform 701 comprising a print window 702 to hold a film of a viscous liquid 704, which may include a photoactive resin. The open platform 701 may be a vat or a container configured to retain at least a portion of the viscous liquid. Alternatively, the open platform 701 may not be a vat or a container. For example, the open platform 701 may be a substrate or slab that does not have a depression (e.g., vat or container) for retaining a viscous liquid 704. The viscous liquid 704 may be sufficiently viscous such that the viscous liquid 704 remains on the open platform 701.

The 3D printing system 700 may be configured to use the viscous liquid 704 to generate a green part corresponding to the thermal management device. A green part may be a part that holds a plurality of particles together before the plurality of particles are fused together (e.g., through sintering) to create a 3D object (e.g., the thermal management device) comprising the plurality of particles. The green part may not be the final 3D object (i.e., further processing may be needed to generate the thermal management device from the green part or a derivative of the green part). A green part may correspond to a thermal management device that is printed using any of the 3D printing methods disclosed herein. A green part may correspond to the shape and/or size of the thermal management device or may correspond to the shape and/or size of a portion of the thermal management device. The green part may have the same shape and/or dimensions as the thermal management device. The green part may have a similar shape to the thermal management device and dimensions that are proportional to the dimensions of the thermal management device. In some examples, the green part may correspond to the shape and/or size of the thermal management device, a portion of the thermal management device, a fin of the thermal management device, a portion of the fin, etc.

The green part may comprise a polymeric material and a plurality of particles (e.g., metal, ceramic, or both) that are encapsulated by the polymeric material. The polymeric material may be a polymer (or polymeric) matrix. The polymeric material may be created by polymerizing monomers into the polymeric material and/or cross-linking oligomers into the polymeric material, as described in further detail elsewhere herein. The plurality of particles may be encapsulated in the polymer (or polymeric) matrix. The plurality of particles may be capable of sintering or melting. The green part may be self-supporting. The green part may be heated in a heater (e.g., in a furnace) to burn off and/or vaporize at least a portion of the polymeric material and to coalesce the plurality of particles into the thermal management device or into at least a portion of the thermal management device.

The thermal management device and/or a green part corresponding to the thermal management device may be fabricated using at least one viscous liquid. The at least one viscous liquid may be a resin. A resin may be a viscous liquid that is usable to print a 3D object. The resin may include a photoactive resin. The photoactive resin may include a polymeric precursor and at least one photoinitiator. A polymeric precursor may be a polymerizable and/or cross-linkable component, such as a monomer, for example. A photoinitiator may be a compound that activates curing of the polymerizable and/or cross-linkable component, thereby subjecting the polymerizable and/or cross-linkable component to polymerization and/or cross-linking. Polymerization may be a process of reacting monomers together to form one or more chains of polymers. Polymerization may include step-growth polymerization, chain-growth polymerization, or photopolymerization. Step-growth polymerization may involve reactions between monomers with one or more functional groups to form polymer chains. Chain-growth polymerization may involve reactions between one or monomers and an initiator to add monomer molecules onto one or more active sites of a polymer chain. An initiator may be a compound that reacts with monomers to form an intermediate compound. The intermediate compound may be capable of linking one or more monomers into a polymer chain. Photopolymerization may be a chain-growth polymerization initiated by the absorption of visible or ultraviolet light. Cross-linking may be a process of joining two or more polymer chains together by using a chemical reaction to form covalent bonds between two or more polymer chains.

The resin may include a plurality of particles (e.g., metal particles, non-metal particles, or both). The resin may be a paste, a slurry, or a photopolymer slurry. The plurality of particles may be added to the resin. The plurality of particles may be solids or semi-solids (e.g., gels). The plurality of particles may be suspended throughout the resin. The plurality of particles in the resin may have a distribution that is monodisperse or polydisperse. The resin may contain additional optical absorbers and/or non-photoreactive components (e.g., fillers, binders, plasticizers, etc.). The 3D printing methods disclosed herein may be performed with at least 1, 2, 3, 4, 5, 6, 7, 8, 9, 10 or more resins. A plurality of resins comprising different materials (e.g., a different photoactive resin and/or a different plurality of particles) may be used for printing a multi-material 3D object.

The resin used to fabricate the thermal management device may include a plurality of particles (e.g., metallic, intermetallic, ceramic, and/or polymeric particles). The plurality of particles may be used to fabricate the thermal management device and/or a green part corresponding to the thermal management device or a portion of the thermal management device. The thermal management devices disclosed herein may be fabricated using the plurality of particles. The plurality of particles may comprise inorganic materials and/or organic materials. The inorganic materials may be a metallic material, an intermetallic material, a ceramic material, a composite material, or any combination thereof. The organic materials may comprise one or more polymers.

The resin used to fabricate the thermal management device may comprise a metallic material. The metallic material may comprise one or more elements selected from the group consisting of aluminum, platinum, calcium, magnesium, barium, scandium, titanium, vanadium, chromium, manganese, iron, cobalt, nickel, copper, zinc, yttrium, niobium, molybdenum, ruthenium, rhodium, silver, cadmium, actinium, and gold.

The resin used to fabricate the thermal management device may comprise an intermetallic material. The intermetallic material may be a solid-state compound exhibiting metallic bonding, defined stoichiometry and ordered crystal structure (i.e., alloys). The intermetallic material may be in a prealloyed powder form. Examples of such prealloyed powders may include, but are not limited to, brass (copper and zinc), bronze (copper and tin), duralumin (aluminum, copper, manganese, and/or magnesium), gold alloys (gold and copper), rose-gold alloys (gold, copper, and zinc), nichrome (nickel and chromium), and/or stainless steel (iron, carbon, and additional elements including manganese, nickel, chromium, molybdenum, boron, titanium, silicon, vanadium, tungsten, cobalt, and/or niobium). The prealloyed powders may include superalloys. The superalloys may comprise iron, nickel, cobalt, chromium, tungsten, molybdenum, tantalum, niobium, titanium, and/or aluminum.

The resin used to fabricate the thermal management device may comprise a ceramic material. The ceramic material may comprise metal (e.g., aluminum, platinum, titanium, etc.), non-metal (e.g., oxygen, nitrogen, etc.), and/or metalloid (e.g., germanium, silicon, etc.) atoms primarily held in ionic and/or covalent bonds. A metal may be any element selected from the group consisting of aluminum, platinum, calcium, magnesium, barium, scandium, titanium, vanadium, chromium, manganese, iron, cobalt, nickel, copper, zinc, yttrium, niobium, molybdenum, ruthenium, rhodium, silver, cadmium, actinium, and gold. A non-metal may be any element selected from the group consisting of hydrogen, carbon, nitrogen, oxygen, phosphorus, sulfur, selenium, fluorine, chlorine, bromine, iodine, astatine, tennessine, helium, neon, argon, krypton, xenon, radon, and oganesson. A metalloid may be any element selected from the group consisting of arsenic, tellurium, germanium, silicon, antimony, boron, polonium, astatine, and selenium. The ceramic material may be, for example, aluminide, boride, beryllia, carbide, chromium oxide, hydroxide, sulfide, nitride, mullite, kyanite, ferrite, titania zirconia, yttria, and/or magnesia.

The resin used to fabricate the thermal management device may comprise one or more polymers. The one or more polymers may comprise monomers to be polymerized into the one or more polymers, oligomers to be cross-linked into the one or more polymers, or both. The monomers may be of the same or different types. An oligomer may comprise two or more monomers that are covalently linked to each other. The oligomer may be of any length, such as at least 2 (dimer), 3 (trimer), 4 (tetramer), 5 (pentamer), 6 (hexamer), 7, 8, 9, 10, 20, 30, 40, 50, 100, 200, 300, 400, 500, or more monomers. The one or more polymers may comprise a homopolymer and/or a copolymer. The homopolymer may comprise one or more identical monomer units. The copolymer may be a linear copolymer or a branched copolymer. The copolymer may be an alternating copolymer, periodic copolymer, statistical copolymer, random copolymer, and/or block copolymer. Examples of monomers may include one or more of hydroxyethyl methacrylate; n-Lauryl acrylate; tetrahydrofurfuryl methacrylate; 2,2,2-trifluoroethyl methacrylate; isobornyl methacrylate; polypropylene glycol monomethacrylates, aliphatic urethane acrylate (i.e., Rahn Genomer 1122); hydroxyethyl acrylate; n-Lauryl methacrylate; tetrahydrofurfuryl acrylate; 2,2,2-trifluoroethyl acrylate; isobornyl acrylate; polypropylene glycol monoacrylates; trimethylpropane triacrylate; trimethylpropane trimethacrylate; pentaerythritol tetraacrylate; pentaerythritol tetraacrylate; triethyleneglycol diacrylate; triethylene glycol dimethacrylate; tetrathyleneglycol diacrylate; tetrathylene glycol dimethacrylate; neopentyldimethacrylate; neopentylacrylate; hexane dioldimethacylate; hexane diol diacrylate; polyethylene glycol 400 dimethacrylate; polyethylene glycol 400 diacrylate; diethylglycol diacrylate; diethylene glycol dimethacrylate; ethyleneglycol diacrylate; ethylene glycol dimethacrylate; ethoxylated bis phenol A dimethacrylate; ethoxylated bis phenol A diacrylate; bisphenol A glycidyl methacrylate; bisphenol A glycidyl acrylate; ditrimethylolpropane tetraacrylate; and ditrimethylolpropane tetraacrylate.

The resin used to fabricate the thermal management device may comprise one or more composite materials. The one or more composite materials may comprise fiberglass, carbon fibers, carbon nanofibers, fiber-reinforced polymers, carbon-fiber-reinforced polymers, and/or glass-reinforced plastics.

Referring to FIG. 7, the three-dimensional (3D) printing system 700 may include a deposition head 705 that comprises a nozzle 707 that is in fluid communication with a source of the viscous liquid 709. The source of the viscous liquid 709 may be a syringe. The syringe may be operatively coupled to a syringe pump. The syringe pump can direct the syringe in a positive direction (from the source of the viscous liquid 709 towards the nozzle 707) to dispense the viscous liquid. The syringe pump can direct the syringe in a negative direction (away from the nozzle 707 towards the source of the viscous liquid 709) to retract any excess viscous liquid in the nozzle and/or on the print window back into the syringe. The deposition head 705 may be configured to move across the open platform 701 comprising the print window 702 to deposit the film of the viscous liquid 704. In some cases, the three-dimensional (3D) printing system 700 may comprise an additional source of an additional viscous liquid that is in fluid communication with the nozzle 707 or an additional nozzle of the deposition head 705. In some cases, the three-dimensional (3D) printing system 700 may comprise an additional deposition head comprising an additional nozzle that is in fluid communication with an additional source of an additional viscous liquid. In some cases, the three-dimensional (3D) printing system 700 may comprise three or more deposition heads and three or more sources of the same or different viscous liquids.

The viscous liquid comprising the resin and the plurality of particles may be stored in a source of the viscous liquid. The source of the viscous liquid may be a cup, container, syringe, or any other repository that can hold the viscous liquid. The source of the viscous liquid may in fluid communication (e.g., via a passageway) with the nozzle of the deposition head. The source of the viscous liquid may be connected to a flow unit. The flow unit may provide and control flow of the viscous liquid from the source of the viscous liquid towards the nozzle, thereby dispensing the viscous liquid. Alternatively or in addition to, the flow unit may provide and control flow of the viscous liquid in a direction away from the nozzle and towards the source of the viscous liquid, thereby retrieving the viscous liquid. The flow unit may use pressure mechanisms to control the speed and direction of the flow of the viscous liquid. The flow unit may be a syringe pump, vacuum pump, an actuator (e.g., linear, pneumatic, hydraulic, etc.), a compressor, or any other suitable device to exert pressure (positive or negative) to the viscous liquid in the source of the viscous liquid. A controller may be operatively coupled to the flow unit the control the speed, duration, and/or direction of the flow of the viscous liquid.

The source of the viscous liquid may comprise a sensor (e.g., an optical sensor) to detect the volume of the viscous liquid. The controller may be operatively coupled to the sensor to determine when the source of the viscous liquid may be replenished with new viscous liquid. Alternatively or in addition to, the source of the viscous liquid may be removable. The controller may determine when the source of the viscous liquid may be replaced with a new source of the viscous liquid comprising with the viscous liquid.

The three-dimensional (3D) printing system 700 of FIG. 7 may be configured to move the deposition head 705 across the open platform 701 and dispense the viscous liquid 704 through the nozzle 707 to deposit one or more layers of a film of the viscous liquid 704 over the print window 702. The deposition head 705 may be configured to move across the open platform 701 and deposit the film of the viscous liquid 704 over the print window 702. The deposition head 705 may be configured to deposit the viscous liquid 704 in a configuration such that the resulting green part generated by photopolymerization corresponds to the thermal management device, a portion of the thermal management device, a fin of the thermal management device, a portion of the fin, etc. The deposition head 705 may be configured to deposit the viscous liquid 704 in a configuration such that the green part generated by photopolymerization corresponds to a thermal management device with, for example, an array of fins in a staggered arrangement.

The film of the viscous liquid 704 may have a thickness ranging between about 1 micrometer (μm) to about 1000 μm. The film of the viscous liquid 704 may have a thickness of at least about 1 μm, 2 μm, 3 μm, 4 μm, 5 μm, 6 μm, 7 μm, 8 μm, 9 μm, 10 μm, 20 μm, 30 μm, 40 μm, 50 μm, 60 μm, 70 μm, 80 μm, 100 μm, 200 μm, 300 μm, 400 μm, 500 μm, 600 μm, 700 μm, 800 μm, 900 μm, 1000 μm, or more. The film of the viscous liquid 704 may have a thickness of at most about 1000 μm, 900 μm, 800 μm, 700 μm, 600 μm, 500 μm, 400 μm, 300 μm, 200 μm, 100 μm, 90 μm, 80 μm, 70 μm, 60 μm, 50 μm, 40 μm, 30 μm, 20 μm, 10 μm, 9 μm, 8 μm, 7 μm, 6 μm, 5 μm, 4 μm, 3 μm, 2 μm, 1 μm, or less. The thickness of the film of the viscous liquid 704 may have a tolerance ranging between about 1 μm to about 10 μm. The thickness of the film of the viscous liquid 704 may have a tolerance of at least about 1 μm, 2 μm, 3 μm, 4 μm, 5 μm, 6 μm, 7 μm, 8 μm, 9 μm, 10 μm, or more. The thickness of the film of the viscous liquid 704 may have a tolerance of at most about 10 μm, 9 μm, 8 μm, 7 μm, 6 μm, 5 μm, 4 μm, 3 μm, 2 μm, 1 μm, or less.

The deposition head 705 may comprise a nozzle 707. The nozzle 707 may be in fluid communication with the source of the viscous liquid 704. The deposition head 705 may dispense the viscous liquid 704 over the print window 702 through the nozzle 707 as a process of depositing the film of the viscous liquid 704 over the print window 702. The deposition head 705 may be configured to deposit the viscous liquid 704 in a configuration such that the resulting green part generated by photopolymerization corresponds to the thermal management device, a portion of the thermal management device, a fin of the thermal management device, a portion of the fin, etc. The deposition head 705 may retrieve any excess viscous liquid 704 from the print window 702 back into the source of the viscous liquid 704 through the nozzle 707. In some cases, the source of the viscous liquid 704 may be connected to the flow unit to provide and control flow of the viscous liquid towards or away from the nozzle 707 of the deposition head 705. Alternatively or in addition to, the nozzle 707 may comprise a nozzle flow unit that provides and controls flow of the viscous liquid towards or away from the print window 702. Examples of the nozzle flow unit include a piezoelectric actuator and an auger screw that is connected to an actuator.

The deposition head may comprise a wiper. The wiper may be movable along a direction towards and/or away from the print window. The wiper may have a variable height relative to the print window. The deposition head may comprise an actuator connected to the wiper to control movement of the wiper in a direction towards and away from the print window. The actuator may be a mechanical, hydraulic, pneumatic, or electro-mechanical actuator. The controller may be operatively coupled to the actuator to control the movement of the wiper in a direction towards and away from the print window. Alternatively or in addition to, a vertical distance between the wiper and the print window (e.g., a distance perpendicular to the print window) may be static. The deposition head may comprise a plurality of wipers with different configurations. In some cases, the deposition head may comprise the nozzle and three wipers.

The wiper of the deposition head may be configured to (i) reduce or inhibit flow of the viscous liquid out of the deposition head, (ii) flatten the film of the viscous liquid, and/or (iii) remove any excess of the viscous liquid. In an example, the wiper may be configured to be in contact with the print window and reduce or inhibit flow of the viscous liquid out of the deposition head. In another example, the wiper may be movable along a direction away from the print window and configured to flatten the film of the viscous liquid. The wiper may flatten the film of the viscous liquid to a defined height (or thickness). In a different example, the wiper may be movable along a direction away from the print window and configured to remove the excess of the viscous liquid.

The wiper may comprise polymer (e.g., rubber, silicone), metal, or ceramic. The wiper may comprise (e.g., entirely or as a coating) one or more fluoropolymers that prevent adhesion of the viscous liquid on the wiper. Examples of the one or more fluoropolymers include polyvinylidene fluoride (PVDF), ethylenchlorotrifluoroethylene (ECTFE), ethylenetetrafluoroethylene (ETFE), polytetrafluoroethylene (PTFE), perfluoroalkoxy (PFA), and modified fluoroalkoxy (a copolymer of tetrafluoroethylene and perfluoromethylvinylether, also known as MFA).

The wiper of the deposition head may be a blade (e.g., a squeegee blade, a doctor blade). The blade may have various shapes. The blade may be straight and/or curved. The wiper may be a straight blade with a flat surface. The wiper may be a straight blade with a curved surface. The wiper may be a curved blade (curved along the long axis of the wiper) with a flat surface. The wiper may be a curved blade (curved along the long axis of the wiper) with a curved surface. In some cases, the wiper may comprise at least one straight portion and at least one curved portion along its length. For example, the wiper may be a blade comprising a straight central portion between two curved portions.

In an example, the wiper may be a straight blade and configured perpendicular to the print window. In another example, the wiper may be a straight blade with a flat surface, and tilted at an angle. When the deposition head moves to remove any excess viscous liquid from the print window, the tilted straight blade may concentrate the excess resin at the bottom of the blade. The straight blade may be tilted at an angle ranging between about 1 degree to about 50 degrees. The straight blade may be tilted at an angle of at least about 1 degree, 2 degrees, 3 degrees, 4 degrees, 5 degrees, 6 degrees, 7 degrees, 8 degrees, 9 degrees, 10 degrees, 20 degrees, 30 degrees, 40 degrees, 50 degrees, or more. The straight blade may be tiled at an angle of at most about 50 degrees, 40 degrees, 30 degrees, 20 degrees, 10 degrees, 9 degrees, 8 degrees, 7 degrees, 6 degrees, 5 degrees, 4 degrees, 3 degrees, 2 degrees, 1 degree, or less.

In another example, the wiper may be a straight blade with a curved surface (a curved blade). When the deposition head moves to remove any excess viscous liquid from the print window, the curved blade may concentrate the excess resin in the center of the concave surface of the wiper. The curved blade may reduce or prevent the excess resin from spilling out from the sides of the blade. A radius of curvature of the surface of the blade may range between about 10 millimeter (mm) to about 1000 mm. The radius of curvature of the surface of the blade may be at least about 10 millimeters (mm), 20 mm, 30 mm, 40 mm, 50 mm, 60 mm, 70 mm, 80 mm, 90 mm, 100 mm, 200 mm, 300 mm, 400 mm, 500 mm, 1000 mm, or more. The radius of curvature of the surface of the blade may be at most about 1000 mm, 500 mm, 400 mm, 300 mm, 200 mm, 100 mm, 90 mm, 80 mm, 70 mm, 60 mm, 50 mm, 40 mm, 30 mm, 20 mm, 10 mm, or less.

The wiper of the deposition head may be a roller. The roller may have a surface that is flat or textured. The roller may be configured to rotate clockwise and/or counterclockwise while the deposition head moves across the print window. Alternatively or in addition to, the roller may be configured to be static while the deposition head moves across the print window. In some cases, the wiper of the deposition head may be a rod. The rod may have a surface that is flat or textured. The rod may be configured to rotate clockwise and/or counterclockwise while the deposition head moves across the print window. Alternatively or in addition to, the rod may be configured to be static while the deposition head moves across the print window. In an example, the rod may be a wire wound rod, also known as a Meyer rod.

The deposition head may comprise a slot die. The slot die may be configured to move along a direction away from the print window. The slot die may be height adjustable with respect to the print window. The slot die may comprise a channel in fluid communication with the source of the viscous liquid. The channel may comprise a first opening to receive the viscous liquid from the source of the viscous liquid. The channel may comprise a second opening opposite of the first opening to dispense the viscous liquid to the print window. The second opening may be an injection point. The channel may have a reservoir between the first and second openings to hold a volume of the viscous liquid. The injection point of the slot die may comprise a flat surface to flatten the film of the viscous liquid to a defined height (or thickness).

The deposition head comprising the slot die may include a separate nozzle to suction and retrieve any excess viscous liquid from the film of the viscous liquid during printing. The separate nozzle of the deposition head comprising the slot die may be in fluid communication with a repository to collect the excess viscous liquid. The repository may be a recycling bin. The repository may also be in fluid communication with the slot die to send the excess viscous liquid collected in the repository back into the reservoir of the slot die. Alternatively or in addition to, the collected excess viscous liquid may be removed for reprocessing. The reprocessing of the collected excess viscous liquid may comprise (i) filtering out any polymerized solid particulates, (ii) filtering out any of the plurality of particles that may be greater than a target particle size, (iii) remixing the viscous liquid to ensure homogeneity, and/or (iv) removing at least a portion of air entrapped in the viscous liquid. The at least the portion of air entrapped in the viscous liquid may be removed by centrifuging the viscous liquid.

The three-dimensional (3D) printing system may further comprise an additional deposition head comprising an additional nozzle. The additional nozzle of the additional deposition head may be in fluid communication with an additional source of an additional viscous liquid. The nozzle of the deposition head of the three-dimensional (3D) printing system may be in fluid communication with the source of the viscous liquid and the additional source of the additional viscous liquid. Alternatively or in addition to, the deposition head may comprise a first nozzle in fluid communication with the source of the viscous liquid, and (b) a second nozzle in fluid communication with the additional source of the additional viscous liquid. The presence of the additional source of the additional viscous liquid may allow for printing of at least a portion of one or more components (e.g., channels, fins, etc.) of the thermal management device using multiple materials (multi-materials) in different layers and/or in different portions within the same layer.

The viscous liquid and the additional viscous liquid may be the same. As an alternative, the viscous liquid and the additional viscous liquid may be different. The viscous liquid and the additional viscous liquid may comprise different types of the photoactive resin, the plurality of particles, or both. Alternatively or in addition to, the viscous liquid and the additional viscous liquid may comprise different amounts (concentrations in terms of weight by volume) of the photoactive resin, the plurality of particles, or both. In an example, the viscous liquid may comprise metallic particles, and the additional viscous liquid may comprise ceramic particles. A first concentration of the metallic particles in the viscous liquid and a second concentration of the ceramic particles in the additional viscous liquid may be the same or different. A first photoactive resin in the viscous liquid and a second photoactive resin in the additional viscous liquid may be the same or different. In another example, the viscous liquid may comprise a first type of metallic particles, and the additional viscous liquid may comprise a second type of metallic particles. In a different example, the viscous liquid may comprise ceramic particles at a first concentration, and the additional viscous liquid may comprise the same ceramic particles at a second concentration that is different from the first concentration.

The three-dimensional (3D) printing system may comprise a build head. The build head may be configured to hold and/or support at least a portion (e.g., a layer) of the thermal management device generated using the resin. During printing, the at least the portion of the thermal management device may be printed on the build head. The build head may be configured to move relative to the print window during printing. The build head may be configured to move along a direction away from the print window during printing. Such movement may be relative movement, and thus the moving piece may be the build head, the print window, or both. The build head may be connected to a build head actuator for moving the build head relative to the print window. The build head actuator may be a mechanical, hydraulic, pneumatic, or electro-mechanical actuator. Alternatively or in addition to, the open platform comprising the print window may be connected to an open platform actuator for moving the open platform relative to the build head. The open platform actuator may be a mechanical, hydraulic, pneumatic, or electro-mechanical actuator. The controller may be operatively coupled to the build head actuator and/or the open platform actuator to control the relative distance between the build head and the print window. The relative distance between the build head and the print window may be adjusted to adjust a thickness of a layer within the at least the portion of the 3D object (e.g., the thermal management device) and/or at least a portion of a green part corresponding to the thermal management device.

The three-dimensional (3D) printing system may comprise a cleaning zone. The cleaning zone may be configured adjacent to the open platform. The cleaning zone may be configured in a path of movement of the deposition head across the open platform. The cleaning zone may be configured to clean the deposition head. Cleaning the deposition head may (i) improve reliability and reproducibility of printing at least the portion of the thermal management device and/or printing at least a portion of a green part corresponding to the thermal management device, and (ii) reduce wear and tear of the deposition head. The deposition head may be static or move relative to the cleaning zone while the cleaning zone cleans the deposition head. The cleaning zone may comprise a wiper, a nozzle configured to provide at least one cleaning solvent, or both. The wiper of the cleaning zone may be a blade (e.g., a doctor blade), a roller, or a rod. In some cases, one or more wipers of the cleaning zone may come in contact with one or more wipers of the deposition head and remove any excess resin remaining on the one or more wipers of the deposition head. In some cases, one or more nozzles of the cleaning zone may dispense or jet the at least one cleaning solvent to the one or more wipers of the deposition head for cleaning. The one or more nozzles of the cleaning zone may be in fluid communication with at least one source of the at least one cleaning solvent. At least a portion of the viscous liquid may be soluble in the at least one cleaning solvent. The cleaning zone may comprise a repository that can hold the excess viscous liquid that is removed from the deposition head and/or the at least one cleaning solvent.

The three-dimensional (3D) printing system may comprise a repository (e.g., vat or container) adjacent to the open platform. The repository may be configured to collect the viscous liquid from the film of the deposition head. The repository may be configured to hold any excess viscous liquid that is removed from the print window by the deposition head. After removing any excess viscous liquid from the print window, the deposition head may move and use at least one wiper to collect the excess viscous liquid into the repository. The repository may be a recycling bin. The repository may be in fluid communication with the source of the viscous liquid to recycle the collected excess viscous liquid for printing. Alternatively or in addition to, the collected excess viscous liquid may be removed for reprocessing. The reprocessing of the collected excess viscous liquid may comprise (i) filtering out any polymerized solid particulates, (ii) filtering out any of the plurality of particles that may be greater than a target particle size, (iii) remixing the viscous liquid to ensure homogeneity, and/or (iv) removing at least a portion of air entrapped in the viscous liquid. The at least the portion of air entrapped in the viscous liquid may be removed by centrifuging the viscous liquid. In some cases, the repository may comprise a sensor (e.g., an optical sensor or a weight scale) to detect when the repository is full and/or when an amount of the collected excess viscous liquid is above a predefined threshold.

The three-dimensional (3D) printing system may comprise a sensor. The sensor may be configured to move across the open platform and/or measure a thickness of at least a portion of the film of the viscous liquid. The sensor may assess integrity of the film of the viscous liquid before inducing polymerization of the polymeric precursors in the photoactive resin in the film of the viscous liquid. The sensor may detect any variation in thickness across the film. The sensor may detect any irregularities (e.g., defects, empty spots, solid particles, etc.) in the film. The sensor may be configured to perform quality control after printing at least a portion (e.g., a layer) of the 3D object. The sensor may scan a remaining portion of the film of the viscous liquid after printing, and the controller that is operatively coupled to the sensor may determine if the previous printing process was successful or not. The sensor may be an optical profilometer (e.g., an in-line profilometer).

The three-dimensional (3D) printing system may comprise a transparent film adjacent to the open platform and configured to hold the film of the viscous liquid. The transparent film may cover the print window. The transparent film may comprise one or more fluoropolymers that reduce adhesion of a cured portion of the viscous liquid on the transparent film. Examples of the one or more fluoropolymers include polyvinylidene fluoride (PVDF), ethylenchlorotrifluoroethylene (ECTFE), ethylenetetrafluoroethylene (ETFE), polytetrafluoroethylene (PTFE), perfluoroalkoxy (PFA), and modified fluoroalkoxy (a copolymer of tetrafluoroethylene and perfluoromethylvinylether, also known as MFA). The transparent film may reduce or eliminate any undesirable force (e.g., a sliding or rotational mechanism) that may otherwise be needed to separate the cured portion of the viscous liquid and the print window. This may yield a reduced failure rate and increased printing speed.

The three-dimensional (3D) printing system may comprise an optical source that provides a light through the print window for curing the at least the portion of the film of the viscous liquid. The optical source may include lamps (e.g., incandescent lamps, halogen lamps, carbon arc lamps, or discharge lamps), torches, lasers, light emitting diodes (LEDs), super luminescent diodes (SLDs), gas-filled tubes such as fluorescent bulbs, or any other equipment capable of producing a stream of photons. The optical source may emit electromagnetic waves with a wavelength ranging from about 200 nm to about 700 nm. The optical source may include sources of ultraviolet light. In some cases, a light of the optical source may comprise a first wavelength for curing the photoactive resin in a first portion of the film of the viscous liquid. The first wavelength may activate the at least one photoinitiator of the photoactive resin, thereby initiating curing of the polymeric precursors into the polymeric material. The light may be a photoinitiation light, and the first portion of the film may be a photoinitiation layer. The optical source may provide an additional light having a second wavelength for inhibiting curing of the photoactive resin in a second portion of the film of the viscous liquid. The first wavelength and the second wavelength may be different. In some cases, the photoactive resin may comprise at least one photoinhibitor. The second wavelength may activate the at least one photoinhibitor in the photoactive resin, thereby inhibiting curing of the polymeric precursors into the polymeric material. The additional light may be a photoinhibition light, and the second portion of the film of the viscous liquid may be a photoinhibition layer. In some cases, a dual-wavelength projector (e.g., a dual-wavelength laser) may be used as the optical source to provide both the photoinitiation light and the photoinhibition light.

The light of the optical source may comprise a first wavelength for curing the photoactive resin in a first portion of the film of the viscous liquid. The first wavelength may activate the at least one photoinitiator of the photoactive resin, thereby initiating curing of the polymeric precursors into the polymeric material. The polymeric material may encapsulate the plurality of particles in the photoactive resin. The photoactive resin and/or the polymeric precursors may be cured in a manner and/or a configuration such that the portion of the film of the viscous liquid that is cured corresponds to the size and/or the shape of the thermal management device or a portion of the thermal management device. The photoactive resin and/or the polymeric precursors may be cured in a manner and/or a configuration such that a resulting green part generated by photopolymerization or curing corresponds to the size and/or the shape of the thermal management device or a portion of the thermal management device. The light may be a photoinitiation light, and the first portion of the film may be a photoinitiation layer. The light may be a patterned light. The three-dimensional (3D) printing system may further comprise an additional optical source comprising an additional light having a second wavelength for inhibiting curing of the photoactive resin in a second portion of the film of the viscous liquid. The additional optical source may include lamps (e.g., incandescent lamps, halogen lamps, carbon arc lamps, or discharge lamps), torches, lasers, light emitting diodes (LEDs), super luminescent diodes (SLDs), gas-filled tubes such as fluorescent bulbs, or any other equipment capable of producing a stream of photons. The additional optical source may emit electromagnetic waves with a wavelength ranging from about 200 nm to about 700 nm. The additional optical source may include sources of ultraviolet light. The first wavelength of the light emitted from the optical source may be different than the second wavelength of the additional light emitted from the additional optical source. The second wavelength may activate the at least one photoinhibitor of the photoactive resin, thereby inhibiting curing of the polymeric precursors into the polymeric material. The additional light may be a photoinhibition light, and the second portion of the film of the viscous liquid may be a photoinhibition layer. In some cases, the additional light may be a flood light.

The optical source that directs the photoinitiation light may be a mask-based display, such as a liquid crystal display (LCD) device, or light emitting, such as a discrete light emitting diode (LED) array device. Alternatively, the optical source that directs the photoinitiation light may be a digital light processing (DLP) device, including a digital micro-mirror device (DMD) for producing patterned light that can selectively illuminate and cure 3D printed structures. The initiation light directed from the DLP device may pass through one or more projection optics (e.g., a light projection lens) prior to illuminating through the print window and to the film of the viscous liquid. The one or more projection optics may be integrated in the DLP device. Alternatively or in addition to, the one or more projection optics or may be configured between the DLP device and the print window. A relative position of the one or more projection optics relative to the DLP device and the print window may be adjustable to adjust an area of the photoinitiation layer in the film of the viscous liquid. The area of the photoinitiation layer may be defined as a build area. In some cases, the one or more projection optics may be on a projection optics platform. The projection optics platform may be coupled to an actuator that directs movement of the projection optics platform. The controller may be operatively coupled to the actuator to control movement of the projection optics platform. The controller may direct the actuator (e.g., a screw-based mechanism) to adjust a relative position of the one or more projection optics to the DLP device and the print window during printing the 3D object.

The additional optical source that directs the photoinhibition light may comprise a plurality of light devices (e.g., a plurality of light emitting diodes (LEDs)). The light devices may be adjacent to a light platform. The light platform may be configured (i) move relative to the print window and (ii) yield a uniform projection of the photoinhibition light within the photoinhibition layer in the film of the viscous liquid adjacent to the print window. The position of the light platform may be independently adjustable with respect to a position of the optical source that directs the photoinitiation light. The light platform comprising the plurality of light devices may be arranged with respect to the print window such that a peak intensity of each of the plurality of light devices is directed at a different respective position (e.g., corner or other position) of the build area. In an example, the build area may have four corners and a separate beam of light (e.g., a separate LED) may be directed to each corner of the build area. The beams of photoinhibition light from the plurality of light devices may overlap to provide the uniform projection of the photoinhibition light within the photoinhibition layer. The light platform may be coupled to an actuator that is configured to direct movement of the light platform. The controller may be operatively coupled to the actuator to control movement of the light platform. The controller may direct the actuator (e.g., a screw-based mechanism) to adjust a relative position of the plurality of light devices to the print window during printing the 3D object. In some cases, the one or more projection optics to the DLP device (for the photoinitiation light) may be on the light platform.

Whether using one optical source or two optical sources, a photoinhibition light may be configured to create a photoinhibition layer in the film of the viscous liquid adjacent to the print window. The photoinhibition light may be configured to form the photoinhibition layer in the film of the viscous liquid adjacent to the transparent film that is covering the print window. Furthermore, the photoinitiation light may be configured to cure the photoactive resin in the photoinitiation layer that resides between the photoinhibition layer and the build head. The photoactive resin in the photoinitiation layer may be cured into at least a portion of the thermal management device and/or at least a portion of a green part corresponding to the thermal management device. The photoactive resin and/or the polymeric precursors may be cured in a manner and/or a configuration such that the portion of the film of the viscous liquid that is cured corresponds to the size and/or the shape of the thermal management device or a portion of the thermal management device. The photoactive resin and/or the polymeric precursors may be cured in a manner and/or a configuration such that a resulting green part generated by photopolymerization or curing corresponds to the size and/or the shape of the thermal management device or a portion of the thermal management device. In some examples, the photoactive resin in the photoinitiation layer may be cured into at least a portion of the thermal management device (e.g., a fin, a portion of the fin, etc.) and/or at least a portion of a green part corresponding to the thermal management device, a portion of the thermal management device, a fin of the thermal management device, a portion of the fin, etc. The photoinitiation light may be configured to cure the photoactive resin in the photoinitiation layer that resides between the photoinhibition layer and the at least the portion of the 3D structure (e.g., a portion of a green part corresponding to a portion of the thermal management device) adjacent to the build head.

As illustrated in FIG. 7, the three-dimensional (3D) printing system 700 may be further configured to direct light through the print window 702 to the one or more layers of the film to cure the photoactive resin in at least a portion of the one or more layers of the film, thereby printing at least a portion of the thermal management device and/or a green part corresponding to at least a portion of the thermal management device. The photoactive resin and/or the polymeric precursors may be cured in a manner and/or a configuration such that the portion of the film of the viscous liquid that is cured corresponds to the size and/or the shape of the thermal management device or a portion of the thermal management device. The photoactive resin and/or the polymeric precursors may be cured in a manner and/or a configuration such that a resulting green part generated by photopolymerization or curing corresponds to the size and/or the shape of the thermal management device or a portion of the thermal management device.

As shown in FIG. 7, illumination (e.g., a light from an optical source) may be transmitted through the print window 702 to cure at least a portion of the film of the viscous liquid 704 to print at least a portion of a 3D structure 708. The at least a portion of the 3D structure 708 may correspond to a portion of the thermal management device (e.g., a fin, a portion of the fin, etc.) or at least a portion of a green part corresponding to thermal management device, a portion of the thermal management device, a fin of the thermal management device, a portion of the fin, etc. The at least the portion of the 3D structure 708 is illustrated in FIG. 7 as a block; however, in practice a wide variety of complicated shapes may be printed. The at least the portion of the 3D structure 708 may include entirely solid structures, hollow core prints, lattice core prints, and generative design geometries.

The illumination transmitted through the print window 702 may initiate photopolymerization of at least a portion of the film of the viscous liquid 704. Photopolymerization of the polymeric precursors into the polymeric material may be controlled by one or more photoactive species, such as a photoinitiator. The at least one photoinitiator may be configured to initiate formation of the polymeric material from the polymeric precursor. For example, the at least one photoinitiator may be a photon-absorbing compound that (i) is activated by a first light comprising a first wavelength and (ii) initiates photopolymerization of the polymeric precursors. The first light may comprise wavelengths ranging between about 420 nanometers (nm) to about 510 nm. In an example, the first wavelength to induce photoinitiation may be about 460 nm.

Relative rates of the photoinitiation by the at least one photoinitiator may be controlled by adjusting the intensity and/or duration of the first light. By controlling the relative rates of the photoinitiation, an overall rate and/or amount (degree) of polymerization of the polymeric precursors into the polymeric material may be controlled. Controlling the relative rates of the photoinitiation may help to (i) prevent polymerization of the polymeric precursors at an interface between a print window and the resin, (ii) control the rate at which polymerization takes place in the direction away from the print window, and/or (iii) control a thickness of the polymeric material within the film of the viscous liquid and/or resin.

The photoinitiator may be a photon-absorbing compound that (i) is activated by a first light comprising a first wavelength and (ii) initiates photopolymerization of the polymeric precursors.

Examples of photoinitiators include one or more of benzophenones, thioxanthones, anthraquinones, benzoylformate esters, hydroxyacetophenones, alkylaminoacetophenones, benzil ketals, dialkoxyacetophenones, benzoin ethers, phosphine oxides acyloximino esters, alphahaloacetophenones, trichloromethyl-S-triazines, titanocenes, dibenzylidene ketones, ketocoumarins, dye sensitized photoinitiation systems, maleimides, and mixtures thereof. Examples of photoinitiators in a photoactive resin include one or more of 1-hydroxy-cyclohexyl-phenyl-ketone (Irgacure™ 184; BASF, Hawthorne, NJ); a 1:1 mixture of 1-hydroxy-cyclohexyl-phenyl-ketone and benzophenone (Irgacure™ 500; BASF); 2-hydroxy-2-methyl-1-phenyl-1-propanone (Darocur™ 1173; BASF); 2-hydroxy-1-[4-(2-hydroxyethoxy)phenyl]-2-methyl-1-propanone (Irgacure™ 2959; BASF); methyl benzoylformate (Darocur™ MBF; BASF); oxy-phenyl-acetic acid 2-[2-oxo-2-phenyl-acetoxy-ethoxy]-ethyl ester; oxy-phenyl-acetic 2-[2-hydroxy-ethoxy]-ethyl ester; a mixture of oxy-phenyl-acetic acid 2-[2-oxo-2-phenyl-acetoxy-ethoxy]-ethyl ester and oxy-phenyl-acetic 2-[2-hydroxy-ethoxy]-ethyl ester (Irgacure™ 754; BASF); alpha,alpha-dimethoxy-alpha-phenylacetophenone (Irgacure™ 651; BASF); 2-benzyl-2-(dimethylamino)-1-[4-(4-morpholinyl)-phenyl]-1-butanone (Irgacure™ 369; BASF); 2-methyl-1-[4-(methylthio)phenyl]-2-(4-morpholinyl)-1-propanone (Irgacure™ 907; BASF); a 3:7 mixture of 2-benzyl-2-(dimethylamino)-1-[4-(4-morpholinyl) phenyl]-1-butanone and alpha,alpha-dimethoxy-alpha-phenylacetophenone per weight (Irgacure™ 1300; BASF); diphenyl-(2,4,6-trimethylbenzoyl) phosphine oxide (Darocur™ TPO; BASF); a 1:1 mixture of diphenyl-(2,4,6-trimethylbenzoyl)-phosphine oxide and 2-hydroxy-2-methyl-1-phenyl-1-propanone (Darocur™ 4265; BASF); phenyl bis(2,4,6-trimethyl benzoyl) phosphine oxide, which can be used in pure form (Irgacure™ 819; BASF, Hawthorne, NJ) or dispersed in water (45% active, Irgacure™ 819DW; BASF); 2:8 mixture of phosphine oxide, phenyl bis(2,4,6-trimethyl benzoyl) and 2-hydroxy-2-methyl-1-phenyl-1-propanone (Irgacure™ 2022; BASF); Irgacure™ 2100, which comprises phenyl-bis(2,4,6-trimethylbenzoyl)-phosphine oxide); bis-(eta 5-2,4-cyclopentadien-1-yl)-bis-[2,6-difluoro-3-(1H-pyrrol-1-yl) phenyl]-titanium (Irgacure™ 784; BASF); (4-methylphenyl) [4-(2-methylpropyl) phenyl]-iodonium hexafluorophosphate (Irgacure™ 250; BASF); 2-(4-methylbenzyl)-2-(dimethylamino)-1-(4-morpholinophenyl)-butan-1-one (Irgacure™ 379; BASF); 4-(2-hydroxyethoxy)phenyl-(2-hydroxy-2-propyl)ketone (Irgacure™ 2959; BASF); bis-(2,6-dimethoxybenzoyl)-2,4,4-trimethylpentylphosphine oxide; a mixture of bis-(2,6-dimethoxybenzoyl)-2,4,4-trimethylpentylphosphine oxide and 2 hydroxy-2-methyl-1-phenyl-propanone (Irgacure™ 1700; BASF); 4-Isopropyl-9-thioxanthenone; and mixtures thereof. Additional examples of the photoinitiator may include sulfanylthiocarbonyl and other radicals generated in photoiniferter polymerizations; sulfanylthiocarbonyl radicals used in reversible addition-fragmentation chain transfer polymerization; and/or nitrosyl radicals used in nitroxide mediate polymerization.

The at least one photoinitiator may be present in an amount ranging between about 0.001 percent by weight (wt %) to about 10 wt % in the photoactive resin. The at least one photoinitiator may be present in an amount of at least about 0.001 wt. %, 0.002 wt. %, 0.003 wt. %, 0.004 wt. %, 0.005 wt. %, 0.006 wt. %, 0.007 wt. %, 0.008 wt. %, 0.009 wt. %, 0.01 wt. %, 0.02 wt. %, 0.03 wt. %, 0.04 wt. %, 0.05 wt. %, 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, 5 wt %, 6 wt %, 7 wt %, 8 wt %, 9 wt %, 10 wt %, or more in the photoactive resin. The at least one photoinitiator may be present in an amount of at most about 10 wt %, 9 wt %, 8 wt %, 7 wt %, 6 wt %, 5 wt %, 4 wt %, 3 wt %, 2 wt %, 1 wt %, 0.9 wt %, 0.8 wt %, 0.7 wt %, 0.6 wt %, 0.5 wt %, 0.4 wt %, 0.3 wt %, 0.2 wt %, 0.1 wt %, 0.009 wt. %, 0.008 wt. %, 0.007 wt. %, 0.006 wt. %, 0.005 wt. %, 0.004 wt. %, 0.003 wt. %, 0.002 wt. %, 0.001 wt. %, or less in the photoactive resin.

As illustrated in FIG. 7, the at least the portion of the 3D structure 708 may be printed on a build head 710, which may be connected by a rod 712 to one or more 3D printing mechanisms 714. The 3D printing mechanisms 714 may include various mechanical structures for moving the build head 710 in a direction towards and/or away from the open platform 701. This movement may be a relative movement, and thus moving pieces can be the build head 710, the open platform 701, or both, in various embodiments. The 3D printing mechanisms 714 may include Cartesian (xyz) type 3D printer motion systems or delta type 3D printer motion systems. The 3D printing mechanisms 714 may include one or more controllers to direct movement of the build head 710, the open platform 701, or both.

Multiple devices emitting various wavelengths and/or intensities of light, including a light projection device 726 and light sources 728, may be positioned below the print window 702 and in communication with the one or more controllers. The light sources 728 can include at least 2, 3, 4, 5, 6, or more light sources. As an alternative to the light sources 728, a single light source may be used. The light projection device 726 directs a first light having a first wavelength through the print window 702 and into the film of the viscous liquid 704 adjacent to the print window 702. The first wavelength emitted by the light projection device 726 may be selected to induce photoinitiation and may be used to create at least a portion of the 3D structure on the at least the portion of the 3D structure 708 that is adjacent to the build head 710 by curing the photoactive resin in the film of the viscous liquid 704 within a photoinitiation layer 730. The photoactive resin and/or the polymeric precursors may be cured in a manner and/or a configuration such that the portion of the film of the viscous liquid that is cured corresponds to the size and/or the shape of the thermal management device or a portion of the thermal management device. The photoactive resin and/or the polymeric precursors may be cured in a manner and/or a configuration such that a resulting green part generated by photopolymerization or curing corresponds to the size and/or the shape of the thermal management device or a portion of the thermal management device. The light projection device 726 may be utilized in combination with one or more projection optics 732 (e.g. a projection lens for a digital light processing (DLP) device), such that the light output from the light projection device 726 passes through the one or more projection optics 732 prior to illuminating the film of the viscous liquid 704 adjacent to the print window 702.

The light projection device 726 may be a DLP device including a digital micro-mirror device (DMD) for producing patterned light that can selectively illuminate and cure the photoactive resin in the photoinitiation layer 730. The light projection device 726, in communication with the one or more controllers, may receive instructions defining a pattern of illumination to be projected from the light projection device 726 into the photoinitiation layer 730 to cure a layer of the photoactive resin onto the at least the portion of the 3D structure 708.

In some cases, photoinhibition may be used in conjunction with photoinitiation in order to, for example, help prevent adhesion of the cured layer onto a print window. In such cases, the photoactive resin used to generate the thermal management device and/or a green part corresponding to the thermal management device may comprise at least one photoinhibitor. The photoinhibitor may be configured to inhibit curing of the polymerizable and/or cross-linkable component. The at least one photoinhibitor may be another photon-absorbing compound that (i) is activated by a second light comprising a second wavelength and (ii) inhibits the photopolymerization of the polymeric precursors. The at least one photoinhibitor in the photoactive resin may comprise one or more radicals that may preferentially terminate growing polymer radicals, rather than initiating polymerization of the polymeric precursors. In situations where the photoactive resin comprises at least one photoinhibitor, the three-dimensional (3D) printing system may be configured to control the photopolymerization of the polymeric precursors into the polymeric material using the at least one photoinitiator and the at least one photoinhibitor. For example, the at least one photoinitiator may be configured to initiate formation of the polymeric material from the polymeric precursor. The at least one photoinitiator may be a photon-absorbing compound that (i) is activated by a first light comprising a first wavelength and (ii) initiates photopolymerization of the polymeric precursors. The at least one photoinhibitor may be configured to inhibit formation of the polymeric material from the polymeric precursor. The at least one photoinhibitor may be another photon-absorbing compound that (i) is activated by a second light comprising a second wavelength and (ii) inhibits the photopolymerization of the polymeric precursors. The first wavelength and the second wavelength may be different. The first light and the second light may be directed by the same light source. Alternatively, the first light may be directed by a first light source and the second light may be directed by a second light source. The first light may comprise wavelengths ranging between about 420 nanometers (nm) to about 510 nm. The second light may comprise wavelengths ranging between about 350 nm to about 410 nm. In an example, the first wavelength to induce photoinitiation may be about 460 nm. The second wavelength to induce photoinhibition may be about 365 nm.

The photoinhibitor may comprise a hexaarylbiimidazole (HABI) or a functional variant thereof. The hexaarylbiimidazole may comprise a phenyl group with a halogen and/or an alkoxy substitution. In an example, the phenyl group comprises an ortho-chloro-substitution. In another example, the phenyl group comprises an ortho-methoxy-substitution. In another example, the phenyl group comprises an ortho-ethoxy-substitution. Examples of the functional variants of the hexaarylbiimidazole include: 2,2′-Bis(2-chlorophenyl)-4,4′,5,5′-tetraphenyl-1,2′-biimidazole; 2-(2-methoxyphenyl)-1-[2-(2-methoxyphenyl)-4,5-diphenyl-2H-imidazol-2-yl]-4,5-diphenyl-1H-imidazole; 2-(2-ethoxyphenyl)-1-[2-(2-ethoxyphenyl)-4,5-diphenyl-2H-imidazol-2-yl]-4,5-diphenyl-1H-imidazole; and 2,2′,4-tris-(2-Chlorophenyl)-5-(3,4-dimethoxyphenyl)-4′,5′-diphenyl-1,1′-biimidazole.

Other examples of the photoinhibitor may include one or more of: zinc dimethyl dithiocarbamate: zinc dimethyl dithiocarbamate; zinc diethyl dithiocarbamate; zinc dibutyl dithiocarbamate; nickel dibutyl dithiocarbamate; zinc dibenzyl dithiocarbamate; tetramethylthiuram disulfide; tetraethylthiuram disulfide (TEDS); tetramethylthiuram monosulfide; tetrabenzylthiuram disulfide; tetraisobutylthiuram disulfide; dipentamethylene thiuram hexasulfide; N,N′-dimethyl N,N′-di(4-pyridinyl)thiuram disulfide; 3-Butenyl 2-(dodecylthiocarbonothioylthio)-2-methylpropionate; 4-Cyano-4-[(dodecylsulfanylthiocarbonyl)sulfanyl]pentanoic acid; 4-Cyano-4-[(dodecylsulfanylthiocarbonyl)sulfanyl]pentanol; Cyanomethyl dodecyl trithiocarbonate; Cyanomethyl [3-(trimethoxysilyl)propyl] trithiocarbonate; 2-Cyano-2-propyl dodecyl trithiocarbonate; S,S-Dibenzyl trithiocarbonate; 2-(Dodecylthiocarbonothioylthio)-2-methylpropionic acid; 2-(Dodecylthiocarbonothioylthio)-2-methylpropionic acid N-hydroxysuccinimide; Benzyl 1H-pyrrole-1-carbodithioate; Cyanomethyl diphenylcarbamodithioate; Cyanomethyl methyl(phenyl)carbamodithioate; Cyanomethyl methyl(4-pyridyl)carbamodithioate; 2-Cyanopropan-2-yl N-methyl-N-(pyridin-4-yl)carbamodithioate; Methyl 2-[methyl(4-pyridinyl)carbamothioylthio]propionate; 1-Succinimidyl-4-cyano-4-[N-methyl-N-(4-pyridyl)carbamothioylthio]pentanoate; Benzyl benzodithioate; Cyanomethyl benzodithioate; 4-Cyano-4-(phenylcarbonothioylthio)pentanoic acid; 4-Cyano-4-(phenylcarbonothioylthio)pentanoic acid N-succinimidyl ester; 2-Cyano-2-propyl benzodithioate; 2-Cyano-2-propyl 4-cyanobenzodithioate; Ethyl 2-(4-methoxyphenylcarbonothioylthio)acetate; 2-Phenyl-2-propyl benzodithioate; Cyanomethyl methyl(4-pyridyl)carbamodithioate; 2-Cyanopropan-2-yl N-methyl-N-(pyridin-4-yl)carbamodithioate; Methyl 2-[methyl(4-pyridinyl)carbamothioylthio]propionate; 1,1′-Bi-1H-imidazole; and functional variants thereof. Other examples of the at least one photoinhibitor may include one or more of thiocarbamates, xanthates, dithiobenzoates, hexaarylbiimidazoles, photoinitiators that generate ketyl and other radicals that tend to terminate growing polymer chains radicals (i.e., camphorquinone (CQ) and benzophenones), atom-transfer radical polymerization (ATRP) deactivators, and/or polymeric versions thereof.

The photoinhibitor may be present in the mixture at an amount from about 0.001 percent by weight (wt. %) to about 10 wt. %. The photoinhibitor may be present in the mixture at amount of at least about 0.001 wt. %, 0.002 wt. %, 0.003 wt. %, 0.004 wt. %, 0.005 wt. %, 0.006 wt. %, 0.007 wt. %, 0.008 wt. %, 0.009 wt. %, 0.01 wt. %, 0.02 wt. %, 0.03 wt. %, 0.04 wt. %, 0.05 wt. %, 0.06 wt. %, 0.07 wt. %, 0.08 wt. %, 0.09 wt. %, 0.1 wt. %, 0.5 wt. %, 1 wt. %, 5 wt. %, 6 wt. %, 7 wt. %, 8 wt. %, 9 wt. %, 10 wt. %, or more. The photoinhibitor may be present in the mixture at an amount of at most about 10 wt. %, 9 wt. %, 8 wt. %, 7 wt. %, 6 wt. %, 5 wt. %, 1 wt. %, 0.5 wt. %, 0.1 wt. %, 0.05 wt. %, 0.04 wt. %, 0.03 wt. %, 0.02 wt. %, 0.01 wt. %, 0.009 wt. %, 0.008 wt. %, 0.007 wt. %, 0.006 wt. %, 0.005 wt. %, 0.004 wt. %, 0.003 wt. %, 0.002 wt. %, 0.001 wt. %, or less.

For photoinhibition to occur during the 3D printing, the amount of the photoinhibitor in the mixture may be sufficient to generate inhibiting radicals at a greater rate that initiating radicals are generated. One skilled in the art will understand how to manipulate the ratio of the amount of the photoinhibitor and/or the photoinitiator based on the intensity of the optical sources available, as well as the quantum yields and light absorption properties of the photoinhibitor and the photoinitiator in the mixture.

Relative rates of the photoinitiation by the at least one photoinitiator and relative rates of the photoinhibition by the at least one photoinhibitor may be controlled by adjusting the intensity and/or duration of the first light, the second light, or both. By controlling the relative rates of the photoinitiation and the photoinhibition, an overall rate and/or amount (degree) of polymerization of the polymeric precursors into the polymeric material may be controlled. Such a process may be used to (i) prevent polymerization of the polymeric precursors at an interface between a print window and the resin, (ii) control the rate at which polymerization takes place in the direction away from the print window, and/or (iii) control a thickness of the polymeric material within the film of the viscous liquid and/or resin.

As illustrated in FIG. 7, the three-dimensional (3D) printing system may include one or more light sources 728 configured to direct a second light having a second wavelength into the film of the viscous liquid 704 adjacent to the open platform 701 comprising the print window 702. The second light may be provided as multiple beams from the light sources 728 through the print window 702 simultaneously. As an alternative, the second light may be generated from the light sources 728 and provided as a single beam through the print window 702. The second wavelength emitted by the light sources 728 may be selected to induce photoinhibition in the photoactive resin in the film of the viscous liquid 704 and is used to create a photoinhibition layer 734 within the film of the viscous liquid 704 directly adjacent to the print window 702. The light sources 728 can produce a flood light to create the photoinhibition layer 734, the flood light being a non-patterned, high-intensity light. The light sources 728 may be light emitting diodes (LEDs) 736. The light sources 728 can be arranged on a light platform 738. The light platform 738 is mounted on adjustable axis rails 740. The adjustable axis rails 740 allow for movement of the light platform 738 along an axis towards or away from the print window 702. The light platform 738 and the one or more projection optics 732 may be moved independently. A relative position of the light platform comprising the light sources may be adjusted to project the second light into the photoinhibition layer 734 at the respective peak intensity and/or in a uniform projection manner. The light platform 738 may function as a heat-sink for at least the light sources 728 arranged on the light platform 738.

The respective thicknesses of the photoinitiation layer 730 and the photoinhibition layer 734 may be adjusted by the one or more controllers. This change in layer thickness(es) may be performed for each new 3D printed layer, depending on the desired thickness of the 3D printed layer, and/or the type of viscous liquid in the film of the viscous liquid 704. The thickness(es) of the photoinitiation layer 730 and the photoinhibition layer 734 may be changed, for example, by changing the intensity of the respective light emitting devices (726 and/or 728), exposure times for the respective light emitting devices, or both. By controlling relative rates of reactions between the photoactive species (e.g., at least one photoinitiator and at least one photoinhibitor), the overall rate of curing of the photoactive resin in the photoinitiation layer 730 and/or the photoinhibition layer 734 may be controlled. This process can thus be used to prevent curing from occurring at the film of the viscous liquid-print window interface and control the rate at which curing of the photoactive resin takes place in the direction normal to the film of the photoactive resin-print window interface.

A thickness of the photoinitiation layer, the photoinhibition layer, or both may be adjusted by adjusting an intensity and duration of the photoinitiation light, the photoinhibition light, or both. The thickness of the photoinitiation layer, the photoinhibition layer, or both may be adjusted to adjust the thickness of the printed layer of the at least the portion of the 3D object. Alternatively or in addition to, the thickness of the photoinitiation layer, the photoinhibition layer, or both may be adjusted by adjusting the speed at which the build head moves away in a direction away from the print window.

The green part corresponding to at least a portion of the thermal management device may comprise a binder. The binder may be any compound or resin that retains or partially retains the plurality of particles comprising the green part in a shape corresponding to the thermal management device or a portion of the thermal management device. The green part may comprise a polymeric material. The polymeric material may be a polymer (or polymeric) matrix. The polymeric material may be created by polymerizing monomers into the polymeric material and/or cross-linking oligomers into the polymeric material, as described in further detail elsewhere herein. The polymeric material may encapsulate the plurality of particles in the green part.

The green part corresponding to at least the portion of the thermal management device may be fabricated using the three-dimensional (3D) printing system disclosed herein. The green part corresponding to at least the portion of the thermal management device may be heated at a processing temperature to sinter at least a portion of the plurality of particles and to burn off at least a portion of other components (i.e., organic components). Sintering may involve using heat to fuse one or more of a plurality of particles together at one or more grain boundaries between one or more of the plurality of particles in the green part. Sintering may involve using heat to close one or more pores or a porous network created in a green part during de-binding. Alternatively, sintering may involve using heat to remove at least a portion of a polymeric material or a binder remaining in the green part after de-binding and/or pre-sintering. The heat for sintering may be supplied by a light source. Examples of a light source may include lamps, torches, lasers, light emitting diodes (LEDs), super luminescent diodes (SLDs), gas-filled tubes such as fluorescent bulbs, or any other equipment capable of producing a stream of photons. A light source may emit electromagnetic waves with a wavelength ranging from about 200 nm to about 700 nm. A light source may include sources of ultraviolet light. The light source used for sintering may be located external to the green part. Alternatively, the heat for sintering may be supplied by a source of thermal energy. Examples of a source of thermal energy may include lamps, torches, lasers, heaters, furnaces, or an open flame. A furnace may be an enclosed chamber with heat energy supplied by fuel combustion, electricity, conduction, convection, induction, radiation, or any combination thereof. The source of thermal energy may generate thermal energy through resistive heating. Resistive heating may include heating achieved by passing an electrical current through a material. The material may be a conducting material with a resistance property that may impede the movement of electrons through the material or cause electrons to collide with each other, thereby generating heat. The source of thermal energy may generate thermal energy through induction heating. Induction heating may involve the use of electromagnetic induction to generate electrical currents inside a conducting material. The electrical currents may flow through the conducting material and generate thermal energy by resistive heating. The source of thermal energy may generate thermal energy through dielectric heating. Dielectric heating may involve the use of radio wave or microwave electromagnetic radiation to cause the rotation of molecules within a material. The source of thermal energy may be a processing chamber. The temperature of the processing chamber may be regulated with any source of thermal energy disclosed herein. The processing chamber may be an oven or a furnace. The oven or furnace may be heated with various heating approaches, such as resistive heating, convective heating and/or radiative heating. Examples of the furnace include an induction furnace, electric arc furnace, gas-fired furnace, plasma arc furnace, microwave furnace, and electric resistance furnace. Such heating may be employed at a fixed or variating heating rate from an initial temperature to a target temperature or temperature range. The source of thermal energy used for sintering may be located external to the green part.

The processing temperature (i.e., the sintering temperature) for sintering the green part corresponding to the thermal management device (including the metal and/or intermetallic particles) may range between about 300 degrees Celsius to about 2200 degrees Celsius. The processing temperature for sintering the green part may be at least about 300 degrees Celsius, 350 degrees Celsius, 400 degrees Celsius, 450 degrees Celsius, 500 degrees Celsius, 550 degrees Celsius, 600 degrees Celsius, 650 degrees Celsius, 700 degrees Celsius, 750 degrees Celsius, 800 degrees Celsius, 850 degrees Celsius, 900 degrees Celsius, 950 degrees Celsius, 1000 degrees Celsius, 1050 degrees Celsius, 1100 degrees Celsius, 1150 degrees Celsius, 1200 degrees Celsius, 1250 degrees Celsius, 1300 degrees Celsius, 1350 degrees Celsius, 1400 degrees Celsius, 1450 degrees Celsius, 1500 degrees Celsius, 1550 degrees Celsius, 1600 degrees Celsius, 1700 degrees Celsius, 1800 degrees Celsius, 1900 degrees Celsius, 2000 degrees Celsius, 2100 degrees Celsius, 2200 degrees Celsius, or more. The processing temperature for sintering the green part (including the particles) may be at most about 2200 degrees Celsius, 2100 degrees Celsius, 2000 degrees Celsius, 1900 degrees Celsius, 1800 degrees Celsius, 1700 degrees Celsius, 1600 degrees Celsius, 1550 degrees Celsius, 1500 degrees Celsius, 1450 degrees Celsius, 1400 degrees Celsius, 1350 degrees Celsius, 1300 degrees Celsius, 1250 degrees Celsius, 1200 degrees Celsius, 1150 degrees Celsius, 1100 degrees Celsius, 1050 degrees Celsius, 1000 degrees Celsius, 950 degrees Celsius, 900 degrees Celsius, 850 degrees Celsius, 800 degrees Celsius, 750 degrees Celsius, 700 degrees Celsius, 650 degrees Celsius, 600 degrees Celsius, 550 degrees Celsius, 500 degrees Celsius, 450 degrees Celsius, 400 degrees Celsius, 350 degrees Celsius, 300 degrees Celsius, or less.

During sintering of the green part comprising the plurality of particles, the temperature of the processing chamber may change at a rate ranging between about 0.1 degrees Celsius per minute (degrees Celsius/min) to about 200 degrees Celsius/min. The temperature of the processing chamber may change at a rate of at least about 0.1 degrees Celsius/min, 0.2 degrees Celsius/min, 0.3 degrees Celsius/min, 0.4 degrees Celsius/min, 0.5 degrees Celsius/min, 1 degrees Celsius/min, 2 degrees Celsius/min, 3 degrees Celsius/min, 4 degrees Celsius/min, 5 degrees Celsius/min, 6 degrees Celsius/min, 7 degrees Celsius/min, 8 degrees Celsius/min, 9 degrees Celsius/min, 10 degrees Celsius/min, 20 degrees Celsius/min, 50 degrees Celsius/min, 100 degrees Celsius/min, 150 degrees Celsius/min, 200 degrees Celsius/min, or more. The temperature of the processing chamber may change at a rate of at most about 200 degrees Celsius/min, 150 degrees Celsius/min, 100 degrees Celsius/min, 50 degrees Celsius/min, 20 degrees Celsius/min, 10 degrees Celsius/min, 9 degrees Celsius/min, 8 degrees Celsius/min, 7 degrees Celsius/min, 6 degrees Celsius/min, 5 degrees Celsius/min, 4 degrees Celsius/min, 3 degrees Celsius/min, 2 degrees Celsius/min, 1 degrees Celsius/min, 0.5 degrees Celsius/min, 0.4 degrees Celsius/min, 0.3 degrees Celsius/min, 0.2 degrees Celsius/min, 0.1 degrees Celsius/min, or less.

Sintering the green part comprising the plurality of particles may involve holding at a fixed temperature between room temperature and the processing temperature for a time ranging between about 1 min to about 240 min. The sintering process may comprise holding at a fixed temperature for at least about 10 min, 20 min, 30 min, 40 min, 50 min, 60 min, 90 min, 120 min, 150 min, 180 min, 210 min, 240 min, or more. The sintering process may comprise holding at a fixed temperature for at most about 240 min, 210 min, 180 min, 150 min, 120 min, 90 min, 60 min, 50 min, 40 min, 30 min, 20 min, 10 min, 1 min, or less. During the sintering process, the temperature may not be held at a processing temperature for an extended period of time (e.g., once a target temperature is reached, the temperature may be reduced). In an example, the sintering process may increase the temperature to a first temperature and immediately (e.g., without holding at the first temperature for a period of time) lower the temperature to a second temperature that is lower than the first temperature.

Prior to sintering the plurality of particles, the green part may be treated (e.g., immersed, jetted, etc.) with a solvent (liquid or vapor). The solvent may be an extraction solvent. The extractable material may be soluble in the solvent. A first solubility of the extractable material in the solvent may be higher than a second solubility of the polymeric material in the solvent. The solvent may be a poor solvent for the polymeric material. Thus, treating the green part with the solvent may solubilize and extract at least a portion of the extractable material out of the green part into the solvent, and create one or more pores in the at least the portion of the 3D object. The one or more pores may be a plurality of pores. The green part may be treated with the solvent and heat at the same time. The one or more pores may create at least one continuous porous network in the at least the portion of the 3D object. Such process may be a solvent de-binding step.

The green part corresponding to the thermal management device may undergo de-binding prior to sintering. De-binding may include, for example, using heat to evaporate the polymeric material or at least a portion of the polymeric material that encapsulates the plurality of particles in the green part. Alternatively, de-binding may involve using heat to solubilize or vaporize at least a portion of the polymeric material and/or binder in the green part. Solubilizing may involve the use of heat to remove at least a portion of the polymeric material or binder from the green part in a liquid form. Vaporizing may involve the use of heat to remove at least a portion of the polymeric material or binder from the green part in gas or vapor form. De-binding the green part by solubilizing or vaporizing at least a portion of the polymeric material or binder in the green part may create one or more pores in at least a portion of the green part. The one or more pores may create a continuous porous network in at least a portion of the green part. De-binding may involve using heat to decompose the polymeric material and/or binder in the green part. Decomposing the polymeric material and/or binder in the green part may involve using heat to remove at least a portion of the polymeric material and/or binder from the green part in a gas, liquid, or vapor form. Decomposing the polymeric material and/or binder may involve removing at least a portion of the polymeric material and/or binder through the one or more pores in the green part. Decomposing and/or de-binding the polymeric material and/or binder may involve using heat to remove at least a portion of the green part that does not include the plurality of particles.

The green part corresponding to the thermal management device may undergo pre-sintering prior to sintering. Pre-sintering may involve using heat to remove at least a portion of the polymeric material or binder from the green part in part through one or more pores in the green part. Pre-sintering may involve using heat to partially fuse one or more of a plurality of particles together at one or more grain boundaries between the one or more of the plurality of particles in the green part. Alternatively, pre-sintering may involve using heat to partially close one or more pores or a porous network created in a green part during de-binding. Pre-sintering may occur at a pre-sintering temperature. The pre-sintering temperature may be less than a sintering temperature. A sintering temperature may be a temperature at which one or more of a plurality of particles in a green part can fuse together at one or more grain boundaries between the one or more of the plurality of particles in the green part. The sintering temperature may be less than one or more melting temperatures of the one or more of the plurality of particles in a green part.

The three-dimensional (3D) printing system 700 of FIG. 7 may be configured to implement a method for fabricating the thermal management devices disclosed herein. The method may comprise providing a deposition head adjacent to an open platform comprising a print window. The deposition head may be movable across the open platform. The deposition head may comprise a nozzle in fluid communication with a source of a viscous liquid comprising a plurality of particles for printing the thermal management device. The viscous liquid may be a photoactive resin. The deposition head may comprise a wiper.

The method may comprise moving the deposition head across the open platform and dispensing the viscous liquid through the nozzle to deposit a film of the viscous liquid over the print window. The deposition head may be configured to dispense and/or deposit the viscous liquid in a configuration such that a green part generated by photopolymerization of the viscous liquid corresponds to the shape and/or the size of the thermal management device, a portion of the thermal management device, a fin of the thermal management device, a portion of the fin, etc. A green part may be a part that holds a plurality of particles together before the plurality of particles are fused together (e.g., through sintering) to create a 3D object (e.g., the thermal management device) comprising the plurality of particles. The green part may not be the final 3D object (i.e., further processing may be needed to generate the 3D object from the green part or a derivative of the green part). The green part may correspond to the size and/or the shape of a 3D object (e.g., a thermal management device) or a portion of the 3D object. The green part may be printed using stereolithography (SLA) and/or by photopolymerization of at least a portion of a film of a viscous liquid (e.g., a resin) that is deposited over a print window. The green part may correspond to the shape and/or size of the thermal management device or may correspond to the shape and/or size of a portion of the thermal management device. The green part may have the same shape and/or dimensions as the thermal management device or a portion of the thermal management device. The green part may have a similar shape to the thermal management device and dimensions that are proportional to the dimensions of the thermal management device or a portion of the thermal management device.

The method may comprise directing light through a print window of the three-dimensional (3D) printing system to the film of the viscous liquid to cure the photoactive resin in at least a portion of the film, thereby printing at least a portion of the thermal management device (e.g., a fin of the thermal management device, a portion of the fin, etc. The photoactive resin and/or the polymeric precursors may be cured in a manner and/or a configuration such that the portion of the film of the viscous liquid that is cured corresponds to the size and/or the shape of the thermal management device or a portion of the thermal management device. The photoactive resin and/or the polymeric precursors may be cured in a manner and/or a configuration such that a resulting green part generated by photopolymerization or curing of the resin corresponds to the size and/or the shape of the thermal management device or a portion of the thermal management device.

The method may further comprise configuring the wiper to be in contact with the print window, and using the wiper to reduce or inhibit flow of the viscous liquid out of the deposition head while moving the deposition head to deposit the film.

The method may further comprise positioning the wiper at a distance away from the print window, and using the wiper to flatten the film of the viscous liquid into a desired thickness while moving the deposition head. The desired thickness of the film of the viscous liquid may be substantially the same as the distance between the wiper and the print window. The distance between the wiper and the print window may be adjustable. Thus, the thickness of the film of the viscous liquid may be adjustable. The thickness of the film may be adjusted to control a thickness of the at least the portion of the 3D object. In some cases, after printing the at least the portion of the 3D object, the method may further comprise moving the deposition head cross the open platform in a first direction, and using the wiper of the deposition head that is in contact with the print window to remove any excess of the viscous liquid from the print window. Furthermore, in some cases, the deposition head may further comprise an additional wiper. After moving the deposition head in the first direction and using the wiper to remove the excess of the viscous liquid from the print window, the method may further comprise moving the deposition head in the second direction opposite of the first direction and using the additional wiper to collect the excess of the viscous liquid between the additional wiper and the wiper within the deposition head.

The excess of the viscous liquid may be collected and used (recycled) to deposit an additional film of the viscous liquid over the print window. In some cases, if a volume of the excess of viscous liquid collected by the deposition head is not sufficient to deposit the additional film, the nozzle of the deposition head may dispense more viscous liquid into the collected excess of viscous liquid. In an example, the controller may use a computer model of the 3D object, such as a computer-aided design (CAD) stored in a non-transitory computer storage medium, to determine theoretical amounts of (i) the viscous liquid used in a first printing step and (ii) the excess of the viscous liquid remaining on the print window. The controller may also use the computer model of the 3D object to determine a theoretical amount of the viscous liquid needed to deposit a film of the viscous liquid for the second printing step. If the volume of the collected excess of viscous liquid is not sufficient for the second printing step, the controller may direct the nozzle to dispense more viscous liquid. The system may comprise a repository (e.g., vat or container) adjacent to the open platform. After each printing step, the deposition head may move to the repository and collect the excess viscous liquid into the repository. The collected excess viscous liquid may be reprocessed and used for printing.

The deposition head may be coupled to a motion stage adjacent to the open platform. Thus, the method may comprise moving the motion stage to move the deposition head across the open platform to at least deposit the film of the viscous liquid on the print window. The open platform may have different shapes (e.g., rectangle or ring), and movement of the motion stage may have different shapes. The motion stage may move linearly, thereby directing the deposition head in a first direction and/or in a second direction that is opposite to the first direction. The motion stage may move circularly, thereby direction the deposition clockwise and/or counterclockwise.

The method may comprise providing a build head for holding at least a portion of the 3D object during fabrication. Prior to directing the light through the print window and to the film of the viscous liquid, the method may further comprise moving the build head towards the print window and bringing in contact with the film of the viscous liquid. Subsequent to directing the light to cure at least a portion of the photoactive resin in the film of viscous liquid between the print window and the build head, the method may further comprise moving the build head in a direction away from the print window.

The method may comprise moving the build head in the direction away from the window while forming the 3D object. The rate of movement of the build head may be controlled to adjust a thickness of one or more layers in the 3D object. A surface of the build head in contact with a first layer of the 3D object may be smooth, knurled, or serrated to adjust contact surface area and/or frictional force between the surface and the first layer of the 3D object. Alternatively or in addition to, the first layer of the 3D object may be a support layer for the 3D object that may be removed post-processing.

The method may comprise using a plurality of viscous liquids for printing the 3D object. In some cases, the method may comprise providing an additional deposition head comprising an additional nozzle. The additional nozzle may be in fluid communication with an additional source of an additional viscous liquid. The method may further comprise moving the additional deposition head across the open platform and depositing a film of the additional viscous liquid over the print window. In some cases, the method may comprise providing the additional source of the additional viscous liquid that is in fluid communication with the nozzle of the deposition head. The method may further comprise dispensing the additional viscous liquid through the nozzle to the print window during printing. Alternatively or in addition to, the method may comprise providing the additional source of the additional viscous liquid that is in fluid communication with an additional nozzle in the deposition head. The method may further comprise dispensing the additional viscous liquid through the additional nozzle to the print window during printing.

The method may comprise providing a cleaning zone adjacent to the open platform. The method may further comprise moving the deposition head to the cleaning zone and activating the cleaning zone to clean the deposition head. The deposition head may be cleaned prior to depositing a new film of the viscous liquid. The deposition head may be cleaned subsequent to printing at least a portion of the 3D object.

The method may comprise providing a sensor (e.g., an optical profilometer) adjacent to the open platform. The method may further comprise moving the sensor across the open platform and using the sensor to measure a thickness of at least a portion of the film of the viscous liquid prior and/or subsequent to printing at least a portion of the 3D object. The sensor may be configured to detect an irregularity in the thickness and/or a defect (e.g., a hole) in the film of the viscous liquid. The sensor may be configured to alert the controller to direct the deposition head to clean the print window and re-deposit the film of the viscous liquid.

The method may comprise providing a transparent film adjacent to the print window. The transparent film may cover the print window. The transparent film may comprise one or more fluoropolymers that reduce adhesion of a cured portion of the viscous liquid on the transparent film. The method may further comprise directing the light through the print window, through the transparent film, and to the film of the viscous liquid to cure the photoactive resin in the at least the portion of the film of the viscous liquid, thereby printing at least a portion of the 3D object.

The method may comprise using a plurality of wavelengths of light for printing at least a portion of the 3D object (e.g., a portion of the thermal management device, a fin of the thermal management device, a portion of the fin, etc.). The method may comprise directing the light comprising a first wavelength to cure the photoactive resin in a first portion of the film of the viscous liquid. The light comprising the first wavelength may activate at least one photoinitiator to initiate curing of polymeric precursors into a polymeric material to form the least the portion of the 3D object. The photoactive resin and/or the polymeric precursors may be cured in a manner and/or a configuration such that the portion of the film of the viscous liquid that is cured corresponds to the size and/or the shape of the thermal management device or a portion of the thermal management device. The photoactive resin and/or the polymeric precursors may be cured in a manner and/or a configuration such that a resulting green part generated by photopolymerization or curing corresponds to the size and/or the shape of the thermal management device or a portion of the thermal management device.

The method may further comprise directing an additional light having a second wavelength to inhibit curing of the photoactive resin in a second portion of the film of the viscous liquid. The first wavelength and the second wavelength may be different. The additional light having a second wavelength may activate at least one photoinhibitor to inhibit curing of the polymeric precursors into the polymeric material in the second portion of the film adjacent to the print window.

The method may comprise providing the light comprising the first wavelength using an optical source. The method may comprise providing the additional light comprising the second wavelength using an additional optical source. In some cases, the method may comprise providing a light comprising a first wavelength and an additional light comprising a second wavelength using the same optical source.

The method may comprise adjusting a position of the additional optical source independently and relative to a position of the optical source. In some cases, the method may further comprise providing a light platform to hold the additional optical source. In other cases, the method may further comprise, prior to curing the photoactive resin in the first portion of the film of the viscous liquid, moving the light platform relative to the print window and yielding a uniform projection of the additional light within the second portion of the film of the viscous liquid adjacent to the print window.

The three-dimensional (3D) printing system may be configured to implement a method for printing the thermal management device. The method may comprise providing a resin (e.g., a viscous liquid) adjacent to a build surface (e.g., the open platform comprising the print window). The resin may be provided (i.e., deposited or dispensed) in a configuration such that a green part generated by photopolymerization of the viscous liquid corresponds to a portion of the thermal management device, a fin of the thermal management device, a portion of the fin, etc. The resin may comprise a polymeric precursor. The resin may comprise at least one photoinitiator that is configured to initiate formation of a polymeric material from the polymeric precursor. The resin may comprise at least one photoinhibitor that is configured to inhibit formation of the polymeric material from the polymeric precursor. The resin may comprise a plurality of particles (e.g., metallic, intermetallic, and/or ceramic particles) for forming at least a portion of the 3D object.

The method may comprise exposing the resin (e.g., the viscous liquid) to a first light under conditions sufficient to cause the at least one photoinitiator to initiate formation of the polymeric material from the polymeric precursor. The polymeric material may encapsulate the plurality of particles. The plurality of particles encapsulated in the polymeric material may be usable for forming at least a portion the 3D object (e.g., a fin, a portion of the fin, etc. The resin and/or the polymeric precursors of the resin may be cured in a manner and/or a configuration such that the portion of the film of the viscous liquid that is cured corresponds to the size and/or the shape of the thermal management device or a portion of the thermal management device. The photoactive resin and/or the polymeric precursors may be cured in a manner and/or a configuration such that a resulting green part generated by photopolymerization or curing corresponds to the size and/or the shape of the thermal management device or a portion of the thermal management device. In some cases, the method may comprise exposing the resin to a second light under conditions sufficient to cause the at least one photoinhibitor to inhibit formation of the polymeric material adjacent to the build surface.

The method may further comprise repeating, one or more times, (a) providing the resin to the build surface and (b) exposing the resin to (i) the first light to initiate formation of the polymeric material in and (ii) the second light to inhibit formation of the polymeric material adjacent to the build surface. The first light may comprise a first wavelength and the second light may comprise a second wavelength. The first and second wavelengths may be different. The first wavelength may be sufficient to activate the at least one photoinitiator, and the second wavelength may be sufficient to activate the at least one photoinhibitor. The first light may be a photoinitiation light, and the second light may be a photoinhibition light.

The method may further comprise providing a build head adjacent to the build surface. The at least the portion of the 3D object may be formed adjacent to the build head. Additional portions of the 3D object may be formed adjacent to the at least the portion of the 3D object on the build head. During formation of the 3D object, the build head may be moved along a direction away from the build surface. The controller operatively coupled to the build head may be used to adjust a relative distance between the build head and the build surface, thereby adjusting a thickness of a photoinhibition layer within the resin adjacent to the build surface, a photoinitiation layer between the photoinhibition layer and the build head, or both.

The build surface may comprise an optically transparent window. Accordingly, the method may comprise exposing the resin to the photoinitiation light and/or the photoinhibition light through the optically transparent window.

The polymeric precursor of the resin may comprise monomers. Accordingly, the method may comprise exposing the resin to the first light to induce polymerization of the monomers to generate the polymeric material. Alternatively or in addition to, the polymeric precursor of the resin may comprise oligomers. Accordingly, the method may comprise exposing the resin to the first light to induce cross-linking between the oligomers to generate the polymeric material.

The resin may further comprise at least one dye (e.g., an ultraviolet (UV) absorber) configured to absorb the second light (the photoinhibition light). Accordingly, the method may comprise exposing the resin to the second light to initiate the at least one dye to reduce an amount of the second light exposed to the at least one photoinhibitor in at least a portion of the resin.

Once the at least the portion of the thermal management device is printed (herein referred to as a green part), the method may further comprise removing the green part from the build head. The green part may be separated from the build head by inserting a thin material (e.g. a steel blade) between the green part and the build head. A first layer of the green part that is in contact with the build head may not comprise the plurality of particles for easy removal from the build head by the thin material. The method may further comprise washing the green part. The green part may be washed by jetting a solvent (e.g., isopropanol) to remove any excess polymeric precursor.

The method may further comprise subjecting the green part comprising the polymeric material to heating (e.g., in a furnace), to thereby heat at least the plurality of particles encapsulated in the at least the polymeric material. The heating may be under conditions sufficient to sinter the plurality of particles to form a final product that is at least a portion of a 3D object or an entire 3D object. During heating (e.g., sintering), the organic components (e.g., the polymeric material, additives, etc.) may decompose and leave the green part. At least a portion of the decomposed organic components may leave the green part in gas phase.

The green part may be heated in a processing chamber. The temperature of the processing temperature may be regulated with at least one heater. The processing chamber may be an oven or a furnace. The oven or furnace may be heated with various heating approaches, such as resistive heating, convective heating and/or radiative heating. Examples of the furnace include an induction furnace, electric arc furnace, gas-fired furnace, plasma arc furnace, microwave furnace, and electric resistance furnace. Such heating may be employed at a fixed or variating heating rate from an initial temperature to a target temperature or temperature range.

The green part corresponding to at least a portion of the thermal management device may be heated from room temperature to a processing temperature. The processing temperature may be kept constant or substantially constant for a given period of time, or may be adjusted to one or more other temperatures. The processing temperature may be selected based on the material of the particles in the green part (e.g., the processing temperature may be higher for material having a higher melting point than other materials). The processing temperature may be sufficient to sinter but not completely melt the particles in the green part. As an alternative, the processing temperature may be sufficient to melt the particles in the green part.

During sintering of the green part comprising the plurality of particles (e.g. metal, intermetallic, and/or ceramic), the green part may be subjected to cooling by a fluid (e.g., liquid or gas). The fluid may be applied to the green part and/or the processing chamber to decrease the temperature of the green part. The fluid may be subjected to flow upon application of positive or negative pressure. Examples of the fluid for cooling the green part include water, oil, hydrogen, nitrogen, argon, etc. Cooling the green part during the sintering process may control grain size within the sintered part.

In some cases, the resin may further comprise an extractable material (e.g., a binder). Accordingly, the method may comprise additional steps of treating the green part (e.g., de-binding and/or pre-sintering) prior to subjecting the green part to heating (e.g., sintering).

The extractable material may be soluble in the polymeric precursor and/or dispersed throughout the rein. Accordingly, the method may comprise curing the polymeric precursor of the resin in at least a portion of the resin, thereby creating a first solid phase comprising the polymeric material and a second solid phase comprising the extractable material within at least a portion of the 3D object (e.g., the thermal management device). Such method may be a polymerization-induced phase separation (PIPS) process. The plurality of particles (e.g., metallic, intermetallic, and/or ceramic particles) may be encapsulated by the first solid phase comprising the polymeric material. The at least the portion of the 3D object may be a green part that can undergo heating to sinter at least a portion of the plurality of particles and burn off at least a portion of other components (i.e., organic components).

The extractable material may be soluble in a solvent (e.g., isopropanol). The solvent may be an extraction solvent. A first solubility of the extractable material in the solvent may be higher than a second solubility of the polymeric material in the solvent. The solvent may be a poor solvent for the polymeric material. Accordingly, the method may further comprise (i) treating (e.g., immersed, jetted, etc.) the green part with the solvent (liquid or vapor), (ii) solubilizing and extracting at least a portion of the extractable material from the second solid phase of the green part into the solvent, and (iii) generating one or more pores in the green part. The one or more pores in the green part may be a plurality of pores. The one or more pores may create at least one continuous porous network in the green part. In some cases, the method may further comprise treating the green part with the solvent and heat at the same time. Such a process may be a solvent de-binding process.

The solvent for the solvent de-binding process may not significantly swell the polymeric material in the green part. In some cases, the viscous liquid may comprise acrylate-based polymeric precursors. Since acrylate-based polymers are of intermediate polarity, both protic polar solvents (e.g., water and many alcohols such as isopropanol) and non-polar solvents (e.g., heptane) may be used. Examples of the solvent for the solvent de-binding process include water, isopropanol, heptane, limolene, toluene, and palm oil. On the other hand, intermediate polarity solvents (e.g., acetone) may be avoided.

The solvent de-binding process may involve immersing the green part in a container comprising the liquid solvent. A volume of the solvent may be at least about 2 times the volume of the green part. The volume of the solvent may be at least about 2, 3, 4, 5, 6, 7, 8, 9, 10 times or more than the volume of the green part. The container comprising the liquid solvent and the green part may be heated to a temperature ranging between about 25 degrees Celsius to about 50 degrees Celsius. The container comprising the liquid solvent and the green part may be heated (e.g., a water bath, oven, or a heating unit from one or more sides of the green part) to a temperature of at least about 25 degrees Celsius, 26 degrees Celsius, 27 degrees Celsius, 28 degrees Celsius, 29 degrees Celsius, 30 degrees Celsius, 35 degrees Celsius, 40 degrees Celsius, 45 degrees Celsius, 50 degrees Celsius, or more. The container comprising the liquid solvent and the green part may be heated to a temperature of at most about 50 degrees Celsius, 45 degrees Celsius, 40 degrees Celsius, 35 degrees Celsius, 30 degrees Celsius, 29 degrees Celsius, 28 degrees Celsius, 27 degrees Celsius, 26 degrees Celsius, 25 degrees Celsius, or less. The solvent de-binding process may last between about 0.1 hours (h) to about 48 h. The solvent de-binding process may last between at least about 0.1 h, 0.2 h, 0.3 h, 0.4 h, 0.5 h, 1 h, 2 h, 3 h, 4 h, 5 h, 6 h, 12 h, 18 h, 24 h, 30 h, 36 h, 42 h, 48 h, or more. The solvent de-binding may last between at most about 48 h, 42 h, 36 h, 30 h, 24 h, 18 h, 12 h, 6 h, 5 h, 4 h, 3 h, 2 h, 1 h, 0.5 h, 0.4 h, 0.3 h, 0.2 h, 0.1 h, or less. After the solvent de-binding process, the solvent may be removed and the green part may be allowed to dry. A weight of the green part may be measured before and after the solvent de-binding to determine the amount of material extracted from the green part.

After the solvent de-binding process, the green part may be heated (e.g., sintered) and/or cooled as abovementioned. During heating (e.g., sintering), at least a portion of the organic components (e.g., the polymeric material, additives, etc.) may decompose and leave the green part in part through the at least one continuous porous network. The presence of the at least one continuous porous network from the solvent de-binding step may improve the speed of the sintering process.

Subsequent to sintering the green part, the heated (e.g., sintered) particles as part of a nascent 3D object (e.g., the thermal management device) may be further processed to yield the 3D object. This may include, for example, performing surface treatment, such as polishing, on one or more surfaces of the nascent 3D object.

Other features and elements of thermal management devices and three-dimensional (3D) printing system for printing such thermal management devices may be as described in International Patent Publication PCT/US2020/032760, which is entirely incorporated herein by reference.

### EXAMPLES

### Example 1

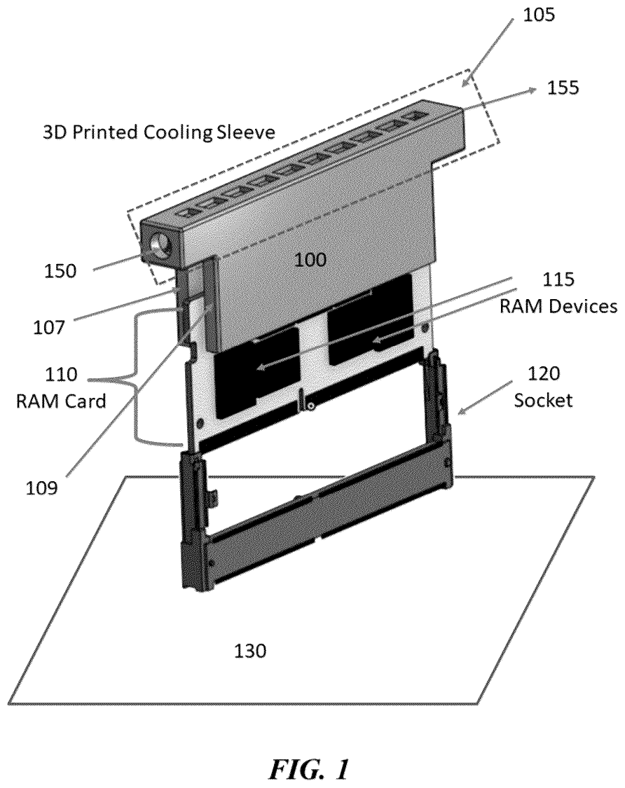

FIG. 1 schematically illustrates a perspective view of a jacketed cooling sleeve thermal management device 100 in relation to an object to be cooled. In this example, the object to be cooled is a vertically-attached board 110 onto which is attached to one or more electronic devices 115 that are known to generate heat. The jacketed cooling sleeve 100 is a shell that has a fluid routing section 105 connected to two conformal sections, 107, 109 that contain fluid channels and are configured to make thermal contact with the vertically-attached board 110. In FIG. 1, the jacketed cooling sleeve 100 is shown partially disposed onto the vertically-attached board 110. The vertically-attached board 110 is configured to slide into a socket 120. The socket 120 is attached to and extends away from a motherboard 130. When the jacketed cooling sleeve 100 is fully disposed onto the vertically-attached board 110, the electronic devices 115 are no longer visible in this view. Conformal section 107 makes thermal contact with one side of the vertically-attached board 110, and conformal section 109 makes thermal contact with an opposite side of the vertically-attached board 110. In some cases, there may be a gap pad between the electronic devices 115 and the conformal section 109. The gap pad may be made of a thermal interface material, such as silicone containing silver particles and facilitate thermal conduction between the RAM devices 115 and the jacketed cooling sleeve 100. Examples of electronic devices that are known to generate heat include RAM, network cards, sound cards, graphics processing units (GPUs), etc. Although the example in FIG. 1 shows electronic devices 115 attached to only one side of the vertically-attached board 110, it should be understood that in other embodiments, there may be electronic devices 115 attached to both sides of the vertically-attached board 110.

Referring to FIG. 1, the jacketed cooling sleeve thermal management device 100 is configured as a shell that has an internal layout that allows a cooling fluid to flow through it. The jacketed cooling sleeve 100 has an inlet port 150 that allows cooling fluid to flow into the jacketed cooling sleeve 100. The jacketed cooling sleeve 100 also has an outlet port 155 that allows cooling fluid to flow out of the jacketed cooling sleeve 100. The inlet port 150 and/or the outlet port 155 can be configured to be either male or female. In some cases, the jacketed cooling sleeve may comprise tubes at the inlet port 150 and/or the outlet port 155 configured to accept compression fittings. In some cases, the inlet port 150 and/or the outlet port 155 can be configured with hose barbs that to which hoses such as flexible rubber tubing can be attached.

### Example 2

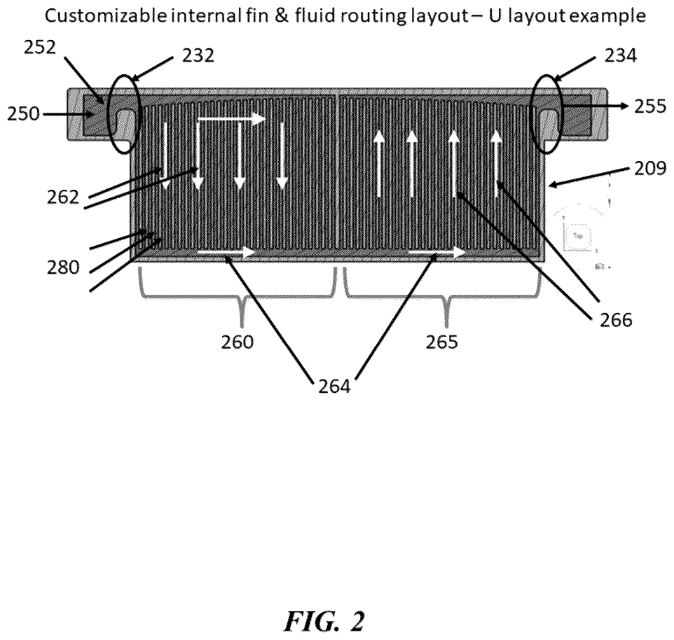

FIG. 2 schematically illustrates a jacketed cooling sleeve thermal management device in a lateral-section view taken through a conformal section 209 and an adjacent portion of a fluid supply section 205, which shows one of many possible internal configurations for the conformal section 209. There are two major regions in the conformal section 209—an inflow region 260 and an outflow region 265, separated by partial wall 270. Within both the inflow region 260 and the outflow region 265 there are a series of internal fins 280.

The jacketed cooling sleeve is configured to receive cooling fluid 252 in through the inlet port 250 and to direct the cooling fluid 252 to flow through the fins 280 in the inflow region 260. The direction of flow is shown by arrows 262. The cooling fluid 252 is then directed to flow to the other side of the partial wall 270 and into the outflow region 265 as shown by arrows 264. The cooling fluid then flows through the fins 280 in the outflow region 265 as shown by arrows 266. Finally, the cooling fluid 252 is directed to flow out of the jacketed cooling sleeve through the outlet port 255. FIG. 2 shows an internal layout that guides the cooling fluid 252 through a U-shaped path.

In some cases, flow passages adjacent to the inlet port and/or the outlet port are configured to optimize a balanced flow by providing a tapered region 232 adjacent to the inlet port 150 and/or a tapered region 234 adjacent to the outlet port 255.

### Example 3

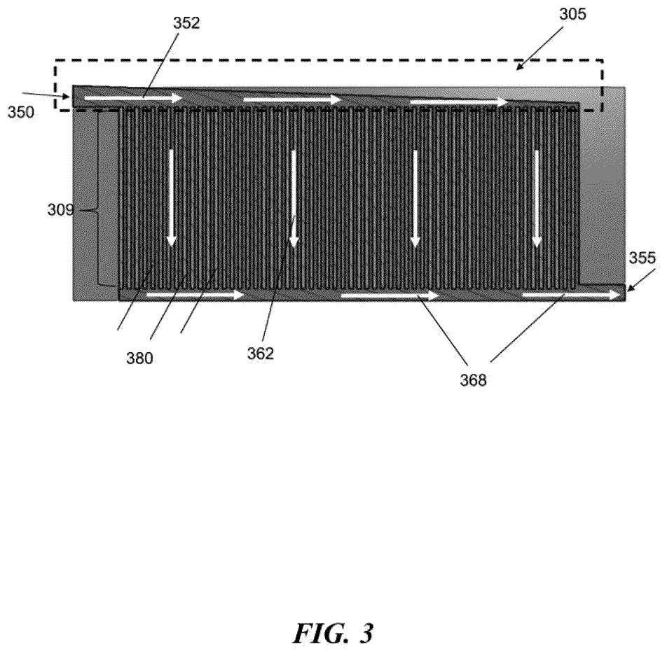

FIG. 3 schematically illustrates a lateral-section view taken through a conformal section 309 and an adjacent portion of the fluid supply section 305, which shows one of many possible internal configurations. The conformal section 309 is configured to receive cooling fluid 352 in through the inlet port 350 and to direct the cooling fluid 352 to flow through fins 380 in the conformal section 309. The fluid supply section 305 is widest adjacent to the inlet port 350 and becomes narrower with each succeeding fin 380. After the cooling fluid 352 passes through the fins 380, to flows out through an outlet port 355 as shown by arrows 368. FIG. 3 shows an internal layout that guides the cooling fluid 352 through a Z-shaped path.

In any embodiments of the examples provided herein, any of a variety of internal layouts and flow paths configurations may be used within the shell of the jacketed cooling sleeve. In some cases, both conformal sections may have the same internal layout and flow path. In some cases, the internal layouts and/or flow paths of the conformal sections may be different.

### Example 4

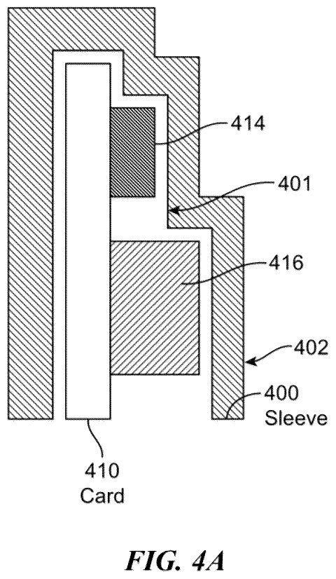

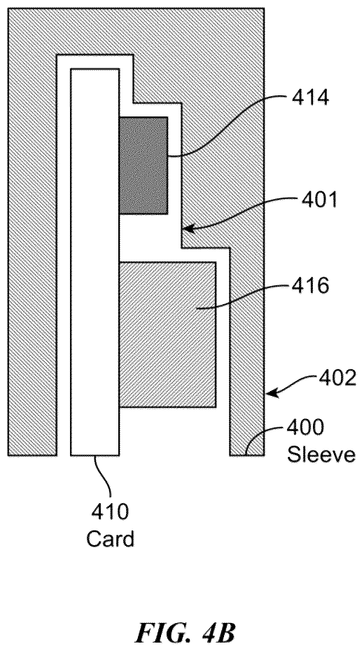

In some cases, a conformal sections of a jacketed cooling sleeve as disclosed herein may or may not be planar. For example, when the devices on a card all have the same thickness, a conformal section can have a planar surface that can make thermal contact with all the devices on the card. Alternatively, when the devices on a card do not all have the same thickness, a conformal section can have a surface that follows the contours of the devices on the card. FIG. 4A schematically illustrates a jacketed cooling sleeve thermal management device 400 that is configured to make thermal contact with two devices 414, 416 that have different thicknesses. The device 414 is substantially thicker than the device 416. The two devices 414, 416 are both on one side of a vertically-attached board 410. An inner surface 401 of the jacketed cooling sleeve 400 that makes contact to the devices 414, 416 follows the contours of the devices 414, 416 in order to make effective thermal contact to them. When device 414 and device 416 have different cooling requirements, the internal structure of the jacketed cooling sleeve 400 can be configured to provide different cooling rates by choosing specific fin structures and/or cooling fluid paths in regions adjacent to each device.

An outer surface 402 of the jacketed cooling sleeve 400 is approximately parallel to the inner surface 401. In some cases, the outer surface 402 of the jacketed cooling sleeve 400 has a completely different profile. FIG. 4B schematically illustrates a jacketed cooling sleeve thermal management device 400 that has an outer surface 402 with a profile that does not follow the contours of the inner surface 401.

### Example 5

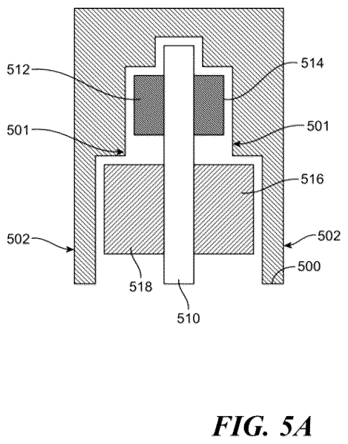

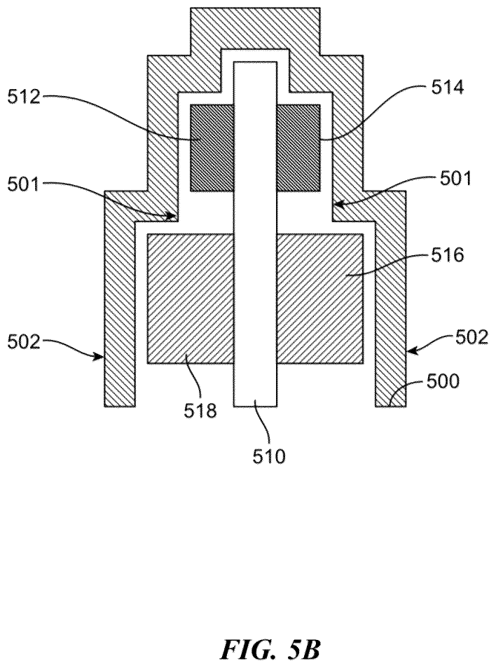

FIG. 5A schematically illustrates a jacketed cooling sleeve thermal management device 500 that is configured to make thermal contact with four devices 514, 516, 512, 518 that do not all have the same thickness. The devices 514, 512 are substantially thicker than the devices 516, 518. There are two devices 514, 516 on one side of a vertically-attached board 510 and two devices 512, 518 on the opposite side of the vertically-attached board 510. An inner surface 501 of the jacketed cooling sleeve 500 that makes contact to the devices 514, 516, 512, 518 follows the contours of the devices 514, 516, 512, 518 in order to make effective thermal contact to them. When some or all of the devices 514, 516, 512, 518 have different cooling requirements, the internal structure of the jacketed cooling sleeve 500 can be configured to provide different cooling rates by choosing specific fin structures and/or cooling fluid paths in regions adjacent to each device.

An outer surface 502 of the jacketed cooling sleeve 500 is approximately parallel to the inner surface 501. In some cases, the outer surface 502 of the jacketed cooling sleeve 500 has a completely different profile. FIG. 5B is a schematic drawing that shows a jacketed cooling sleeve thermal management device 500 that has an outer surface 502 with a profile that does not follow the contours of the inner surface 501.

### Example 6

The jacketed cooling sleeve described herein can be made of any metal or combination of metals that provide good thermal conduction. Examples may include copper, aluminum, and alloys thereof.

In some cases, the thickness of the shell of the jacketed cooling sleeve can be between 50 and 5000 μm, between 100 and 3000 μm, or between 300 and 2000 μm.

In some cases, the jacketed cooling sleeve described herein is manufactured using additive manufacturing methods. The jacketed cooling sleeve may be manufactured as one piece including the outer shell and all internal structures. Alternatively, the jacketed cooling sleeve may be manufactured in two pieces; the internal structures may be manufactured using additive manufacturing methods and the outer shell can be manufactured from metal sheets using conventional methods such as stamping and bending. In some cases, the two pieces are assembled together using O-rings and screws. In some cases, the two pieces are brazed together. The inlet port and/or the outlet port can be features integral to the shell of the jacketed cooling sleeve or they can be separate parts attached to the shell using a technique such as brazing.

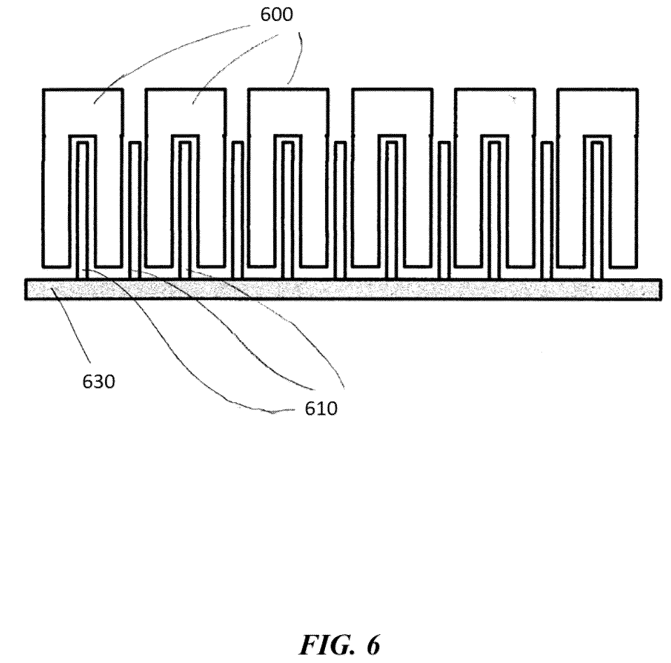

A series of jacketed cooling sleeve thermal management devices, as described herein, can be arranged to provide cooling for numerous objects, such as a series of electronic devices on a motherboard. FIG. 6 schematically illustrates a series of jacketed cooling sleeve thermal management devices 600 disposed onto a series of objects 610 to be cooled attached to a motherboard 630. Cooling fluid routed through each of the cooling sleeves 600 may be configured to pass through each cooling sleeve in series or via a manifold (not shown) to move through the cooling sleeves in parallel fashion.

### Example 7

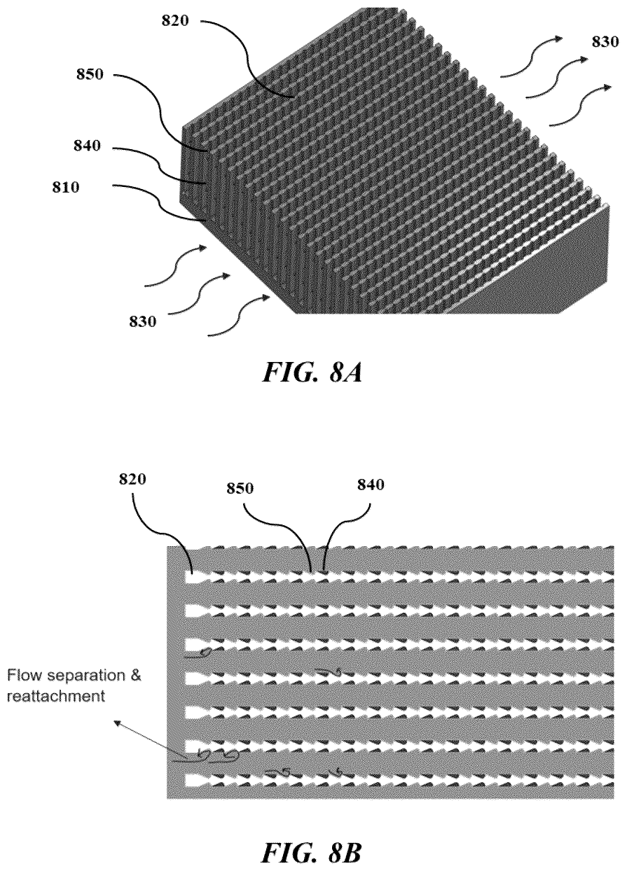

FIGS. 8A and 8B schematically illustrate an example thermal management device, as provided herein. The thermal management device comprises a base plate 810 and a plurality of fins 820 coupled to the base plate 810. The spacings between the plurality of fins may provide a fluid flow path for a working fluid (e.g., cooling fluid) 830 to flow across the thermal management device. One or more fins of the plurality of fins 820 can comprise cavities (e.g., shaped cavities) to initiate vortices and boundary layer disruption of the working fluid as the working fluid is flowing adjacent to the cavities of the one or more fins. A fin can have a plurality of cavities across one or more axes of a surface of the fin comprising the cavities. For example, a fin can have a first row of first depressions 840 across a direction of flow of the working fluid and a second row of second depressions across the same direction. The second row and the first row may be staggered in Z direction (e.g., perpendicular to the direction of flow of the working fluid) for, e.g., additional flow disruption. The first depressions and the second depressions can be staggered (e.g., not aligned along the Z direction) for, e.g., additional flow disruption.

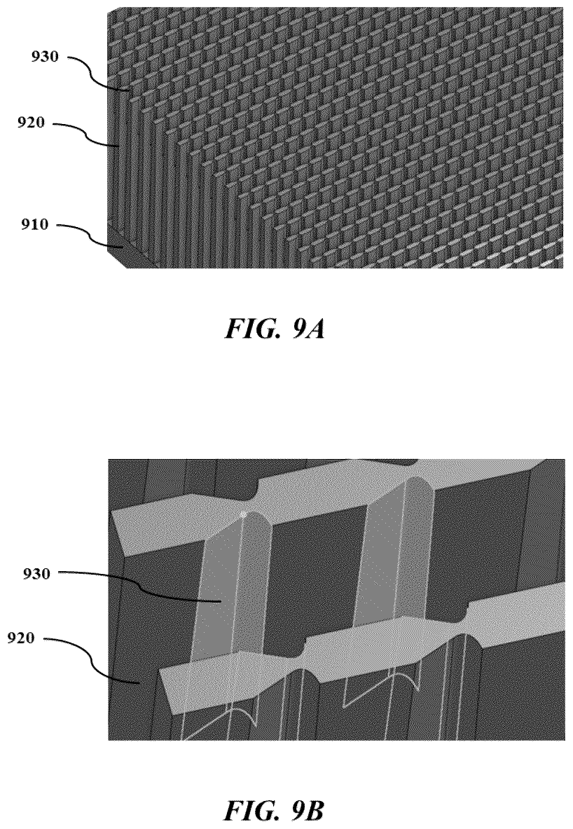

FIGS. 9A and 9B schematically illustrate an example thermal management device, as provided herein. The thermal management device comprises a base plate 910 and a plurality of fins 920 coupled to the base plate 910. The spacings between the plurality of fins may provide a fluid flow path for a working fluid (e.g., cooling fluid) to flow across the thermal management device. One or more fins of the plurality of fins 920 can comprise a row of cavities (e.g., shaped cavities) 930 to initiate vortices and boundary layer disruption of the working fluid as the working fluid is flowing adjacent to the cavities of the one or more fins. As shown in FIG. 9B, a cross-sectional shape of the cavities may be asymmetrical.

### Example 8

FIG. 11 schematically illustrates an example thermal management device, as provided herein. The thermal management device comprises a base plate 1110 and a plurality of fins 1120 coupled to the base plate 810. At least a portion of the plurality of fins 1120 may be non-linear. For example, as illustrated in FIG. 11, at least a portion of the plurality of non-linear fins 1120 may comprise wavy fins. The spacings between the plurality of fins 1120 may provide a fluid flow path along a flow direction 1130 for a working fluid (e.g., cooling fluid) to flow across the thermal management device. FIG. 11 illustrates fins that are non-linear (e.g., wavy) along the direction of the flow 1130 of the working fluid. Alternatively or in addition to, at least a portion of the fins can be non-linear (e.g., wavy) along a different direction (e.g., a transverse direction 1140 that is substantially perpendicular to the direction 1130). An amplitude and/or frequency of the non-linear feature (e.g., the wave amplitude and/or frequency) of each fin may be the same along a dimension of the fin (e.g., along the direction 1130 and/or 1140). Alternatively, the amplitude and/or frequency of the non-linear feature of each fin may vary along a dimension of the fin (e.g., along the direction 1130 and/or 1140). For example, the wave amplitude and/or frequency of at least a portion of a fin may decrease by at least about 0.1%, 0.2%, 0.5%, 1%, 2%, 5%10%, 20%, 30%, 40%, 50%, 80%, or more along a dimension (e.g., along a length of the fin). In another example, the wave amplitude and/or frequency of at least a portion of a fin may increase by at least about 0.1%, 0.2%, 0.5%, 1%, 2%, 5%, 10%, 20%, 30%, 40%, 50%, 80%, or more along a dimension (e.g., along a length of the fin). As illustrated in FIG. 11, the fins of the thermal management device may not comprise a depression or a protrusion. Alternatively, the fins of the thermal management device may comprise a depression or a protrusion.

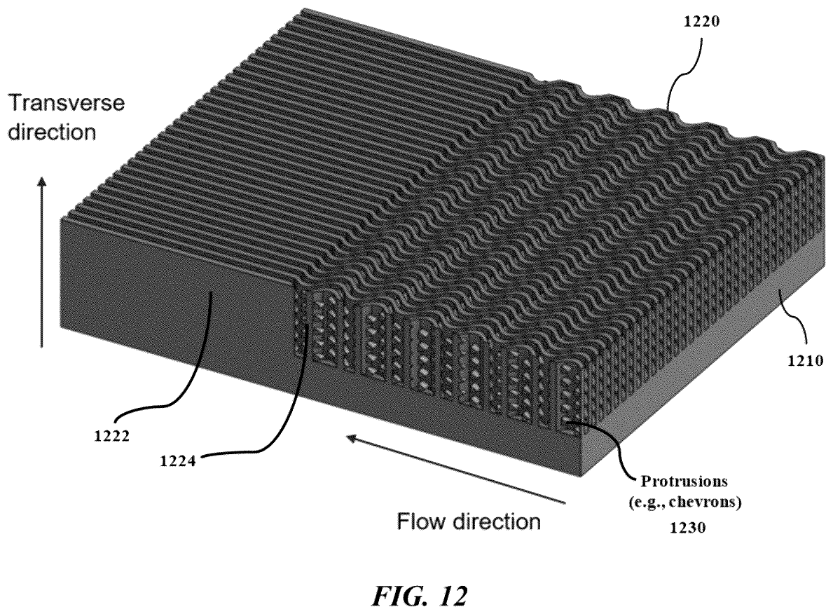

FIG. 12 schematically illustrates an example thermal management device, as provided herein. The thermal management device comprises a base plate 1210 and a plurality of fins 1220 coupled to the base plate 1210. A first portion 1222 of each fin of the plurality of fins 1220 may be linear, and a second portion 1224 of each fin of the plurality of fins 1220 may be wavy. The second portion 1125 (the wavy portion) of the fin of the plurality of fins 1220 may comprise one or more protrusions (or chevrons) 1230 to initiate vortices and boundary layer disruption of the working fluid as the working fluid is flowing adjacent to the cavities of the one or more fins. A fin can have a plurality of protrusions across one or more axes of a surface of the fin comprising the protrusions. A fin can have an array of protrusions across a surface of the wavy portion and/or the linear portion of the fin. As illustrated in FIG. 12, a fin can have an array of protrusions across a surface of the wavy portion of the fin. The protrusions can be uniformly distributed across the surface, as illustrated in FIG. 12. Alternatively, the protrusions can be non-uniformly distributed across the surface.

### Example 9

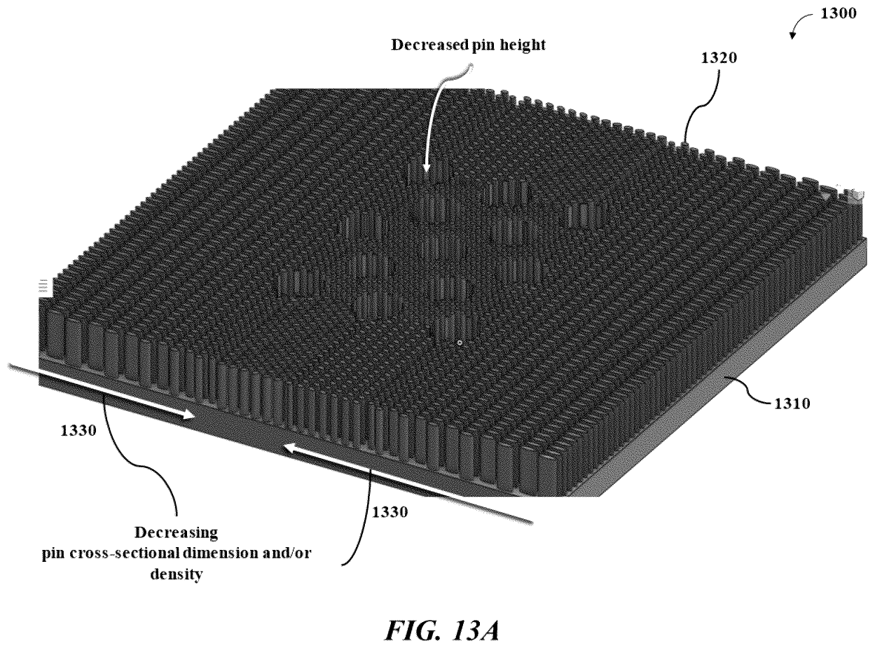

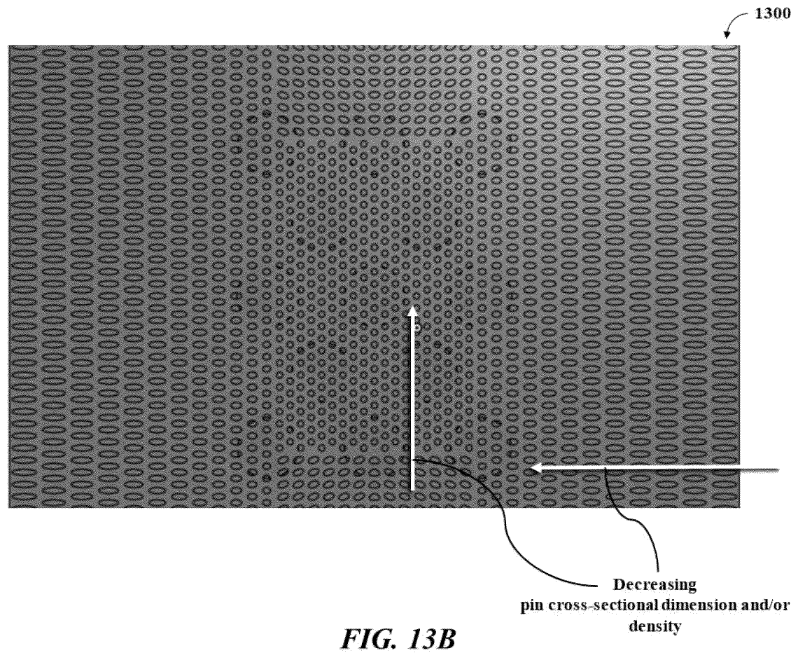

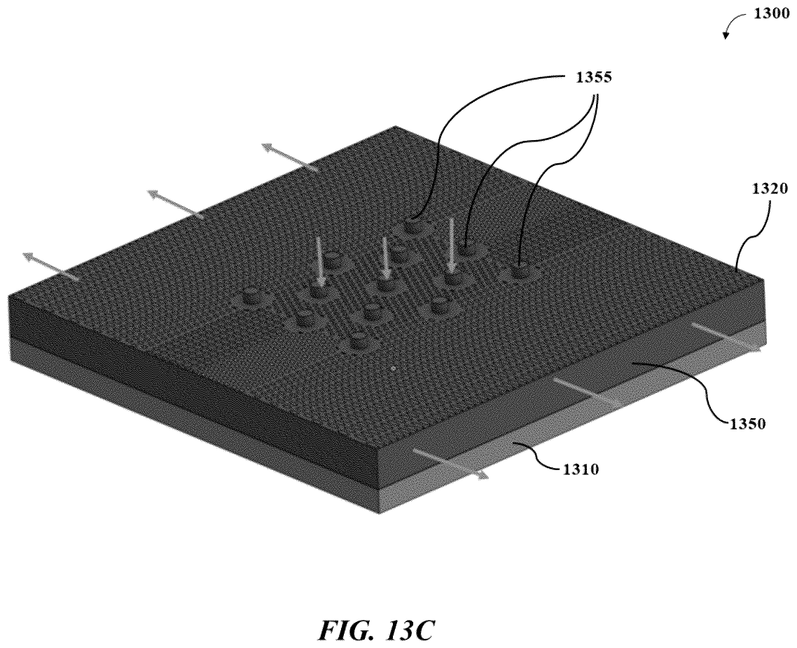

FIGS. 13A-13C schematically illustrate an example thermal management device 1300 as disclosed herein. FIG. 13A schematically illustrates a perspective view of the thermal management device 1300. The thermal management device 1300 may comprise a base plate 1310 and a plurality of pins 1320 coupled to the baseplate 1310. The thermal management device 1300 may comprise a plurality of inlets configured to direct flow of a working fluid towards the top of the plurality of pins 1320. As such, the plurality of inlets may be disposed above the plurality of pins 1320. A sub-population of the plurality of pins 1320 proximal to (e.g., substantially beneath) the inlets may have a decreased pin height, as compared to other pins of the plurality of pins 1320. As illustrated in FIG. 13A, the thermal management device 1300 may comprise 13 inlets, and thus 13 sub-populations of pins of the plurality of pins 1320 may have a decreased pin height, to generate 13 depressed zones to receive the working fluid from the inlets and impinge flow of the working fluid as it flows to and through the thermal management device. In addition, the plurality of pins 1300 may have decreasing pin cross-sectional dimension and/or increasing pin density along the direction as indicated by the arrows 1330. In some cases, the direction indicated by the arrows 1330 may indicate a decreasing distance between each pin and the inlets. FIG. 13B schematically illustrates a top-down view of the thermal management device 1300.

FIG. 13C schematically illustrates the thermal management device 1300 with the working fluid 1350. The working fluid 1350 may fill at least a portion of the gaps (e.g., substantially all of the gaps) between the plurality of pins 1320 of the thermal management device 1300. The columns 1355 schematically represent the working fluid as it is flowing from the inlets towards the cutouts of the plurality of pins. As indicated by the arrows, the working fluid may flow from the inlet (top of the thermal management device) towards the base plate of the thermal management device, and towards the outskirt of the thermal management device that is away from the inlets. In some cases, the varied size and/or density of the plurality of pins of the thermal management device can effect varied heat flux (e.g., heat transfer to the working fluid from the plurality of pins, or vice versa). A sub-population of the plurality of pins can have cutouts to receive the flow in a substantially normal direction, and/or to improve penetration of the working fluid into the thermal management device (e.g., into the spacings between the plurality of pins). The density of the plurality of pins may be higher at upstream of the working fluid (e.g., closer to the inlets) relative to downstream of the working fluid (e.g., farther away from the inlets). The pins proximal to the inlets may be different than the pins away from the inlets.

### Example 10

Performance of various thermal management devices as disclosed herein was assessed, by determining the performance factor of each thermal management device as compared to a control (or baseline). As shown in Table 1, controls (or baselines) included (i) a thermal management device comprising a plurality of straight fins with a 800 micrometer fin gap (e.g., “straight fins 800 μm”), or (ii) a thermal management device comprising a plurality of wavy fins with a 800 micrometer fin gap (e.g., “wavy fins 800 μm”). New thermal management device designs tested included (1) a thermal management device comprising a plurality of straight fins with a 800 micrometer fin gap, and having one or more protrusions (or chevrons) on a surface of one or more straight fins of the plurality of straight fins (e.g., “Chevron 800 μm”), (2) a thermal management device comprising a plurality of straight fins with a 800 micrometer fin gap, and having one or more depressions (or cavities) on a surface of one or more straight fins of the plurality of straight fins (e.g., “Cavities @ 800 μm fin gap”), (3) a thermal management device comprising a plurality of straight fins with a 725 micrometer fin gap, and having one or more depressions (or cavities) on a surface of one or more straight fins of the plurality of straight fins (e.g., “Cavities @ 725 μm fin gap”), (4) a thermal management device comprising a plurality of straight fins with a 600 micrometer fin gap, and having one or more depressions (or cavities) on a surface of one or more straight fins of the plurality of straight fins, and also exhibiting a change in cross-sectional dimension (e.g., cross-sectional width) of the straight fins (e.g., “Cavities @ 600 μm fin gap with 0.5″ taper”), and (5) a thermal management device comprising a plurality of straight fins with a 600 micrometer fin gap, and having one or more depressions (or cavities) on a surface of one or more straight fins of the plurality of straight fins, and also exhibiting a greater change in cross-sectional dimension (e.g., cross-sectional width) of the straight fins (e.g., “Cavities @ 600 μm fin gap with 0.6″ taper”).

As shown in Table 1, while the new designs may have the penalty of exhibiting increased pressure drop (e.g., an increased in the difference in the pressures between the inlet and the outlet of the working fluid) as compared to the control baselines, the overall performance factor remains substantially the same or change only minimally (e.g., close to the value 1) due to the enhancement in thermal performance (e.g., decreased thermal resistivity).

TABLE 1
Performance factors of different thermal management devices, when tested at 10 liters per
meter (LPM). The performance factor is calculated using Equation 1, as provided herein.

| | | | % | | | Performance |
|---|---|---|---|---|---|---|
| | | R [° C./W] | enhancement | dP [Pa] | % change | factor [—] |
| Baseline | Straight fins 800 um | 0.0297 | — | 1042 | — | 1 |
| | Wavy fins 800 um | 0.0289 | 3% | 1153 | 11% | 0.928 |
| New Designs | Chevron 800 um | 0.0247 | 20% | 7802 | 648% | 0.17 |
| | Cavities @ 800 um fin gap | 0.0271 | 10% | 1151 | 10% | 0.991 |
| | Cavities @ 725 um fin gap | 0.0255 | 14% | 1323 | 27% | 0.92 |
| | Cavities @ 600 um fin gap | 0.025 | 15% | 1250 | 20% | 0.98 |
| | with 0.5° taper | | | | | |
| | Cavities @ 600 um fin gap | 0.0258 | 13% | 1200 | 15% | 0.999 |
| | with 0.6° taper | | | | | |

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1-80. (canceled)

81. A thermal management device, comprising:
a shell comprising:
a first conformal section and a second conformal section, wherein said first conformal section is parallel to said second conformal section, said first conformal section and said second conformal section are not in direct contact with one another, and wherein said first conformal section and said second conformal section are configured to receive a cooling fluid; and
a fluid supply section configured to provide fluidic communication with both said first conformal section and said second conformal section, wherein said fluid supply section comprises:
a first opening configured to allow said cooling fluid to flow into said shell; and
a second opening configured to allow said cooling fluid to flow out of said shell; and
an array of fins disposed within said first conformal section and said second conformal section, wherein said array of fins provides a path through which said cooling fluid can flow and wherein said array of fins is in thermal communication with said shell,
wherein said array of fins comprises (i) a plurality of fins with one or more turbulating features disposed on a surface of one or more fins of said plurality of fins or (ii) a plurality of tapered fins.

82. The thermal management device of claim 81, wherein said array of fins comprises (i) said plurality of fins with said one or more turbulating features disposed on said surface of said one or more fins of said plurality of fins.

83. The thermal management device of claim 82, wherein said one or more turbulating features are configured to generate turbulence when said cooling fluid flows across and/or through said array of fins.

84. The thermal management device of claim 81, wherein said array of fins comprises (ii) said plurality of tapered fins.

85. The thermal management device of claim 84, wherein a width of a tapered fin of said plurality of tapered fins gradually decreases along an axis spanning a height of said tapered fin.

86. The thermal management device of claim 81, wherein said array of fins comprises one or more jagged fins.

87. The thermal management device of claim 86, wherein said one or more jagged fins comprise a vertical cross-section that is in a zigzag pattern.

88. The thermal management device of claim 81, wherein said shell is configured to operatively couple to an integrated circuit module (ICM), to facilitate a transfer of thermal energy (a) from a first surface of said ICM to said first conformal section of said shell and (b) from a second surface of said ICM to said second conformal section of said shell.

89. The thermal management device of claim 88, wherein said thermal management device is configured to releasably couple to said ICM.

90. The thermal management device of claim 89, wherein said ICM is a computer memory module.

91. The thermal management device of claim 81, wherein said array of fins comprises a first set of fins and a second set of fins, wherein said first set of fins and said second set of fins are provided in a staggered arrangement.

92. A thermal management device, comprising:
a first portion configured to operatively couple to at least a portion of an edge of an integrated circuit module (ICM);
a second portion configured to facilitate a transfer of thermal energy from a surface of said ICM to a surface of said second portion, or vice versa, wherein said first portion and said second portion are not on a same plane; and
at least one fluid flow path in thermal contact with said second portion and configured to facilitate a transfer of said thermal energy from said second portion to a cooling fluid disposed within said at least one fluid flow path,
wherein said first portion is disposed substantially perpendicular to said second portion.

93. The thermal management device of claim 92, wherein said first portion is in fluid communication with said second portion.

94. The thermal management device of claim 92, wherein said first portion comprises an inlet and an outlet, wherein said at least one fluid flow path is in fluid communication with said inlet and said outlet.

95. The thermal management device of claim 92, wherein said at least one fluid flow path is disposed within said second portion.

96. The thermal management device of claim 92, wherein said first portion is coupled to said second portion.

97. The thermal management device of claim 92, wherein said first portion and said second portion are part of a housing.

98. The thermal management device of claim 92, wherein said housing comprises a shell-like body.

99. The thermal management device of claim 98, wherein said first portion is a base of said shell-like body and said second portion is a sidewall of said shell-like body.

100. The thermal management device of claim 99, wherein said thermal management device is configured to releasably couple to said ICM.
